(19) United States
(12) Patent Application Publication
(10) Pub. No.: US 2025/0185446 A1
(43) Pub. Date: Jun. 5, 2025

(54) HOLE-TRANSPORTING SELF-ORGANISED MONOLAYER FOR PEROVSKITE SOLAR CELLS

(71) Applicants: HELMHOLTZ-ZENTRUM BERLIN FÜR MATERIALIEN UND ENERGIE GMBH, Berlin (DE); KAUNAS UNIVERSITY OF TECHNOLOGY, Kaunas (LT)

(72) Inventors: Artiom MAGOMEDOV, Kaunas (LT); Amran AL-ASHOURI, Berlin (DE); Ernestas KASPARAVICIUS, Kaunas (LT); Steve ALBRECHT, Werder Havel (DE); Vytautas GETAUTIS, Kaunas (LT); Marko JOST, Berlin (DE); Tadas MALINAUSKAS, Kaunas (LT); Lukas KEGELMANN, Berlin (DE); Eike KÖHNEN, Berlin (DE)

(73) Assignees: HELMHOLTZ-ZENTRUM BERLIN FÜR MATERIALIEN UND ENERGIE GMBH, Berlin (DE); KAUNAS UNIVERSITY OF TECHNOLOGY, Kaunas (LT)

(21) Appl. No.: 19/032,142

(22) Filed: Jan. 20, 2025

Related U.S. Application Data
(63) Continuation-in-part of application No. 17/256,052, filed on Apr. 7, 2021, now Pat. No. 12,207,546.

(30) Foreign Application Priority Data
Apr. 25, 2018 (EP) 18000405.3
Jun. 26, 2018 (DE) 10 2018 115 379.1

(51) Int. Cl. H10K 30/86; H10K 30/40; H10K 30/57; H10K 85/60

(52) U.S. Cl. CPC H10K 30/86; H10K 30/40; H10K 30/57; H10K 85/636; H10K 85/655; H10K 85/6572

(57) ABSTRACT

Described herein is a compound according to formula (I)

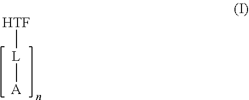

wherein HTF is a hole transporting fragment selected from the group consisting of formulae

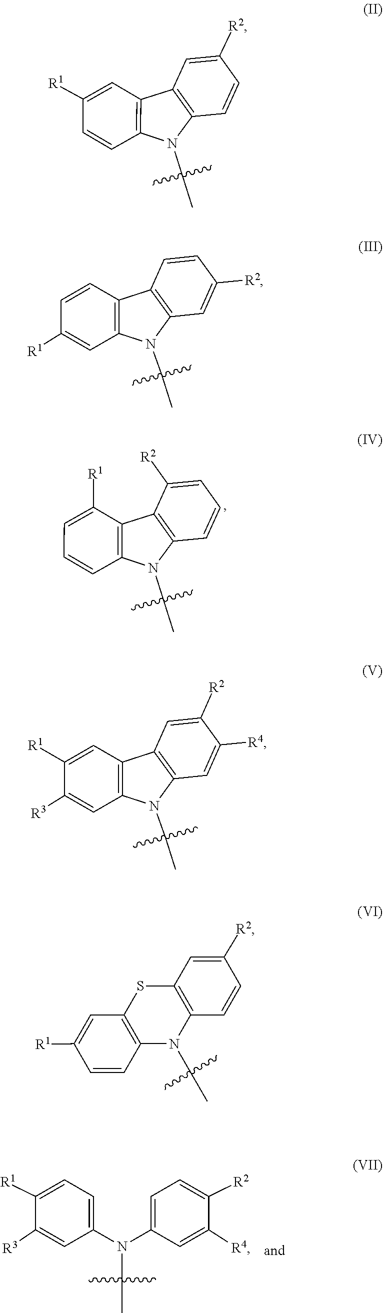

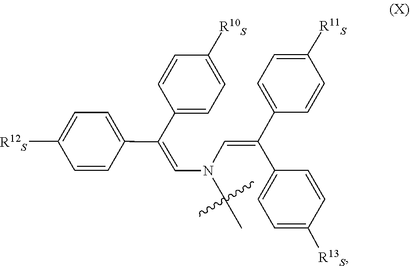

wherein
   L is a linking fragment, selected from the group consisting of C₂ to C₁₆ alkyl and phenyl; A is an anchor group, selected from the group consisting of H₂PO₃ and COOH; R¹ to R⁴ are each independently selected from the group consisting of: —H, -methyl, -tert-butyl, —OCH₃, —CN, —F, —Cl, —Br, —I,
phenyl, thiophene,

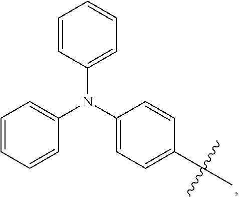 [SMILES: *c1ccc(N(c2ccccc2)c2ccccc2)cc1]

NH₃⁺Br, —NH₃⁺Cl⁻, —(CH₂)₂—NH₃⁺Br⁻, and —(CH₂)₂—NH₃⁺Cl⁻,
   R¹⁰ to R¹³ are selected from the group consisting of —H, and —OCH₃; n is 1 or 2; and is 0 or 1.

### CROSS-REFERENCE TO RELATED APPLICATIONS

This is a Continuation in Part (CIP) of U.S. patent application Ser. No. 17/256,052, filed on Dec. 24, 2020, which is the national stage of International Application No. PCT/EP2019/060586 filed Apr. 25, 2019, which was published in German under PCT Article 21 (2), and which in turn claims the benefit of European Patent Application No. EP 18000405.3 filed Apr. 25, 2018, and German Patent Application No. DE 10 2018 115 379.1 filed Jun. 26, 2018.

### FIELD

The present invention relates to a compound according to formula (I)

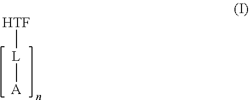

### BACKGROUND

Solar cells with the hybrid perovskite absorbing layer in a strikingly short period of time have surpassed 20% power conversion efficiency (PCE) limit, reaching the record efficiency of 22.7% (“NREL efficiency chart,” hwww.nrel.gov/pv/assets/images/efficiency-chart.png, 26 Jun. 2018). Published record results for the perovskite solar cells (PSCs) (W. S. Yang et al., Science 2017, 356, 1376-1379) were achieved in n-i-p (in literature often referred to as “regular” PSCs) configuration with a TiO₂ (compact and mesoporous layers) as an electron transporting material, deposited on transparent conductive oxide (TCO) substrate. For the p-i-n configuration (in literature often referred to as “inverted” PSCs), where on TCO first hole transporting materials (HTMs) are deposited, also over 20% efficiencies are reported (J. Zhao et al., Energy Environ. Sci. 2016, 9, 3650-3656 and M. Stolterfoht et al. Energy Environ. Sci. 2017, 10, 1530-1539) making it a good competitor. All these results inspire more research in this fast-developing field.

The p-i-n PSCs have several advantages in comparison to the more popular n-i-p architecture. First, high temperature annealing, required for the TiO₂ formation, is avoided. Second, they are known to have much less pronounced hysteresis, leading to virtually “hysteresis-free” devices (J. H. Heo et al., Energy Environ. Sci. 2015, 8, 1602-1608), even though it can still be detected under certain conditions (D. Bryant et al., J. Phys. Chem. Lett. 2015, 6, 3190-3194 and P. Calado, Nat. Commun. 2016, 7, 13831). Third, much cheaper copper can be used instead of gold as a metal contact layer (J. Zhao et al., J. Huang, Energy Environ. Sci. 2016, 9, 3650-3656). Next, no doping is needed for the charge selective contacts which might improve the long term stability as dopants of spiro-OMeTAD (2,2′,7,7′-tetrakis-(N,N-di-p-methoxyphenylamine)9,9′-spirobifluorene) are known to reduce stability. Finally, the p-i-n configuration was shown to enable higher tandem efficiency potential due to less parasitic absorption in the front contact (K. A. Bush et al., 23.6%-efficient monolithic perovskite/silicon tandem solar cells with improved stability, nature energy Vol. 2, 2017, 17009_1-7) and thus p-i-n PSCs have a great potential for the further development.

In a recent work (Stolterfoht et al., Energy Environ Sci. 2017, 10 (6), 1530) it was shown that a reduction of the HTM film thickness leads to the increase in the fill factor (FF). However, as the films are getting thinner, open-circuit voltage (V_{OC}) sharply drops, possibly due to the incomplete coverage of indium tin oxide (ITO), leading to a direct contact between perovskite and ITO.

Recently, several works were published by Y. Hou et.al. on the use of the phosphonic acid-based mixed C₆₀/organic self-assembling monolayer (SAM) as an electron transporting material in the n-i-p PSC instead of TiO₂ (Y. Hou et al., Adv. Mater. Interfaces 2017, 4, 1700007 and Y. Hou et al., Science 2017, 358, 1192-1197). Also, in a similar fashion siloxane-functionalized C₆₀ SAMs were used by P. Topolovsek et.al. (J. Mater. Chem. A 2017, 5, 11882-11893).

Based on the above-mentioned state of the art, the objective of the present invention is to provide means and methods to novel compounds for the formation of self-assembled monolayers in perovskite solar cells. This objective is attained by the subject-matter of the independent claims of the present specification, with further advantageous embodiments described in the dependent claims, examples, figures and general description of this specification.

### SUMMARY

A first aspect of the invention relates to a compound according to formula (I)

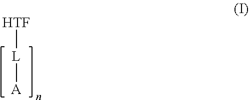

wherein
HTF is a hole transporting fragment selected from the group consisting of formulae

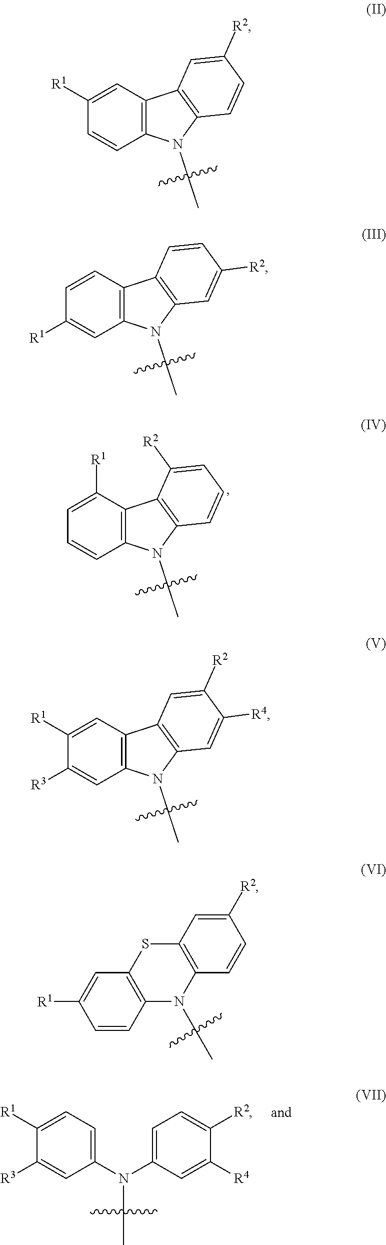

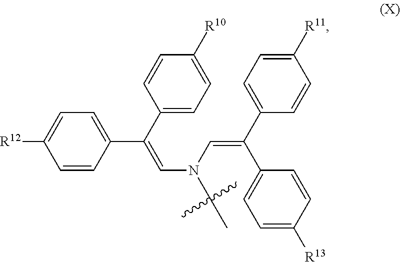

wherein
L is a linking fragment, selected from the group consisting of C₂ to C₁₆ alkyl and phenyl,
A is an anchor group, selected from the group consisting of H₂PO₃ and COOH,
R¹ to R⁴ are each independently selected from the group consisting of:
—H, -methyl, -tert-butyl, —OCH₃,
—CN, —F, —Cl, —Br, —I,
phenyl, thiophene,

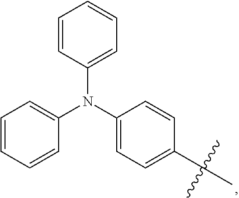 [SMILES: *c1ccc(N(c2ccccc2)c2ccccc2)cc1]

—NH₃⁺Br⁻, —NH₃⁺Cl⁻, —(CH₂)₂—NH₃⁺Br⁻, and —(CH₂)₂—NH₃⁺Cl⁻,
R¹⁰ to R¹³ are selected from the group consisting of —H, and —OCH₃
n is 1 or 2.

A second aspect of the invention relates to a composition comprising a compound according to the first aspect of the invention

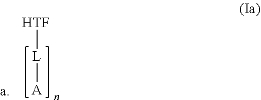

[x],
and a filler molecule FM_{[y]}, consisting of an anchor group selected from the group consisting of phosphonic acid, phosphoric acid, sulphonic acid, sulphuric acid, carboxylic acid and siloxane, a C₁ to C₁₈ alkyl, and a functional group selected from the group consisting of: methyl, halogen, amino, ammonium and sulphuric functional groups; wherein y equals (1−x), and wherein x is in the range of 0.02 to 1.

### BRIEF DESCRIPTION OF THE FIGURES

The invention is further illustrated by the following examples and figures, from which further embodiments and advantages can be drawn. These examples are meant to illustrate the invention but not to limit its scope.

FIG. 1 shows a schematic description of the photoluminescence (PL) experiment and chemical structure of a general carbazole-based SAM, with R denoting a substitution. The number 2 and 4 denotes the number of the linear C atoms between the phosphonic acid anchor group and the conjugated carbazole main fragment. The device stack further shows the hole-selective layers (commonly abbreviated as HTLs, “hole-transporting layers”) used for photoluminescence (PL) measurements. Firstly, the Quasi-Fermi level splitting (QFLS) was measured by absolute PL and then the PL stability of this perovskite composition prepared on indium tin oxide (ITO) substrates covered by the HTLs.

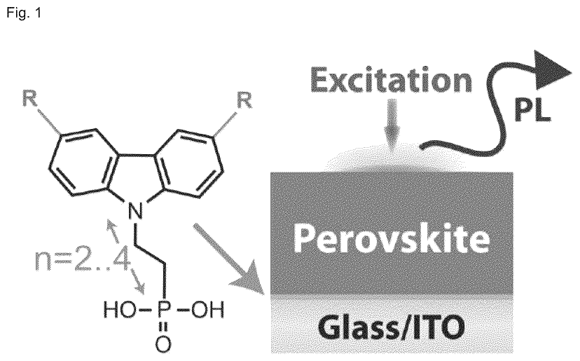

FIGS. 2A-2C show A) a comparison of fill factor values of perovskite solar cells (PSCs) with the stack glass/ITO/HTL/perovskite/C₆₀/SnO₂/Ag, triple-cation perovskite absorber with 1.68 eV bandgap. All data are from cells made from the same perovskite precursor and contact processing batch. The boxes indicate the 25/75 percentiles; the whiskers indicate the 10/90 percentiles. The FF is the major remaining parameter for which PSCs have not yet come close to the values of established solar cell technologies, with the ideality factor being one of the main properties that limit high-efficiency PSCs. MeO-2PACz and 2PACz led to FFs of up to 82%, whereas with Me-4PACz, the values were as high as 84%, representing around 93% of the radiative limit. B) J-V curves of the best cells of the batch in (A) and a J-V curve of a Me-4PACz cell from another batch with LiF interlayer between C₆₀ and perovskite. These were further compared to the best state-of-art compound PTAA. The comparison describes the superior performance of the SAM Me-4PACz reaching a V_{OC} of 1.234 V. C) Intensity-dependent open-circuit voltage V_{OC} with linear fits (dashed lines).

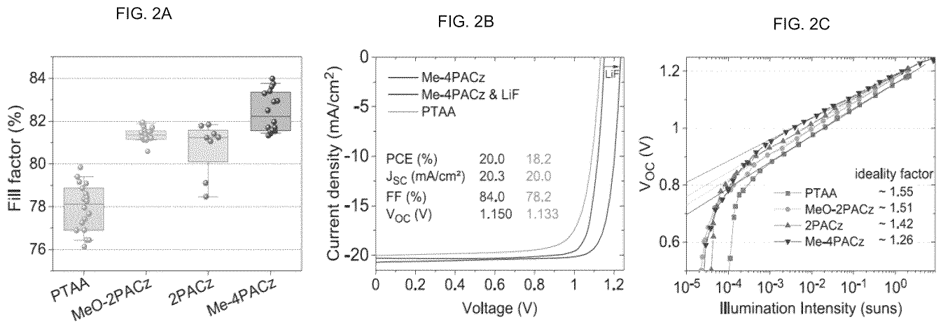

FIGS. 3A-3C show A) Pseudo-J-V curves reconstructed from intensity-dependent absolute photoluminescence (PL) measurements on the illustrated sample stack. To investigate the FF values without the influence of series resistance losses, the intensity-dependent absolute PL spectra were measured and QFLS values (or implied V_{OC}) were computed as a function of the illumination intensity. The derived data pairs of generation currents and implied V_{OC} values allowed the reconstruction of hypothetical, so-called pseudo J-V curves. The 2PACz and Me-4PACz curves almost coincide; the dashed lines represent pseudo-J-V curves from the sample variations including electron-selective C₆₀ layer, with which all curves are comparable because of the limiting nonradiative recombination at the C₆₀ interface. Both, 2PACz and Me-4PACz enabled high “pseudo-FF” (pFF) values of around 88%, which is a 96.8% of the detailed balance limit and similar to the value achieved on a bare quartz substrate. In turn, PTAA allowed for a pFF of only 85.6%. The combination of a high V_{OC} with low np was previously considered as challenging for PSCs, and it allowed to fabricate a perovskite single junction with a PCE of 20.8% with Me-4PACz and a perovskite band gap of 1.68 eV. This highlights how the SAMs formed a practically lossless interface between ITO and perovskite. When including a C₆₀ layer on top of the perovskite film, no differences between the studied HTLs for the implied V_{OC} and pFF were apparent (dashed lines), as the C₆₀ layer sets an implied V_{OC} limitation through high non-radiative recombination rates. B) Pseudo-J-V curves reconstructed from the measurements in (C). Here a counter electrode on the C₆₀ was used to overcome the limitation of the C₆₀ layer setting an implied V_{OC} limitation through high non-radiative recombination rates, underscoring the role of dipoles that Me-4PACz and 2PACz create on the ITO surface. A well-defined built-in potential can exist with the presence of a second electrode countering the ITO in this case, Ag or Cu. Thus, when reconstruction the J-Vs from the suns-V_{OC} measurements on full devices in FIG. 2C to extract the pFF, both 2PACz and Me-4PACz overcame the pFF and implied V_{OC} limitations imposed by the C₆₀ layer. C) Repartition of loss mechanisms lowering the cell's fill factor (FF) below the detailed balance limit, comparing poly [bis(4-phenyl)(2,4,6-trimethylphenyl)amine (PTAA) and Me-4PACz cells: nonradiative loss in neat material (=radiative FF limit minus pFF (pseudo fill factors) of neat film), nonradiative interface loss (=pFF of neat film minus pFF of fuel cell), and transport loss (=pFF of full cell minus FF of measure solar cell). In addition to non-radiative losses at the PTAA interface (red), the film thickness ˜10 nm, versus <1 nm with a SAM) and low conductivity of the PTAA led to greater transport losses than with Me-4PACz.

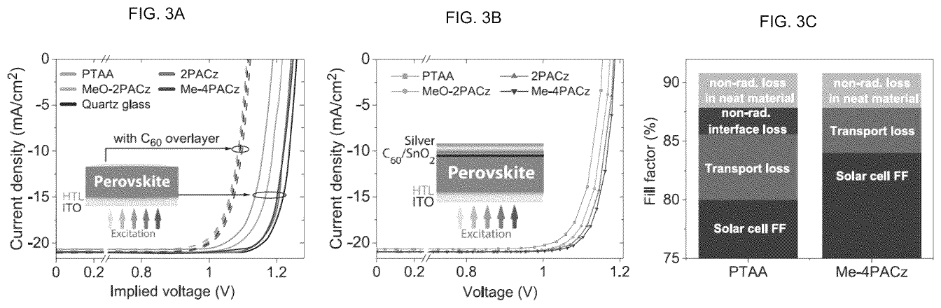

FIG. 4. shows long-term maximum power point (MPP) track using a dichromatic LED illumination of non-encapsulated solar cells in air at a controlled temperature of 25° C. and relative humidity of 30 to 40%. The data are normalised to the MPP average of the first 60 min of each individual track to account for measurement noise. Because of the fast degradation, the MPP track of the PTAA+LiF cell (74.5% after 90 h) is normalised to the first recorded value. The legend specifies each HTL and notes whether a LiF interlayer was used. The degradation for a perovskite-limited tandem cell with Me-4PACz+LiF showed 75.9% of its initial efficiency (29.13%) after 300 h. When substituting the Me-4PACz with PTAA, the PCE decreased to 74.5% or its initial PCE (25.9%) after only 90 h. Additionally, the cell was tracked with Me-4PACz as HTL without a LiF interlayer to test intrinsic stability of the HTL/perovskite combination. After 300 h, the cell still operated at 95.5% of its initial PCE. Comparing the result to state-of-the art stability tests of non-encapsulated tandem solar cells in ambient conditions, where the cells retained 90% of initial PCE after 61 h (Sahli et al.), and 92% after 100 h (Chen et al.), Me-4PACz tandem solar cells show superior operational stability.

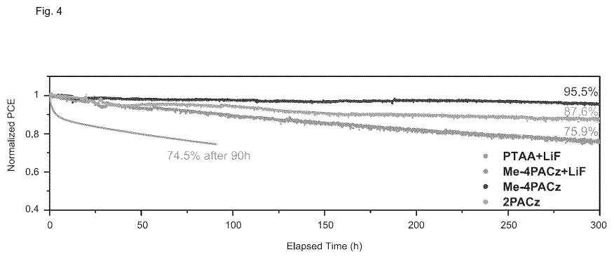

FIG. 5A shows a statistical representation of the J_{SC}, and PCE of opaque p-i-n perovskite solar cells (glass/ITO/SAM/1.68 triple-cation triple-halide perovskite/C₆₀/SnOx/Ag) using four different SAMs, i.e. V1608, V1609, V1610 and V1503. The highest overall power conversion efficiency (PCE) was obtained by using the SAMs V1609 and V1610. This is mainly due to their higher fill factor (FF) compared to devices using the SAMs V1608 and V1503.

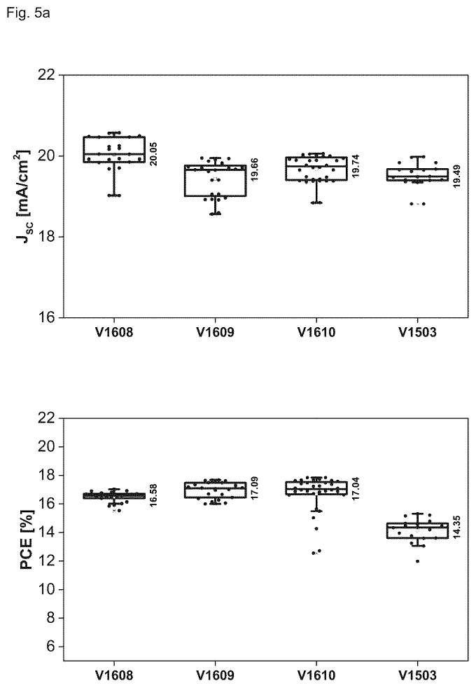

FIG. 5B shows a statistical representation of the V_{OC} and FF of opaque p-i-n perovskite solar cells (glass/ITO/SAM/1.68 eV triple-cation triple-halide perovskite/C₆₀/SnOx/Ag) using four different SAMs, i.e. V1608, V1609, V1610 and V1503. The V_{OC}-box plot additionally contains the quasi-Fermi level splitting (QFLS) calculated from photoluminescence (PL) measurements on solar cell partial stacks (glass/ITO/SAM/perovskite and glass/ITO/SAM/perovskite/C₆₀/SnOx). Although V1608 and V1503 show decent V_{OC} values in the opaque perovskite single-junction devices without a passivation for the perovskite/C₆₀ interface their performance is limited by the fill factor, which could be caused by e.g. an extraction barrier for holes. The QFLS results from PL measurements largely match the V_{OC} trends observed from the devices and indicate a significant reduction of the V_{OC} potential through the addition of the C₆₀/SnOx electron-transporting layer (ETL) stack.

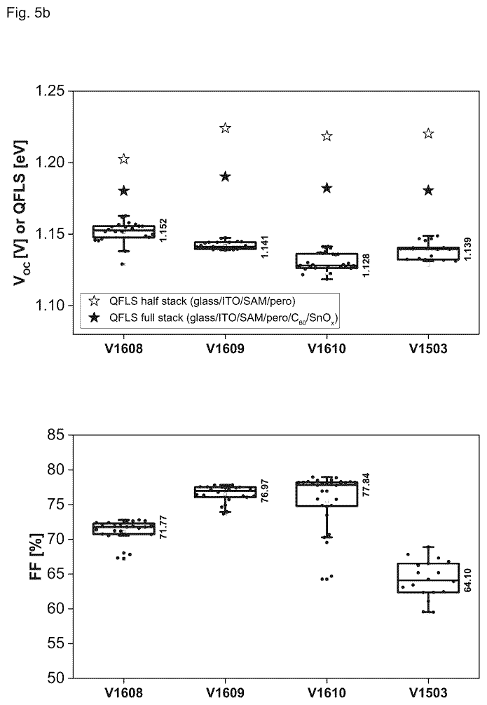

FIG. 6A shows a statistical representation of the J_{SC}, and PCE of opaque p-i-n solar cells (glass/ITO/SAM/1.68 eV triple-cation triple-halide perovskite/1 nm LiF/C₆₀/SnOx/Ag) using four different SAMs, i.e. V1608, V1609, V1610 and V1503 and using a thin LiF layer as interlayer for the perovskite/C₆₀ interface. A reduction in J_{SC} was observed when V1503 was used as hole-transport layer (HTL).

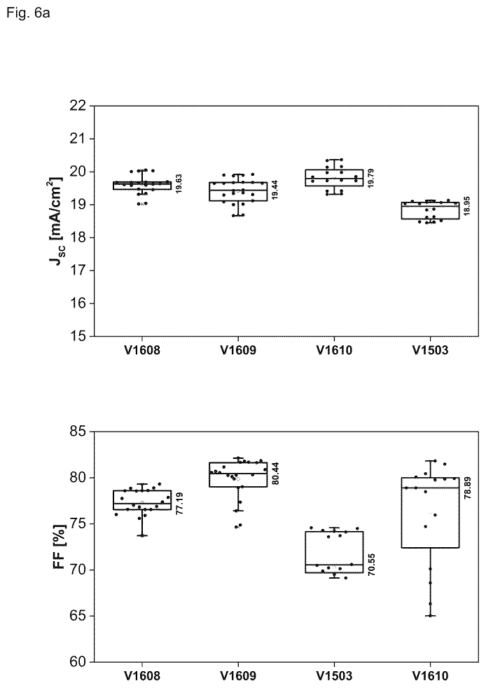

FIG. 6B shows a statistical representation of the V_{OC} and FF of opaque p-i-n solar cells (glass/ITO/SAM/1.68 eV triple-cation triple-halide perovskite/1 nm LiF/C₆₀/SnOx/Ag) using four different SAMs, i.e. V1608, V1609, V1610 and V1503 and using a thin LiF layer as interlayer for the perovskite/C₆₀ interface. The results confirm the lower FF obtained with V1608 and V1503. The devices showed very similar V_{OC} values for all tested SAMs.

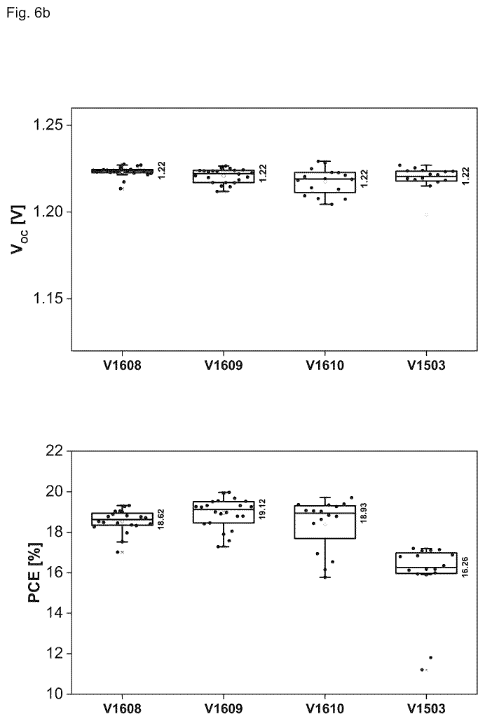

FIG. 7 shows a schematic of a monolithic tandem solar cell.

### DETAILED DESCRIPTION

### Terms and Definitions

### General

For purposes of interpreting this specification, the following definitions will apply and whenever appropriate, terms used in the singular will also include the plural and vice versa. In the event that any definition set forth below conflicts with any document incorporated herein by reference, the definition set forth shall control.

The terms “comprising”, “having”, “containing”, and “including”, and other similar forms, and grammatical equivalents thereof, as used herein, are intended to be equivalent in meaning and to be open-ended in that an item or items following any one of these words is not meant to be an exhaustive listing of such item or items, or meant to be limited to only the listed item or items. For example, an article “comprising” components A, B, and C can consist of (i.e., contain only) components A, B, and C, or can contain not only components A, B, and C but also one or more other components. As such, it is intended and understood that “comprises” and similar forms thereof, and grammatical equivalents thereof, include disclosure of embodiments of “consisting essentially of” or “consisting of.”

Where a range of values is provided, it is understood that each intervening value, to the tenth of the unit of the lower limit, unless the context clearly dictates otherwise, between the upper and lower limit of that range and any other stated or intervening value in that stated range, is encompassed within the disclosure, subject to any specifically excluded limit in the stated range. Where the stated range includes one or both of the limits, ranges excluding either or both of those included limits are also included in the disclosure.

Reference to “about” a value or parameter herein includes (and describes) variations that are directed to that value or parameter per se. For example, description referring to “about X” includes description of “X.”

As used herein, including in the appended claims, the singular forms “a”, “or” and “the” include plural referents unless the context clearly dictates otherwise.

“And/or” where used herein is to be taken as specific recitation of each of the two specified features or components with or without the other. Thus, the term “and/or” as used in a phrase such as “A and/or B” herein is intended to include “A and B,” “A or B,” “A” (alone), and “B” (alone). Likewise, the term “and/or” as used in a phrase such as “A, B, and/or C” is intended to encompass each of the following aspects: A, B, and C; A, B, or C; A or C; A or B; B or C; A and C; A and B; B and C; A (alone); B (alone); and C (alone).

Unless defined otherwise, all technical and scientific terms used herein have the same meaning as commonly understood by one of ordinary skill in the art (e.g organic synthesis). Standard techniques are used for chemical methods.

The formulae of the present specification follow the convention of organic chemistry to not show hydrogen atoms on carbon scaffolds. Carbon is tetravalent and bonds not shown are assumed to be hydrogen unless shown otherwise. Hydrogen can be exchanged for deuterium without changing the bulk chemical properties of the molecule.

The term perovskite, in the context of the present specification relates to the “perovskite structure” and not specifically to the perovskite material, CaTiO₃. For the purpose of this specification, “perovskite” encompasses and preferably relates to any material that has the same type of crystal structure as calcium titanium oxide and of materials in which the bivalent cation is replaced by two separate monovalent cations. The perovskite structure has the general stoichiometry AMX₃, where “A” and “M” are cations and “X” is an anion. The “A” and “M” cations can have a variety of charges and in the original Perovskite mineral (CaTiO₃), the A cation is divalent and the M cation is tetravalent. For the purpose of this invention, the perovskite formulae include structures having one (1), two (2), three (3) or four (4) cations, which may be of the same kind or different, and/or one or two (2) anions, and/or metal atoms carrying two or three positive charges, in accordance with the formulae presented elsewhere in this specification.

Further preferred, the organic-inorganic perovskite layer material of the optoelectronic and/or photoelectrochemical device comprises a perovskite-structure of any one of formulae below:
A¹A²A³A⁴MX₃, A¹A²A³MX₃, A¹A²MX₄; A¹MX₃; A¹A²N_{2/3}X₄; A¹N_{2/3}X₃; BN_{2/3}X₄; A¹₂NMX₆; BMX₄, wherein
   A¹, A², A³, A⁴ are either organic, monovalent cations or mixtures thereof that are independently selected from primary, secondary, tertiary or quaternary organic ammonium compounds, including N-containing heterorings and ring systems, A and A′ having independently from 1 to 60 carbons and 1 to 20 heteroatoms (like Methylammonium or Formamidinium), or inorganic cations (like Na, K, Rb, Cs).
   B is an organic, bivalent cation selected from primary, secondary, tertiary or quaternary organic ammonium compounds having from 1 to 60 carbons and 2-20 heteroatoms and having two positively charged nitrogen atoms;
   M is a divalent metal cation selected from the group consisting of Cu²⁺, Ni²⁺, Co²⁺, Fe²⁺, Mn²⁺, Cr²⁺, Pd²⁺, Cd²⁺, Ge²⁺, Sn²⁺, Pb²⁺, Eu²⁺, or Yb²⁺;
   N is selected from the group of Bi³⁺ and Sb³⁺; and,
   X is independently selected from Cl⁻, Br⁻, I⁻, NCS⁻, CN⁻, and NCO⁻. X can also be a mixture of the listed halides/anions.

### Specific

A first aspect of the invention relates to a compound according to formula (I)

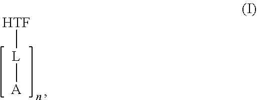

wherein
HTF is a hole transporting fragment selected from the group consisting of formulae

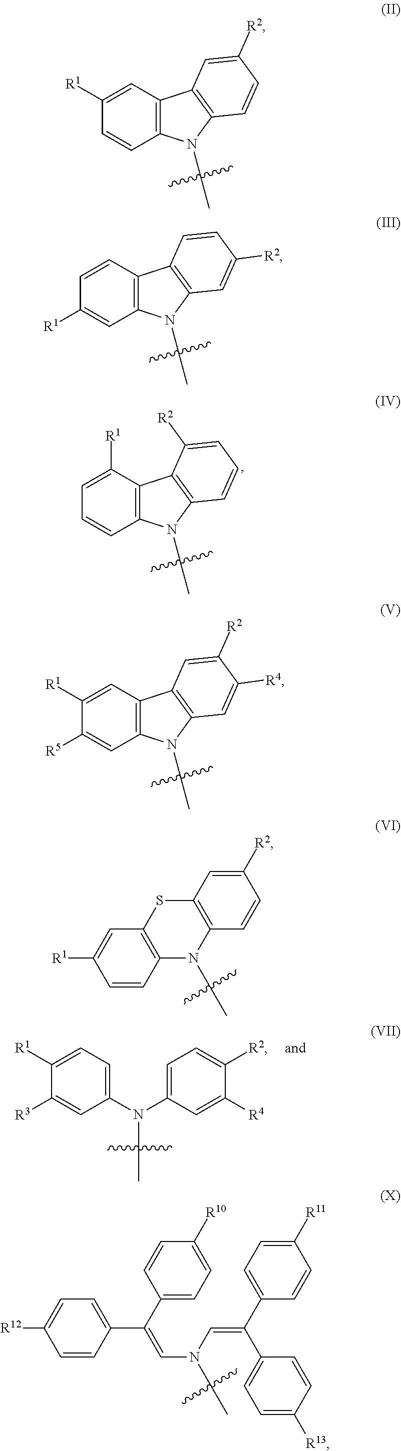

wherein
L is a linking fragment, selected from the group consisting of C₂ to C₁₆ alkyl and phenyl,
A is an anchor group, selected from the group consisting of H₂PO₃ and COOH,
R¹ to R⁴ are each independently selected from the group consisting of:
a. —H, -methyl, -tert-butyl, —OCH₃,
b. —CN, —F, —Cl, —Br, —I,
c. phenyl, thiophene,

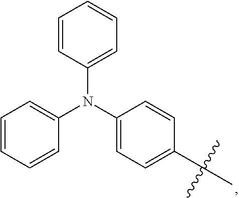 [SMILES: *c1ccc(N(c2ccccc2)c2ccccc2)cc1]

d. —NH₃⁺Br⁻, —NH₃⁺Cl⁻, —(CH₂)₂—NH₃⁺Br⁻, and —(CH₂)₂—NH₃⁺Cl⁻,
R¹⁰ to R¹³ are selected from the group consisting of —H, and —OCH₃
n is 1 or 2.

In certain embodiments, the compound is according to formula (I)

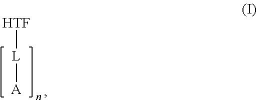

wherein
HTF is a hole transporting fragment selected from the group consisting of formulae

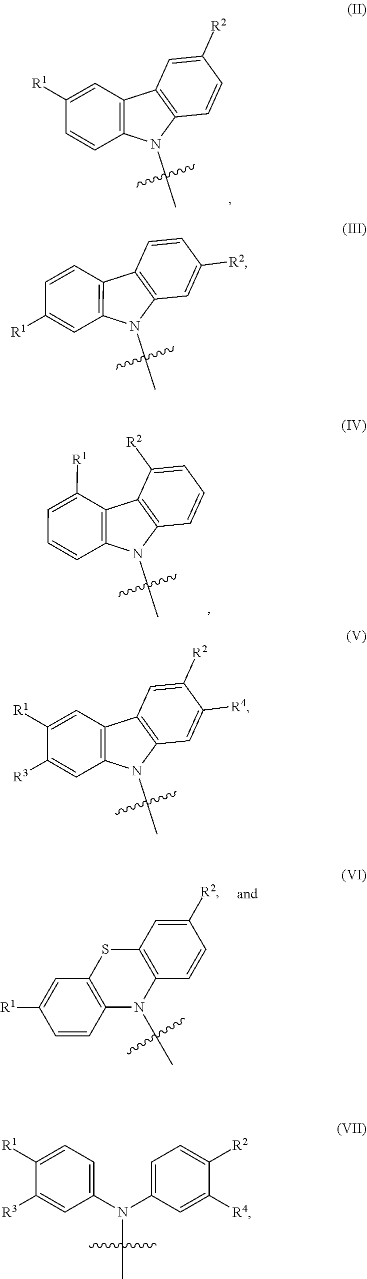

wherein
L is a linking fragment, selected from the group consisting of C₂ to C₁₆ alkyl and phenyl,
A is an anchor group, selected from the group consisting of H₂PO₃ and COOH,
R¹ to R⁴ are each independently selected from the group consisting of:
   —H, -methyl, -tert-butyl, —OCH₃,
   —CN, —F, —Cl, —Br, —I,
   phenyl, thiophene,

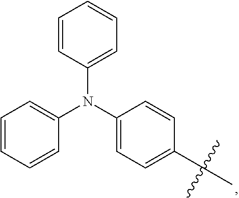 [SMILES: *c1ccc(N(c2ccccc2)c2ccccc2)cc1]

—NH₃⁺Br⁻, —NH₃⁺Cl⁻, —(CH₂)₂—NH₃⁺Br⁻, and —(CH₂)₂—NH₃⁺Cl⁻, and
n is 1 or 2.

In certain embodiments, R¹ to R⁴ are each independently selected from the group consisting of:
—H, -methyl, -tert-butyl, —OCH₃
—CN, —F, —Cl, —Br, —I,
phenyl, thiophene,
—(CH₂)₂—NH₃⁺Br⁻, and —(CH₂)₂—NH₃⁺Cl⁻,
In certain embodiments, wherein HTF is selected from the group consisting of formulae

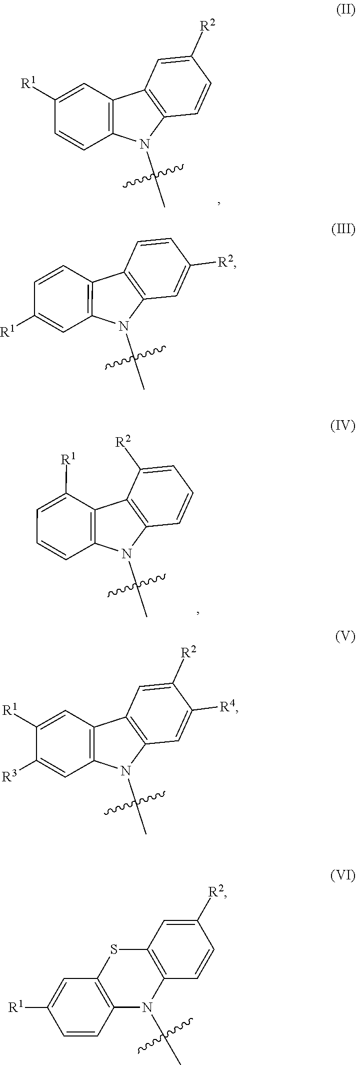

wherein
R¹ to R⁴ are each independently selected from the group consisting of:
   —H, -methyl, -tert-butyl, —OCH₃,
   —CN, —F, —Cl, —Br, —I,
   phenyl, thiophene,
   —(CH₂)₂—NH₃⁺Br⁻, and —(CH₂)₂—NH₃⁺Cl⁻.

In certain embodiments, L is selected from the group consisting of C₂ to C₆ alkyl and phenyl.

In certain embodiments, L is selected from the group consisting of C₂ to C₆ alkyl. In certain embodiments, L is a C₄ alkyl.

In certain embodiments, A is H₂PO₃.

In certain embodiments, the HTF is selected from the group consisting of any formulae:

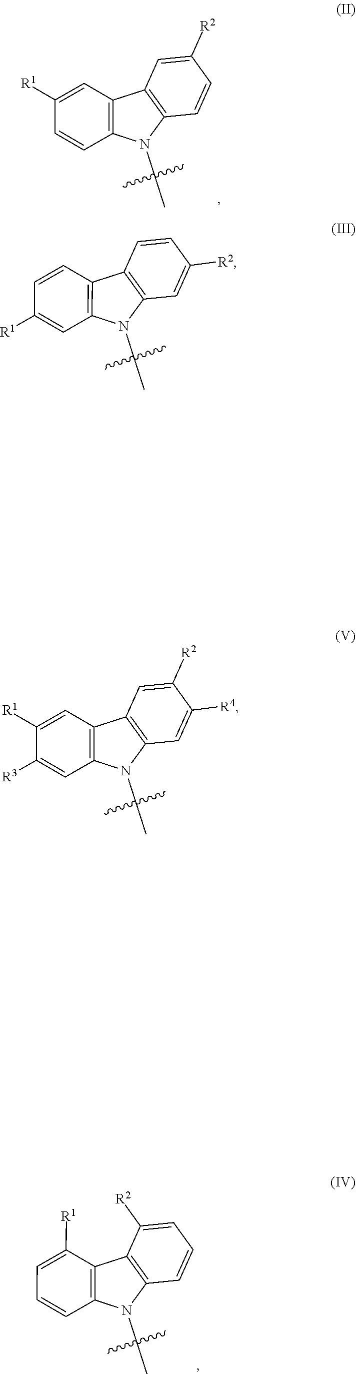

and wherein R¹ to R⁴ are each independently selected from the group consisting of:
—H, -methyl, -tert-butyl, —OCH₃,
—CN, —F, —Cl, —Br, —I,
phenyl, and thiophene.

In certain embodiments, the hole transport fragment HTF is selected is selected from the group consisting of any formulae:

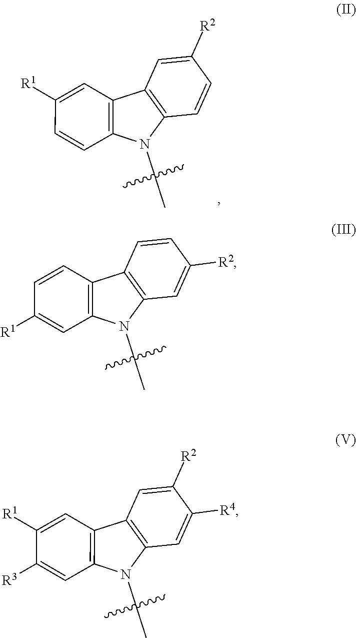

and wherein R¹ to R⁴ are each independently selected from the group consisting of:
—H, -methyl, -tert-butyl, —OCH₃
—CN, —F, —Cl, —Br, —I,
phenyl, and thiophene.

In certain embodiments, the compound is selected from the group consisting of:

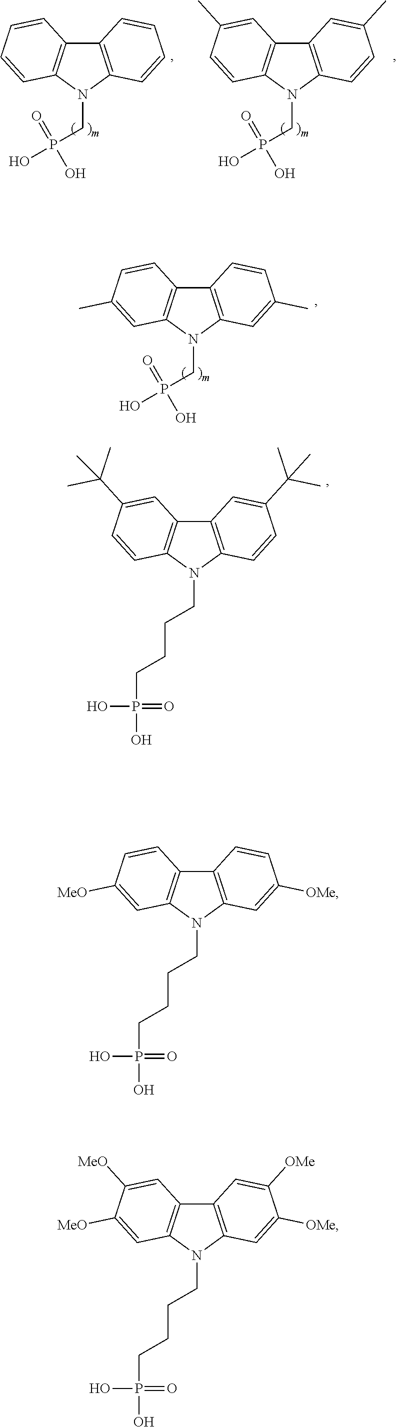

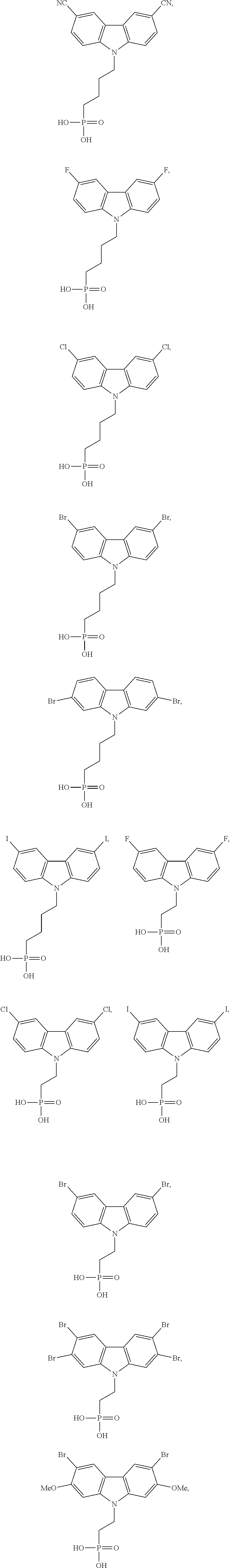

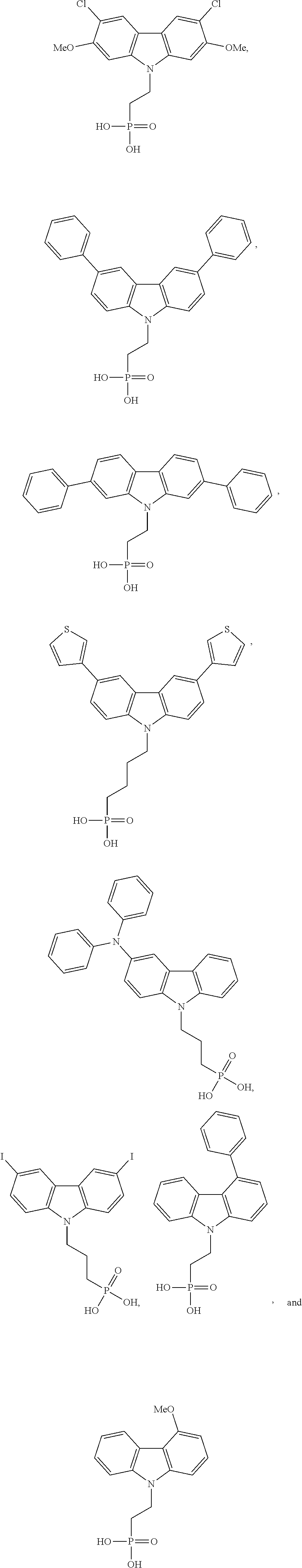

wherein m is an integer in the range of 2 to 6.

In certain embodiments, the compound is selected from the group consisting of:

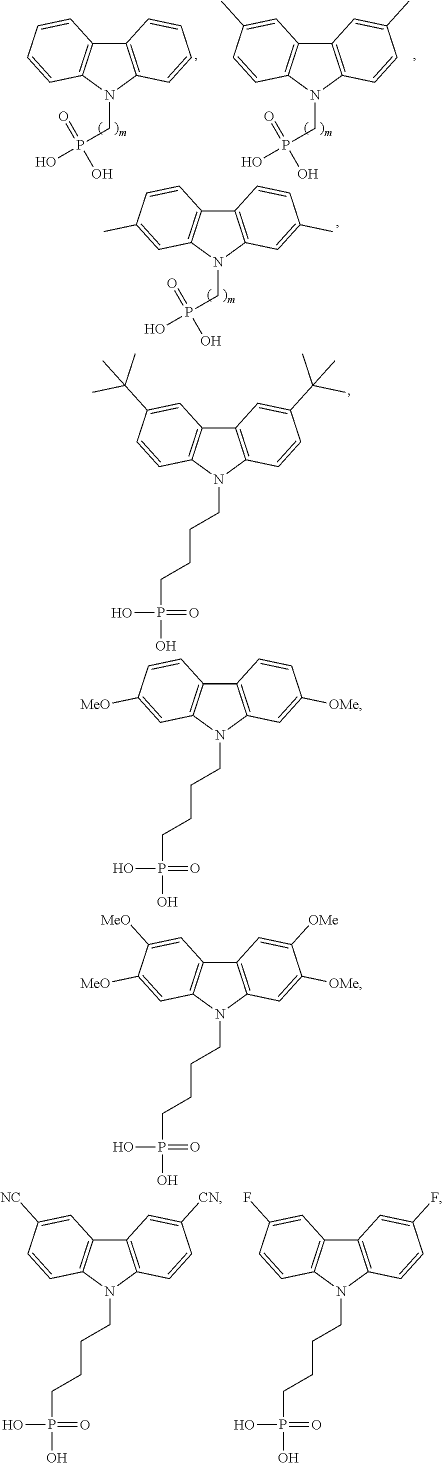

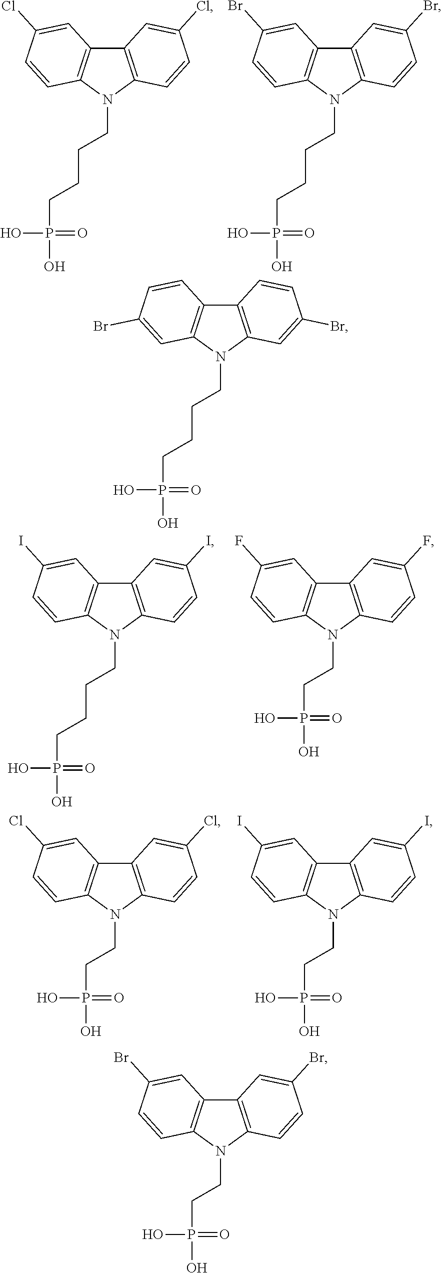

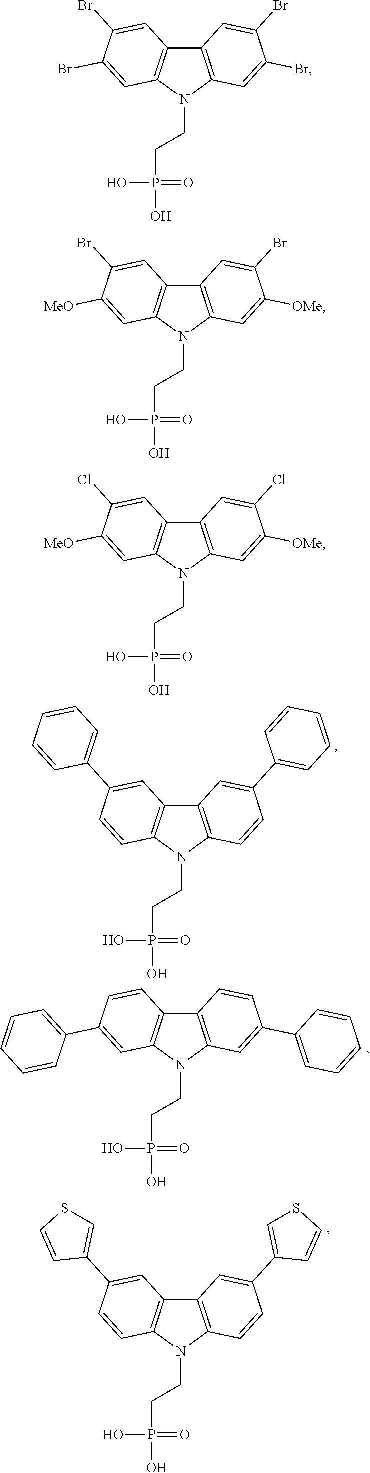

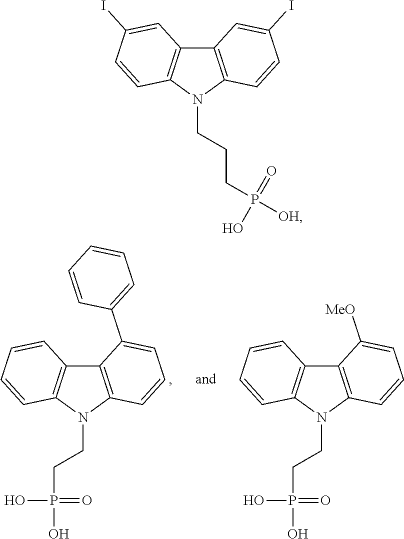

wherein m is an integer in the range of 2 to 6.

In certain embodiments, the compound is selected from the group consisting of:

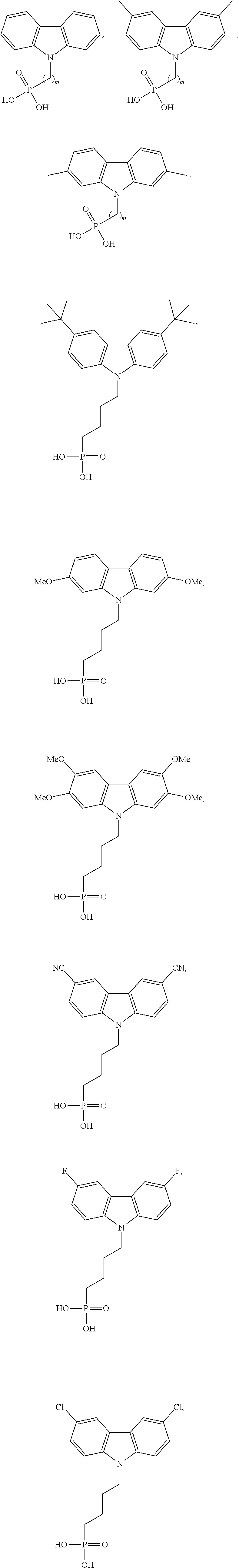

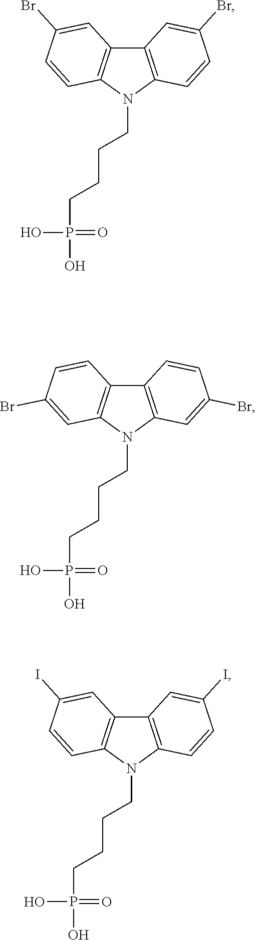

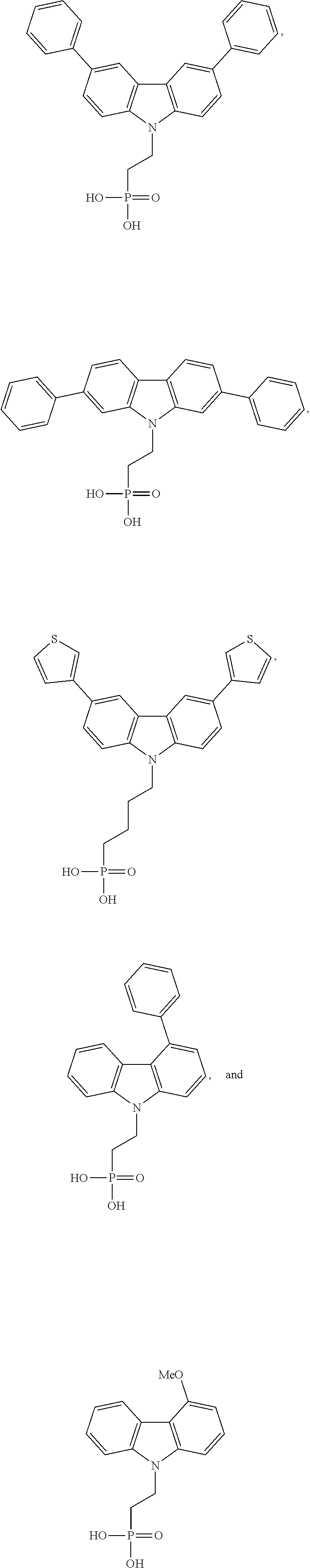

wherein m is an integer in the range of 4 to 6.

In certain embodiments, the compound is selected from the group consisting of:

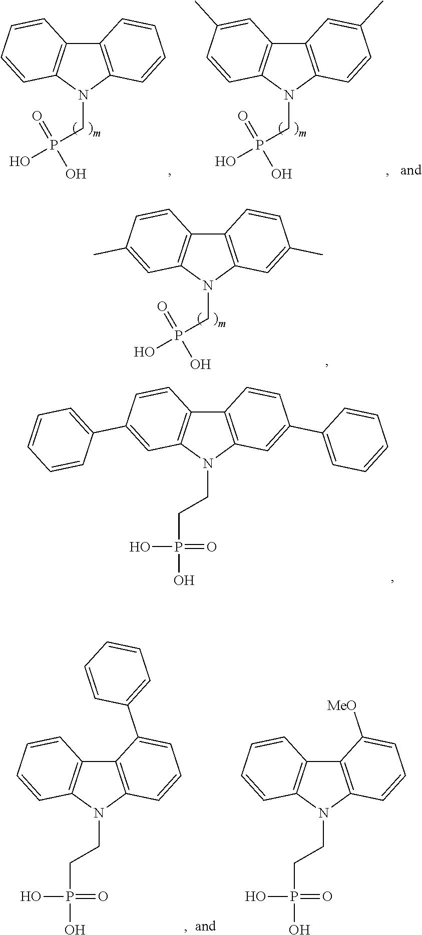

wherein m is an integer in the range of 4 to 6.

In certain embodiments, the compound is selected from the group consisting of:

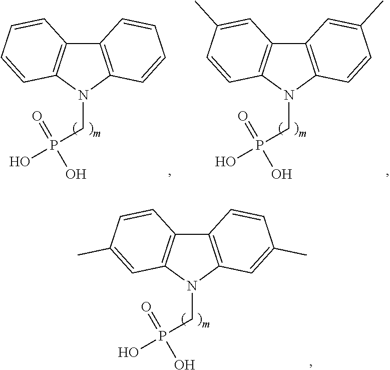

wherein m is an integer in the range of 4 to 6.

In certain embodiments, the compound is

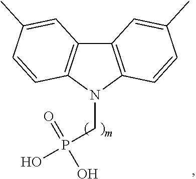

wherein m is 4.
[4-(3,6-dimethyl-9H-carbazol-9-yl)butyl]phosphonic acid (Me-4PACz) SAMs show that a fast hole extraction improves the ideality factor np, which is correlated to the fill factor (FF), which and hence charge extraction efficiency in perovskite solar cells and affects their efficiency. Generally, a lower ideality factor could achieve a higher open-circuit voltage V_{OC}, resulting in more efficient perovskite solar cells. The SAM provides both, fast extraction and efficient passivation at the hole-selective interface, a combination which slowed light-induced halide segregation of tandem-relevant perovskite composition with improved bandgap and hence higher single-junction device V_{OC} values. These improvements transferred into tandem devices allows to fabricate perovskite/silicon tandem solar cells with increased power conversion efficiency (PCE) compared to the state of the art perovskite solar cells.

A second aspect of the invention relates to a composition comprising a compound according to the first aspect of the invention

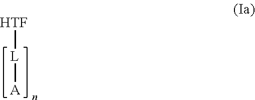

[x],
and a filler molecule FM_{[y]}, consisting of an anchor group selected from the group consisting of phosphonic acid, phosphoric acid, sulphonic acid, sulphuric acid, carboxylic acid and siloxane, a C₁ to C₁₈ alkyl, and a functional group selected from the group consisting of: methyl, halogen, amino, ammonium and sulphuric functional groups; wherein y equals (1−x), and wherein x is in the range of 0.02 to 1.

Wherever alternatives for single separable features are laid out herein as “embodiments”, it is to be understood that such alternatives may be combined freely to form discrete embodiments of the invention disclosed herein

### EXAMPLES

### Example 1: [3-(9H-Carbazol-9-yl)propyl]phosphonic acid (V1300)

### 9-(3-Bromopropyl)-9H-carbazole

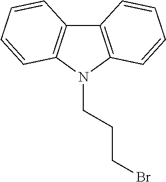 [SMILES: BrCCCn1c2ccccc2c2ccccc21]

9H-Carbazole (1 g, 5.98 mmol) was dissolved in toluene (13 mL). 50% KOH solution (13 mL), 1,3-dibromopropane (1.12 mL, 11.91 mmol) and catalytic amount of tetrabutylammonium bromide were added afterward. After 24 hours at 50° C., an additional 1,3-dibromopropane (1.12 mL) and toluene (8 mL) were added. After the reaction was complete (TLC, acetone:n-hexane 1:4), the mixture was extracted with ethyl acetate, the organic layer was dried with anhydrous sodium sulfate, and the solvent was removed using a vacuum rotary evaporator. The product is purified by column chromatography (eluent, acetone:n-hexane 3:22) to yield 1.2 g (70%) of white powder. Anal. Calcd. for C₁₅H₁₄BrN, %: C, 62.52, H, 4.90, N, 4.86, found, %: C, 62.47, H, 4.77, N, 4.78.

### Diethyl [3-(9H-carbazol-9-yl)propyl]phosphonate

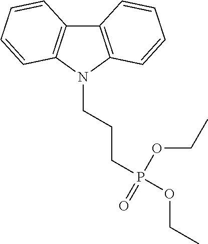 [SMILES: CCOP(=O)(CCCn1c2ccccc2c2ccccc21)OCC]

9-(3-Bromopropyl)-9H-carbazole (0.5 g, 1.74 mmol) was dissolved in triethyl phosphite (5 ml, 31.1 mmol). The reaction mixture was refluxed for 24 hours. After the reaction was complete (TLC, acetone:n-hexane, 1:4) triethyl phosphite was distilled off and the crude solution was purified by column chromatography (eluent, n-hexane) to yield 0.59 g (99%) of a clear liquid. Anal. Calcd. for C₁₉H₂₄NO₃P, %: C. 66.07, H. 7.00, N. 4.06, found, %: C, 65.95, H, 6.93, N, 4.01.

### [3-(9H-Carbazol-9-yl)propyl]phosphonic acid (V1300)

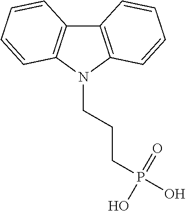 [SMILES: O=P(O)(O)CCCn1c2ccccc2c2ccccc21]

1.71 mmol) was dissolved in anhydrous 1,4-dioxane (20 ml) and bromotrimethylsilane (3 ml) was added dropwise. The reaction mixture was left under argon atmosphere at room temperature for 24 hours. After reaction was completed (TLC: n-hexane:acetone 1:4) a portion of the solvent was distilled off under reduced pressure. A few drops of distilled water were added dropwise, until the reaction solution becomes opaque, and some white precipitate began to form. The precipitate was filtered off and washed with isopropyl alcohol to yield 0.38 g (77%) of white crystals. Anal. Calcd. for C₁₅H₁₆NO₃P. %: C. 62.28, H. 5.58, N. 4.84. found, %: C. 62.16, H. 5.43, N. 4.78;

¹H NMR (400 MHZ. (CD₃)₂SO) δ 8.15 (d, J=7.7 Hz, 2H), 7.65 (d, J=8.2 Hz. 2H), 7.45 (t, J=7.6 Hz, 2H), 7.20 (t, J=7.4 Hz, 2H), 4.48 (t, J=6.8 Hz, 2H), 2.08-1.88 (m, 2H), 1.57 (m, 2H);

¹³C NMR (101 MHZ. (CD₃)₂SO) δ 139.99, 125.71, 122.03, 120.29, 118.73, 109.31, 42.46 (d, J=17.2 Hz. N—CH₂), 25.02 (d, J=137.3 Hz. CH₂). 22.66 (d, J=4.4 Hz. P—CH₂).

### Example 2: (5-(9H-Carbazol-9-yl)pentyl)phosphonic acid (V1302)

### 9-(5-Bromopentyl)-9H-carbazole

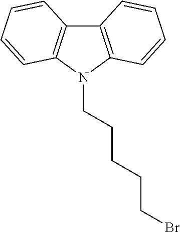 [SMILES: BrCCCCCn1c2ccccc2c2ccccc21]

9H-Carbazole (1 g. 5.98 mmol) was dissolved in toluene (13 mL). 50% KOH solution (13 mL), 1,3-dibromopentane (1.43 ml, 12 mmol) and catalytic amount of tetrabutylammonium bromide were added afterward. After 24 hours at room temperature, an additional 1,3-dibromopentane (1.6 ml) and was added. After the reaction was complete (TLC, acetone:n-hexane 1:4), the mixture was extracted with ethyl acetate, the organic layer was dried with anhydrous sodium sulfate, and the solvent was removed using a vacuum rotary evaporator. The product is purified by column chromatography (eluent, acetone:n-hexane 3:22) to yield 1.45 g (77%) of white powder. Anal. Calcd. For C₁₇H₁₈BrN. %: C, 64.57, H, 5.74, N, 4.43. found, %: C, 64.52, H, 5.69, N, 4.38.

### Diethyl (5-(9H-carbazol-9-yl)pentyl)phosphonate

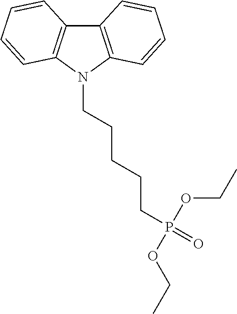 [SMILES: CCOP(=O)(CCCCCn1c2ccccc2c2ccccc21)OCC]

9-(5-Bromopentyl)-9H (1.45 g. 4.59 mmol) was dissolved in triethyl phosphite (14.5 ml, 90.1 mmol). The reaction mixture was refluxed for 24 hours. After the reaction was complete (TLC, acetone:n-hexane, 7:18) triethyl phosphite was distilled off and the crude solution was purified by column chromatography (eluent, acetone:n-hexane, 1:4) to yield 1.64 g (96%) of a clear liquid. Anal. Calcd. for C₂₁H₂₈NO₃P, %: C, 67.54, H, 7.56, N, 3.75, found, %: C, 67.44, H, 7.42, N, 3.68.

### (5-(9H-Carbazol-9-yl)pentyl)phosphonic acid (V1302)

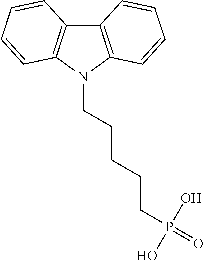 [SMILES: O=P(O)(O)CCCCCn1c2ccccc2c2ccccc21]

Diethyl (5-(9H-carbazol-9-yl)pentyl)phosphonate (0.4 g, 1.07 mmol) was dissolved in anhydrous 1,4-dioxane (20 ml) and bromotrimethylsilane (1.2 ml) was added dropwise. The reaction mixture was left under argon atmosphere at room temperature for 24 hours. After reaction was completed (TLC: n-hexane:acetone 1:4) a portion of the solvent was distilled off under reduced pressure. A few drops of distilled water were added dropwise, until reaction solution becomes opaque and some white precipitate began to form. The precipitate was filtered off and washed with isopropyl alcohol to yield 0.27 g (79%) of white crystals.

Anal. Calcd. for C₁₇H₂₀NO₃P. %: C. 64.35, H. 6.35, N. 4.41, found, %: C, 63.25. H, 6.11. N, 4.54.

¹H NMR (400 MHZ, (CD₃)₂SO) δ 8.14 (d, J=7.7 Hz, 2H), 7.58 (d, J=8.2 Hz, 2H), 7.44 (t, J=7.6 Hz, 2H), 7.19 (t, J=7.4 Hz, 2H), 4.41-4.32 (m, 2H), 1.81-1.70 (m, 2H), 1.58-1.31 (m, 6H).

¹³C NMR (101 MHZ, (CD₃)₂SO) δ 139.94, 125.67, 122.02, 120.27, 118.63, 109.18, 67.03, 59.76, 42.11, 28.14, 22.55.

### Example 3: (16-(9H-Carbazol-9-yl)decahexyl)phosphonic acid (V1304)

### 9-(16-bromodecahexyl)-9H-carbazole

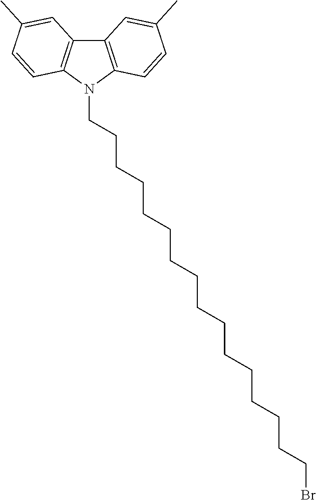 [SMILES: Cc1ccc2c(c1)c1cc(C)ccc1n2CCCCCCCCCCCCCCCCBr]

9H-Carbazole (0.9 g, 5.4 mmol) was dissolved in toluene (11.7 ml). 50% KOH solution (11.7 ml), 1,3-dibromohexile (2.07 g, 5.4 mmol) and catalytic amount of tetrabutylammonium bromide were added afterward and left for 24 hours at room temperature. After the reaction was complete (TLC, acetone:n-hexane 1:4), the mixture was extracted with ethyl acetate, the organic layer was dried with anhydrous sodium sulfate, and the solvent was removed using a vacuum rotary evaporator. The product is purified by column chromatography (eluent, acetone:n-hexane 1:24) to yield 0.93 g (37%) of white powder. Anal. Calcd. for C₂₈H₄₀BrN, %: C, 71.47, H, 8.57, N, 2.98, found. % C, 71.58, H, 8.63, N, 2.91.

### Diethyl (16-(9H-carbazol-9-yl)decahexyl)phosphonate

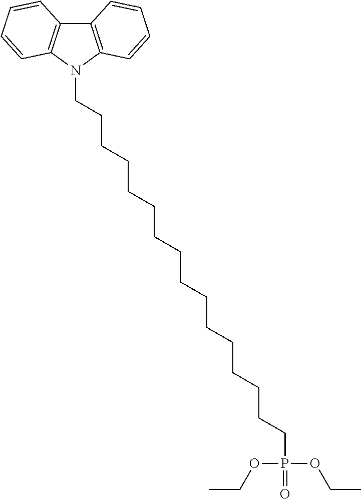 [SMILES: CCOP(=O)(CCCCCCCCCCCCCCCCn1c2ccccc2c2ccccc21)OCC]

9-(16-bromodecahexyl)-9H-carbazole (0.93 g, 1.97 mmol) was dissolved in triethyl phosphite (9.3 ml, 57.8 mmol). The reaction mixture was refluxed for 24 hours. After the reaction was complete (TLC, acetone:n-hexane, 7:18) triethyl phosphite was distilled off and the crude solution was purified by column chromatography (eluent, n-hexane) to yield 1.02 g (98%) of a clear liquid.

Anal. Calcd. for C₃₂H₅₀NO₃P, %: C. 72.83, H. 9.55, N. 2.65, found, %: C, 72.79, H, 9.62, N, 2.47.

### (16-(9H-Carbazol-9-yl)decahexyl)phosphonic acid (V1304)

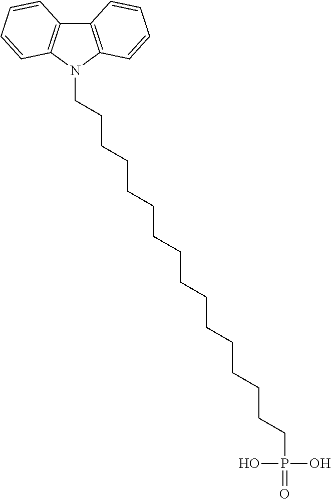 [SMILES: O=P(O)(O)CCCCCCCCCCCCCCCCn1c2ccccc2c2ccccc21]

Diethyl (16-(9H-carbazol-9-yl)decahexyl)phosphonate (0.9 g, 1.71 mol) was dissolved in anhydrous 1,4-dioxane (30 ml) and Bromotrimethylsilane (3 ml) was added dropwise. The reaction mixture was left under argon atmosphere at room temperature for 24 hours. After reaction was completed (TLC: n-hexane: acetone 1:4) a portion of the solvent was distilled off under reduced pressure. A few drops of distilled water were added dropwise, until the reaction solution becomes opaque, and some white precipitate began to form. The precipitate was filtered off and washed with isopropyl alcohol to yield 0.2 g (25%) of white crystals.

Anal. Calcd. for C₂₈H₄₂NO₃P, %: C, 71.31, H, 8.98, N, 2.97, found, %: C, 71.29, H, 8.89, N, 2.85.

¹H NMR (400 MHZ, CD₃)₂SO) δ 8.14 (d, J=7.7 Hz, 2H), 7.58 (d, J=8.2 Hz, 2H), 7.44 (t, J=7.6 Hz, 2H), 7.18 (t, J=7.4 Hz, 2H), 4.38 (t, J=7.0 Hz, 2H), 1.75 (m, 2H), 1.59-1.38 (m, 4H), 1.34-1.11 (m, 24H).

¹³C NMR (101 MHZ, CD₃)₂SO) δ 139.97, 125.61, 121.99, 120.24, 118.58, 109.21, 79.33, 42.17, 30.69, 29.03, 29.01, 28.99, 28.94, 28.89, 28.88, 28.87, 28.72, 28.60, 28.44, 28.32, 26.44, 22.75.

### Example 4: [3-(3,6-dimethyl-9H-carbazol-9-yl)propyl]phosphonic acid (V1231)

### 3,6-dimethyl-9H-carbazole

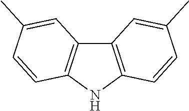

6-dibromo-9H-carbazole (10 g, 30.77 mmol) and 1,3-bis-(diphenylphosphino)dichloronickel(II) (Ni(dppp)₂Cl₂) (2.5 g, 4.62 mmol) were dissolved in 700 ml of absolute diethyl ether under argon atmosphere. After 15 min, to the purple red suspension, 40.9 ml of 3 M CH₃MgBr solution in diethyl ether (123.08 mmol) over a period of 60 min was added, yielding a brown and clear solution. Afterwards, the reaction mixture was refluxed for 5 h (TLC, acetone:n-hexane 1:24 v/v), cooled to room temperature and quenched with 100 ml of saturated aqueous NH₄Cl solution. The organic phase was extracted three times with 200 ml of saturated aqueous Na₂CO₃ solution, three times with 200 ml of water and finally, three times with 200 ml of saturated aqueous NaCl solution. The organic layer was dried over anhydrous Na₂SO₄, and the solvent was distilled off under reduced pressure. The crude product was purified by column chromatography (acetone: n-hexane 1:24 v/v) to give 3.5 g (58%) of white crystals. M.p. 218-219° C. Anal. calcd for C₁₄H₁₃N, %: C, 86.12, H, 6.71, N, 7.17, found, %: C, 85.91, H, 6.82, N, 7.27.

### 9-(3-bromopropyl)-3,6-dimethyl-9H-carbazole

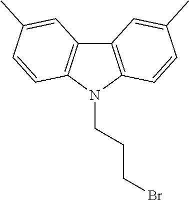

1,3-dibromopropane (8 ml, 78.46 mmol); tetrabuthylammonium bromide (0.148 g, 0.46 mmol) and 50% KOH aqueous solution (0.86 ml, 15.35 mmol) were added subsequently. The reaction was stirred at 55° C. overnight (TLC, acetone:n-hexane 2:23 v/v). After completion of the reaction, the extraction was done with dichloromethane. The organic layer was dried over anhydrous Na₂SO₄, and the solvent was distilled off under reduced pressure. The crude product was purified by column chromatography (acetone n-hexane 1:49 v/v) to give 0.85 g (89%) of white powder. Anal. calcd for C₁₇H₁₈BrN, %: C, 64.57, H, 5.74, N, 4.43, found, %: C, 64.72, H, 5.95, N, 4.26

### Diethyl [3-(3,6-dimethyl-9H-carbazol-9-yl)propyl]phosphonate

9-(3-bromopropyl)-3,6-dimethyl-9H-carbazole (0.6 g, 1.90 mmol) was dissolved in triethylphosphite (9 ml, 52.49 mmol), and the reaction mixture was refluxed overnight. triethylphosphite was distilled off under reduced pressure. The crude product was purified by column chromatography (acetone/n-hexane 1:4 v/v) to give 0.65 g (92%) of yellowish resin. Anal. calcd for C₂₁H₂₈NO₃P, %: C, 67.54, H, 7.56, N, 3.75, found, %: C, 67.41, H, 7.52, N, 3.63.

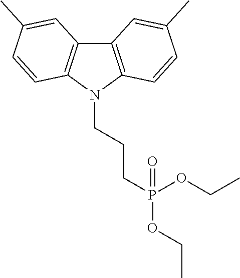 [SMILES: CCOP(=O)(CCCn1c2ccc(C)cc2c2cc(C)ccc21)OCC]

### [3-(3,6-dimethyl-9H-carbazol-9-yl)propyl]phosphonic acid (V1231)

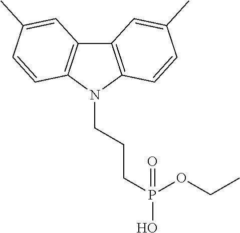 [SMILES: CCOP(=O)(O)CCCn1c2ccc(C)cc2c2cc(C)ccc21]

Diethyl [3-(2,6-dimethyl-9H-carbazol-9-yl)propyl]phosphonate (0.6 g, 1.61 mmol) was dissolved in anhydrous 1,4-dioxane (20 ml) under argon atmosphere, followed by dropwise addition of bromotrimethylsilane (2.12 ml, 16.07 mmol). The reaction was stirred for 22 h at 25° C. under argon atmosphere. Afterwards, methanol (3 ml) was added, and stirring continued for 3 h. Finally, distilled water was added dropwise (15 ml), until the solution became opaque, and it was stirred overnight. The product was filtered off and washed with water dissolved in tetrahydrofuran (1 ml) and precipitated into n-hexane (15 ml); the precipitate was filtered off and washed with n-hexane to give 0.430 g (85%) of white powder. M.p. 201-203° C.

Anal. calcd for C₁₇H₂₀NO₃P, %: C, 64.35, H, 6.35, N, 4.41, found, %: C, 64.18, H, 6.47, N, 4.55.

¹H NMR (400 MHZ, DMSO-d₆) δ 7.89 (s, 2H, Ht), 7.48 (d, J=8.3 Hz, 2H, Ht), 7.24 (d, J=8.3 Hz, 2H, Ht), 4.39 (t, J=7.0 Hz, 2H, NCH₂), 2.47 (s, 6H, 2×CH₃), 2.01-1.86 (m, 2H, CH₂), 1.56-1.43 (m, 2H, CH₂).

¹³C NMR (100 MHZ, DMSO-d₆) δ 138.60, 127.17, 126.83, 121.98, 120.00, 108.98, 42.52 (d, ³J_{(C,P)}=17.2 Hz), 25.05 (d, ¹J_{(C,P)}=137.8 Hz), 22.67 (d, ²J_{(C,P)}=3.6 Hz), 21.05.

### Example 5: [9-(3,6-dimethyl-9H-carbazol-9-yl)nonyl]phosphonic acid (V1234)

### 9-(9-bromononyl)-3,6-dimethyl-9H-carbazole

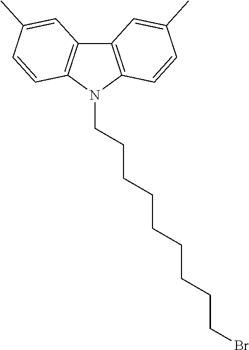 [SMILES: Cc1ccc2c(c1)c1cc(C)ccc1n2CCCCCCCCCBr]

3,6-dimethyl-9H-carbazole (0.6 g, 3.07 mmol) was dissolved in 1,9-(0.148 g, 0.46 mmol) and 50% KOH aqueous solution (0.86 ml, 15.35 mmol) were added subsequently. The reaction was stirred at 60° C. overnight (TLC, acetone:n-hexane 1:24 v/v). After completion of the reaction, the extraction was done with dichloromethane. The organic layer was dried over anhydrous Na₂SO₄, and the solvent was distilled off under reduced pressure. The crude product was purified by column chromatography (acetone n-hexane 1:249 v/v) to give 1.08 g (87%) of white material. Anal. calcd for C₂₃H₃₀BrN, %: C, 68.99, H, 7.55, N, 3.50, found, %: C, 69.15, H, 7.38, N, 3.69

### Diethyl [9-(3,6-dimethyl-9H-carbazol-9-yl)nonyl]phosphonate

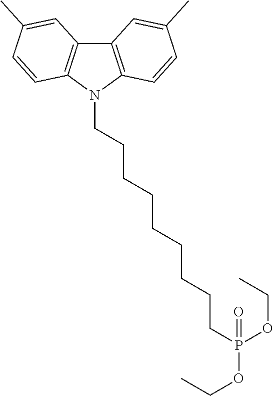 [SMILES: CCOP(=O)(CCCCCCCCCn1c2ccc(C)cc2c2cc(C)ccc21)OCC]

9-(9-bromononyl)-3,6-dimethyl-9H-carbazole (1 g, 2.50 mmol) was dissolved in triethylphosphite (10 ml, 58.32 mmol), and the reaction mixture was refluxed overnight. After reaction completion (TLC, acetone:n-hexane 6:19 v/v), the triethylphosphite was distilled off under reduced pressure. The crude product was purified by column chromatography (acetone:n-hexane 4:21 v/v) to give 1.02 g (89%) of yellowish resin. Anal. calcd for C₂₇H₄₀NO₃P, %: C, 70.87, H, 8.81, N, 3.06, found, %: C, 71.11, H, 8.98, N, 2.95.

### [9-(3,6-dimethyl-9H-carbazol-9-yl)nonyl]phosphonic acid (V1234)

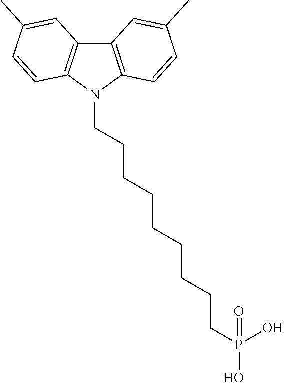 [SMILES: Cc1ccc2c(c1)c1cc(C)ccc1n2CCCCCCCCCP(=O)(O)O]

Diethyl [9-(3,6-dimethyl-9H-carbazol-9-yl)nonyl]phosphonate (0.8 g, 1.75 mmol) was dissolved in anhydrous 1,4-dioxane (25 ml) under argon atmosphere, followed by dropwise addition of bromotrimethylsilane (2.3 ml, 17.48 mmol). The reaction was stirred for 22 h at 25° C. under argon atmosphere. Afterwards, methanol (3 ml) was added, and stirring continued for 3 h. Finally, distilled water was added dropwise (20 ml), until the solution became opaque, and it was stirred overnight. The product was filtered off and washed with water dissolved in tetrahydrofuran (2 ml) and precipitated into n-hexane (25 ml); the precipitate was filtered off and washed with n-hexane to give 0.610 g (87%) of white powder. M.p. 63-65° C.

Anal. calcd for C₂₃H₃₂NO₃P, %: C, 68.81, H, 8.03, N, 3.49, found, %: C, 68.98, H, 7.89, N, 3.65.

¹H NMR (400 MHZ, DMSO-d₆) δ 7.86 (s, 2H, Ht), 7.39 (d, J=8.3 Hz, 2H, Ht), 7.21 (d, J=8.2 Hz, 2H, Ht), 4.26 (t, J=7.1 Hz, 2H, NCH₂), 2.45 (s, 6H, 2×HtCH₃), 1.78-1.61 (m, 2H, CH₂), 1.53-1.35 (m, 4H, 2× CH₂), 1.29-1.07 (m, 10H, 5× CH₂).

¹³C NMR (100 MHZ, DMSO-d₆) δ 138.56, 126.97, 126.73, 121.94, 119.94, 108.82, 42.18, 30.18, 28.84, 28.77, 28.64, 28.49, 26.93, 26.47, 22.76, 21.03.

### Example 6: (2-(2,7-dimethyl-9H-carbazol-9-yl)ethyl)phosphonic acid (V1609)

### 9-(2-bromoethyl)-2,7-dimethyl-9H-carbazole

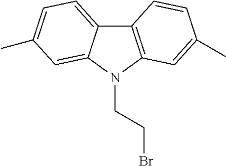

3-Bromo-9-(4-bromophenyl)-9H-carbazole (0.78 g, 0.0019 mol) was dissolved in 1,2-Dibromoethane (8 ml). After, 50% KOH solution (10 ml) and Tetrabutylammonium bromide (0.124 g, 0.0004 mol) was added to the reaction mixture. After 48 hours at 65° C. reaction was complete (TLC, acetone:n-hexane 1:4), the mixture was extracted with ethyl acetate, the organic layer was dried with anhydrous sodium sulfate, and the solvent was removed using a vacuum rotary evaporator. The product is purified by column chromatography (eluent, acetone:n-hexane 1:24) to yield 0.536 g (92%) white powder. Anal. Calcd. for: C₁₆H₁₆BrN, %: C, 63.59; H, 5.34; N, 4.63, found % C, 63.68; H, 5.46; N, 4.78

### Diethyl (2-(2,7-dimethyl-9H-carbazol-9-yl)ethyl)phosphonate

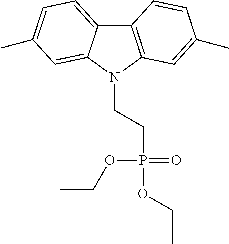

9-(2-bromoethyl)-2,7-dimethyl-9H-carbazole (0.5 g, 0.002 mol) was dissolved in triethyl phosphite (5.1 ml, 0.066 mol) and refluxed for 20 h. After the reaction was finished (TLC acetone: n-hexane, 7:18) the solvent was distilled off under reduced pressure. The crude product was purified by column chromatography (eluent acetone:n-hexane, 4:21) to give 0.58 g (98%) of clear liquid. Anal. Calcd. for C₂₀H₂₆NO₃P, %: C, 66.84; H, 7.29; N, 3.90 found, %: C, 66.65; H, 7.36; N, 4.06.

### (2-(2,7-dimethyl-9H-carbazol-9-yl)ethyl)phosphonic acid (V1609)

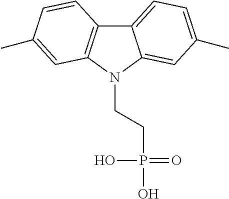

diethyl (2-(2,7-dimethyl-9H-carbazol-9-yl)ethyl)phosphonate (0.4 g, 0.001 mol) was dissolved in 1,4-Dioxane (3.8 ml, 0.445 mol). Then, C (1.6 ml, 0.0123 mol) was added dropwise, and stirring was continued at room temperature for 21 hours. After the reaction was completed (TLC analysis was performed using acetone: hexane v: v 20:5 Rf=) methanol (2 ml, 0.049 mol) was added to the reaction mixture and left for another 3 hours. The resulting solution was then removed using a rotary evaporator, and the product was solidified by adding distilled water dropwise to the reaction mixture to give 0.28 g (83%) of white power.

Anal. Calcd. for: C₁₆H₁₈NO₃P, %: C, 63.36; H, 5.98; N, 4.62, found, %: C, 63.04; H, 6.12; N, 4.46.

¹H NMR (400 MHZ, DMSO) δ 7.95 (d, J=7.9 Hz, 2H), 7.30 (s, 2H), 7.01 (d, J=7.9 Hz, 2H), 4.53-4.43 (m, 2H), 2.50 (s, 6H), 2.03 (t, J=7.8 Hz, 2H).

¹³C NMR (101 MHZ, DMSO) δ 139.87, 134.89, 120.35, 120.21, 119.82, 108.85, 66.38, 37.25, 21.88.

### Example 7: (4-(2,7-dimethoxy-9H-carbazol-9-yl)butyl)phosphonic acid (V1516) 9-(4-bromobutyl)-2,7-dimethoxy-9H-carbazole

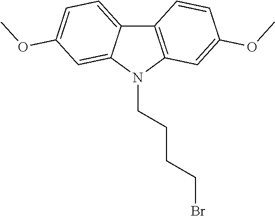

2,7-dimethoxycarbazole (0.8 g, 3.52 mmol) was dissolved in toluene (14 mL). 50% KOH solution (14 mL), 1,4-dibromobutane (1.26 mL, 10.56 mmol) and catalytic amount of tetrabutylammonium bromide were added afterward and left for 24 hours at 50° C. After the reaction was complete (TLC, acetone:n-hexane 1:4), the mixture was extracted with ethyl acetate, the organic layer was dried with anhydrous sodium sulfate, and the solvent was removed using a vacuum rotary evaporator. The product is purified by column chromatography (eluent, acetone:n-hexane 3:22) to yield 0.85 g (66%) of white powder. Anal. Calcd. for C₁₈H₂₀BrNO₂, %: C, 59.68; H, 5.56; N, 3.87, found, %: C, 59.59; H, 5.42; N, 3.85

### Diethyl (4-(2,7-dimethoxy-9H-carbazol-9-yl)butyl)phosphonate

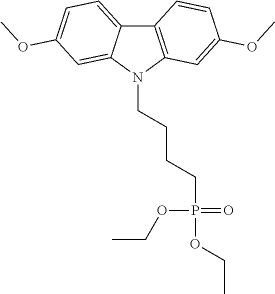

9-(4-bromobutyl)-2,7-dimethoxy-9H-carbazole (0.64 g, 1.76 mmol) was dissolved in triethyl phosphite (6.4 ml). The reaction mixture was refluxed for 24 hours. After the reaction was complete (TLC, acetone:n-hexane, 1:4) triethyl phosphite was distilled off and the crude solution was purified by column chromatography (eluent, n-hexane) to yield 0.6 g (74%) of a clear liquid. Anal. Calcd. for C₂₂H₃₀NO₅P, %: C, 63.00; H, 7.21; N, 3.34, found, %: C, 63.05; H, 7.28; N, 3.28

### (4-(2,7-dimethoxy-9H-carbazol-9-yl)butyl)phosphonic acid (V1516)

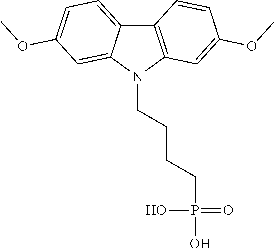

Diethyl [3-(9H-carbazol-9-yl)propyl]phosphonate (0.3 g, 0.71 mmol) was dissolved in anhydrous 1,4-dioxane (7 ml) and Bromotrimethylsilane (1.1 ml) was added dropwise. The reaction mixture was left under argon atmosphere at room temperature for 24 hours. After reaction was completed (TLC: n-hexane:acetone 1:4) a portion of the solvent was distilled off under reduced pressure. A few drops of distilled water were added dropwise, until the reaction solution becomes opaque, and some white precipitate began to form. The precipitate was filtered off and washed with isopropyl alcohol to yield 0.18 g (69%) of white crystals.

Anal. Calcd. for C₁₈H₂₂NO₅P, %: C, 59.50; H, 6.10; N, 3.85. found, %: C, 59.47; H, 6.21; N, 3.74

¹H NMR (400 MHZ, DMSO) δ 7.87 (d, J=8.5 Hz, 2H), 7.08 (d, J=2.2 Hz, 2H), 6.75 (dd, J=8.5, 2.2 Hz, 2H), 4.31 (t, J=7.1 Hz, 2H), 3.86 (s, 6H), 1.83 (p, J=7.0 Hz, 2H), 1.57 (h, J=8.9 Hz, 4H).

¹³C NMR (101 MHz, DMSO) δ 157.39, 141.04, 119.57, 115.66, 106.69, 93.30, 55.04, 41.44, 28.91, 26.25, 19.99.

### Example 8: (2-(4-methoxy-9H-carbazol-9-yl)ethyl)phosphonic acid (V1610)

### 4-methoxy-9H-carbazole

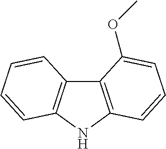

4-hydroxycarbazole (1.5 g, 1 eq) was dissolved in ethyl acetate (6.5 ml, 10 eq). Afterwards, Tetrabutylammonium hydrogen sulfate (0.027 g, 0.08 mmol, 0.01 eq), methyl iodide (1.74 g., 12.3 mmol, 1.5 eq) and potassium carbonate (1.35 g, 9.8 mmol, 1.2 eq) were added. The resulting suspension was refluxed for 16h.), the mixture was extracted with ethyl acetate, the organic layer was dried with anhydrous sodium sulfate, and the solvent was removed using a vacuum rotary evaporator. The product is purified by column chromatography (eluent acetone:n-hexane 3:22 v:v) to give 0.82 g (51%) white material. Anal. Calcd. for: C₁₃H₁₁NO, %: C, 79.17; H, 5.62; N, 7.10, found C, 79.22; H, 5.74; N, 7.23

### 9-(2-bromoethyl)-4-methoxy-9H-carbazole

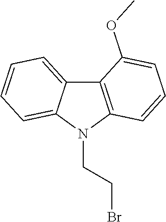 [SMILES: COc1cccc2c1c1ccccc1n2CCBr]

4-methoxy-9H-carbazole (0.77 g, 0.0039 mol) was dissolved in 1,2-Dibromoethane (8 ml). After, 50% KOH solution (8 ml) and Tetrabutylammonium bromide (16.9 ml, 0.1954 mol) was added to the reaction mixture. After 24 hours at 60° C. reaction was complete (TLC, acetone:n-hexane 1:3), the mixture was extracted with ethyl acetate, the organic layer was dried with anhydrous sodium sulfate, and the solvent was removed using a vacuum rotary evaporator. The product is purified by column chromatography (eluent, acetone:n-hexane 1:12) to yield 0.6 g (50%) white powder. Anal. Calcd. for C₁₅H₁₄BrNO, %: C, 59.23; H, 4.64; N, 4.60, found C, 53.78; H, 4.75; N, 4.70

### Diethyl (2-(4-methoxy-9H-carbazol-9-yl)ethyl)phosphonate

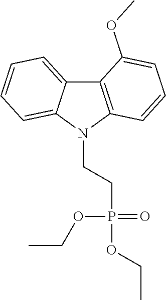 [SMILES: CCOP(=O)(CCn1c2ccccc2c2c(OC)cccc21)OCC]

9-(2-bromoethyl)-4-methoxy-9H-carbazole (0.58 g, 0.002 mol) was dissolved in triethyl phosphite (5.2 ml, 0.030 mol). The reaction mixture was heated to 165° C. and left overnight. After 20 hours when reaction was completed (TLC acetone: hexane v: v 7:18), the solvent was evaporated. The crude solution was purified using column chromatography (eluent: acetone: hexane v: v 4:21) to yield 0.68 g (98%) of clear liquid. Anal. Calcd. for C₁₉H₂₄NO₄P, %: C, 63.15; H, 6.69; N, 3.88, found, %: C, 62.89; H, 6.74; N, 3.99

### (2-(4-methoxy-9H-carbazol-9-yl)ethyl)phosphonic acid (V1610)

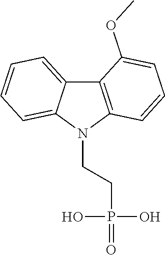 [SMILES: COc1cccc2c1c1ccccc1n2CCP(=O)(O)O]

(0.58 g, 1.6 mmol) was dissolved in anhydrous 1,4-dioxane (5.5 ml, 0.064 mol) and bromotrimethylsilane (3.13 ml, 0.023 mol) was added dropwise The reaction was stirred for 20 h at 25° C. under an argon atmosphere. Afterward, methanol (4 ml) was added, and stirring continued for 3h. Finally, distilled water was added dropwise (10 ml), until the solution became opaque, and it was left in a fridge overnight. The product was filtered off and washed with n-hexane, to yield 0.37 g (75%) of white power.

Anal. Calcd. for C₁₅H₁₆NO₄P, %: C, 59.02; H, 5.28; N, 4.59, found, %: C, 58.82; H, 5.59; N, 4.48

¹H NMR (400 MHZ, DMSO) § 8.18 (s, 1H), 7.54-7.48 (m, 1H), 7.40 (q, J=7.9 Hz, 2H), 7.23-7.10 (m, 2H), 6.77 (d, J=8.0 Hz, 1H), 4.58-4.47 (m, 2H), 4.02 (s, 3H), 2.07-1.94 (m, 2H).

¹³C NMR (101 MHz, DMSO) δ 155.81, 140.82, 138.62, 126.94, 124.88, 122.50, 121.58, 119.13, 111.05, 108.51, 101.88, 100.53, 55.48, 37.67, 28.15.

### Example 9: [4-(2,3,6,7-Tetramethoxy-9H-carbazol-9-yl)butyl]phosphonic acid (V1453)

### 2,3,6,7-Tetramethoxy-9H-carbazole

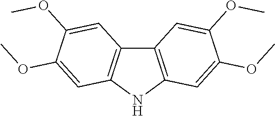

Under inert argon atmosphere sodium (2.99 g, 130 mmol) was dissolved in anhydrous MeOH (35.4 ml, 876 mmol). Afterwards 3,6-dibromo-2,7-dimethoxy-9H-carbazole (2.5 g, 6.49 mmol) pre-dissolved in 20 ml of anhydrous DMF, followed by addition of CuI (5.19 g, 27.3 mmol). Reaction conducted overnight at 100° C. After termination of reaction (TLC, eluent acetone:n-hexane, 6:19), reaction mixture was cooled down, filtered through celite, washed with THF and solvent removed under reduced pressure. Organic components were further extracted with ethyl acetate, organic layer was dried over anhydrous Na₂SO₄, filtered and solvent evaporated under reduced pressure. Crude product was purified by column chromatography (TLC, eluent acetone:n-hexane, 6:19). Product obtained as white crystals (1.42 g, 76%). M.p. 231.5-233° C. (melting and decomposition). Anal. calcd. for C₁₆H₁₇NO₄: C, 66.89, H, 5.96, N, 4.88; found: C, 67.01, H, 6.22, N, 4.69.

### 9-(4-Bromobutyl)-2,3,6,7-tetramethoxy-9H-carbazole

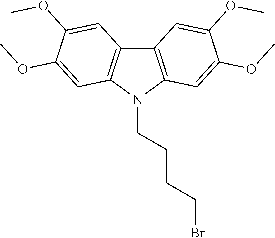

2,3,6,7-Tetramethoxy-9H-carbazole (0.5 g, 1.74 mmol) was dissolved in 10 ml of anhydrous DMF under argon atmosphere, followed by the addition of 1,4-dibromobutane (0.3 ml, 2.61 mmol) and ground KOH (0.15 g, 2.61 mmol). Reaction mixture was stirred overnight at 25° C. After termination of reaction (TLC, acetone:n-hexane, 7:18), organic components were extracted with ethyl acetate, organic layer was dried over anhydrous Na₂SO₄, filtered and solvent evaporated under reduced pressure. Crude product was purified by column chromatography (acetone:n-hexane, 7:18). Product obtained as white crystals (0.62 g, 84% yield). M.p. 182-183.5° C. Anal. calcd. for C₂₀H₂₄BrNO₄: C, 56.88, H, 5.73, N, 3.32; found: C, 58.70, H, 5.79, N, 3.48.

Diethyl [4-(2,3,6,7-tetramethoxy-9H-carbazol-9-yl)butyl]phosphonate

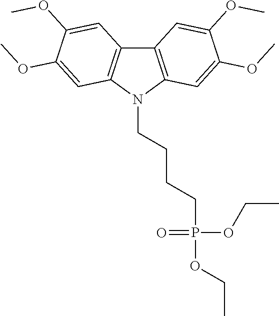 [SMILES: CCOP(=O)(CCCCn1c2cc(OC)c(OC)cc2c2cc(OC)c(OC)cc21)OCC]

9-(4-Bromobutyl)-2,3,6,7-tetramethoxy-9H-carbazole (0.55 g, 1.3 mmol) was suspended in triethyl phosphite (4.5 ml, 26 mmol) and the reaction was refluxed overnight. After termination of reaction (TLC, acetone:n-hexane, 1:1), solvent was removed under reduced pressure and the crude product was purified by column chromatography (acetone:n-hexane, 1:1). Product obtained as barely yellow resin (0.58 g, 93%). Anal. calcd. for C₂₄H₃₄NO₇P: C, 60.12, H, 7.15, N, 2.92; found: C, 60.12, H, 7.06, N, 2.81.

### [4-(2,3,6,7-Tetramethoxy-9H-carbazol-9-yl)butyl]phosphonic acid (V1453)

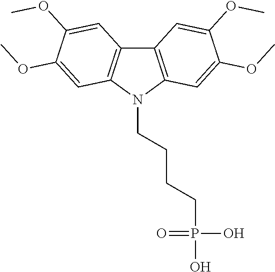

Diethyl [4-(2,3,6,7-tetramethoxy-9H-carbazol-9-yl)butyl]phosphonate (0.55 g, 1.15 mmol) was dissolved in anhydrous 1,4-dioxane (15 ml) under argon atmosphere. Afterwards, bromotrimethylsilane (1.5 ml, 11.5 mmol) was added dropwise and reaction was stirred overnight at 25° C. After consumption of phosphonate (TLC, acetone:n-hexane, 1:1) methanol (0.5 ml, 11.5 mmol) was added and stirring continued for 2 hours. Afterwards, distilled water was added dropwise until precipitate was formed and stirring continued overnight. Product was filtered and purified by dissolving in minimum amount of THF, precipitating into 20-fold excess of n-hexane, filtering, and washing with n-hexane to give grey crystals (0.22 g, 45% yield). M.p. 222.5-223.5° C. (melting and decomposition).

Anal. calcd. for C₂₀H₂₆NO₇P: C, 56.74, H, 6.19, N, 3.31; found: C, 56.81, H, 6.20, N, 3.03.

¹H NMR (400 MHZ, DMSO-d₆): δ 7.60 (s, 2H), 7.12 (s, 2H), 4.31 (t, J=6.4 Hz, 2H), 3.87 (s, 6H), 3.83 (s, 6H), 1.88-1.74 (m, 2H), 1.64-1.46 (m, 4H) ppm.

¹³C NMR (101 MHZ, DMSO-d₆): δ 147.99, 143.48, 134.59, 114.37, 102.99, 93.78, 56.24, 55.96, 41.97, 29.66, 29.51, 28.02, 26.66, 20.39, 20.35 ppm.

### Example 10: [4-(3,6-dicyano-9H-carbazol-9-yl)butyl]phosphonic acid (V1363)

### 9-(4-Bromobutyl)-9H-carbazole-3,6-dicarbonitrile

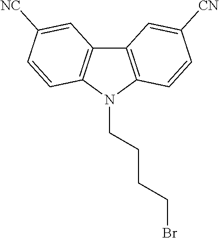 [SMILES: N#Cc1ccc2c(c1)c1cc(C#N)ccc1n2CCCCBr]

9H-Carbazole-3,6-dicarbonitrile (0.8 g, 3.68 mmol) was dissolved in 25 ml of anhydrous DMF under argon atmosphere, followed by the addition of 1,4-dibromobutane (0.66 ml, 5.52 mmol). The mixture was cooled down in an ice bath to 0° C. Afterwards, NaH (60% dispersion in mineral oil) (0.44 g, 5.52 mmol) was added portionwise and 0° C. temperature was maintained until complete consumption of starting material (TLC, acetone:n-hexane, 7:18). Organic components were extracted with ethyl acetate, organic layer was dried over anhydrous Na₂SO₄, filtered and solvent evaporated under reduced pressure. Crude product was purified by column chromatography (acetone:n-hexane, 7:18). Product obtained as white crystals (0.26 g, 20% yield). Anal. calcd. for C₁₈H₁₄BrN₃: C, 61.38, H, 4.01, N, 11.93; found: C, 61.21, H, 3.88, N, 12.04.

### Diethyl [4-(3,6-dicyano-9H-carbazol-9-yl)butyl]phosphonate

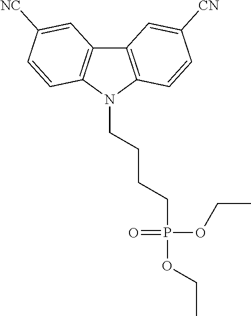 [SMILES: CCOP(=O)(CCCCn1c2ccc(C#N)cc2c2cc(C#N)ccc21)OCC]

9-(4-Bromobutyl)-9H-carbazole-3,6-dicarbonitrile (0.23 g, 0.65 mmol) was suspended in triethyl phosphite (2.23 ml, 13.05 mmol) and the reaction was refluxed overnight. After termination of reaction (TLC, acetone:n-hexane, 3:2), solvent was removed under reduced pressure and the crude product was purified by column chromatography (acetone:n-hexane, 3:2). Product obtained as yellowish crystals (0.23 g, 86%). Anal. calcd. for C₂₂H₂₄N₃O₃P: C, 64.54, H, 5.91, N, 10.26; found: C, 64.64, H, 5.99, N, 10.41.

### [4-(3,6-dicyano-9H-carbazol-9-yl)butyl]phosphonic acid (V1363)

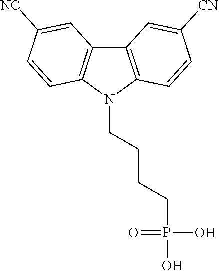 [SMILES: N#Cc1ccc2c(c1)c1cc(C#N)ccc1n2CCCCP(=O)(O)O]

Diethyl [4-(3,6-dicyano-9H-carbazol-9-yl)butyl]phosphonate (0.23, 0.56 mmol) was dissolved in anhydrous 1,4-dioxane: DCM (5:3, 8 ml) under argon atmosphere. Afterwards, bromotrimethylsilane (0.73 ml, 5.61 mmol) was added dropwise and reaction was stirred overnight at 25° C. After consumption of phosphonate (TLC, acetone:n-hexane, 3:2) methanol (0.2 ml, 5.61 mmol) was added and stirring continued for 2 hours. Afterwards, distilled water was added dropwise until precipitate was formed and stirring continued overnight. Product was filtered and purified by dissolving in minimum amount of THE, precipitating into 20-fold excess of n-hexane, filtering, and washing with n-hexane to give brownish white crystals (0.18 g, 91% yield).

Anal. calcd. for C₁₈H₁₆N₃O₃P: C, 61.19, H, 4.56, N, 11.89; found: C, 61.22, H, 4.40, N, 11.73.

¹H NMR (400 MHZ, DMSO-d₆): δ 8.80 (s, 2H), 7.91 (s, 4H), 4.50 (s, 2H), 1.84 (s, 2H), 1.52 (s, 4H) ppm.

¹³C NMR (101 MHz, DMSO-d₆): δ 142.50, 130.06, 126.31, 121.52, 120.01, 111.46, 101.96, 42.63, 29.42, 29.26, 27.90, 26.54, 20.28 ppm.

### Example 11: [4-(3,6-Difluoro-9H-carbazol-9-yl)butyl]phosphonic acid (V1356)

### 9-(4-Bromobutyl)-3,6-difluoro-9H-carbazole

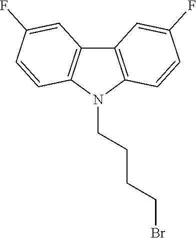 [SMILES: Fc1ccc2c(c1)c1cc(F)ccc1n2CCCCBr]

3.6-Difluoro-9H-carbazole (0.7 g, 3.44 mmol) was dissolved in 10 ml of anhydrous DMF under argon atmosphere, followed by the addition of 1,4-dibromobutane (0.6 ml, 5.16 mmol). The mixture was cooled down in an ice bath to 0° C. Afterwards, NaH (60% dispersion in mineral oil) (0.20 g, 5.16 mmol) was added portionwise and 0° C. temperature was maintained until complete consumption of starting material (TLC, acetone:n-hexane, 1:24). Organic components were extracted with ethyl acetate, organic layer was dried over anhydrous Na₂SO₄, filtered and solvent evaporated under reduced pressure. Crude product was purified by column chromatography (acetone:n-hexane, 1:24). Product obtained as yellowish resin (0.73 g, 63% yield). Anal. calcd. for C₁₆H₁₄BrF₂N: C, 56.82, H, 4.17, N, 4.14; found: C, 56.99, H, 4.02, N, 4.30.

### Diethyl [4-(3,6-difluoro-9H-carbazol-9-yl)butyl]phosphonate

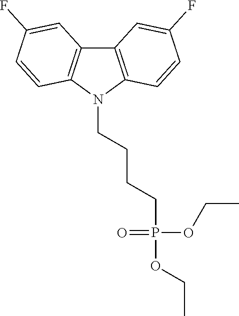 [SMILES: CCOP(=O)(CCCCn1c2ccc(F)cc2c2cc(F)ccc21)OCC]

9-(4-Bromobutyl)-3,6-difluoro-9H-carbazole (0.68 g, 2.01 mmol) was suspended in triethyl phosphite (7.0 ml, 40.21 mmol) and the reaction was refluxed overnight. After termination of reaction (TLC, eluent acetone:n-hexane, 7:18), solvent was removed under reduced pressure and the crude product was purified by column chromatography (eluent acetone:n-hexane, 7:18). Product obtained as yellowish resin (0.49 g, 62% yield). Anal. calcd. for C₂₀H₂₄F₂NO₃P: C, 60.76, H, 6.12, N, 3.54; found: C, 60.65, H, 6.27, N, 3.55.

### [4-(3,6-Difluoro-9H-carbazol-9-yl)butyl]phosphonic acid (V1356)

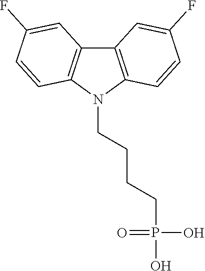 [SMILES: O=P(O)(O)CCCCn1c2ccc(F)cc2c2cc(F)ccc21]

Diethyl [4-(3,6-difluoro-9H-carbazol-9-yl)butyl]phosphonate (0.43 g, 1.08 mmol) was dissolved in anhydrous 1,4-dioxane (5 ml) under argon atmosphere. Afterwards, bromotrimethylsilane (1.4 ml, 10.87 mmol) was added dropwise and reaction was stirred overnight at 25° C. After consumption of phosphonate (TLC, eluent acetone:n-hexane, 8:17) methanol (0.4 ml, 10.87 mmol) was added and stirring continued for 2 hours. Afterwards, distilled water was added dropwise until precipitate was formed and stirring continued overnight. Product was filtered and purified by dissolving in minimum amount of THF, precipitating into 20-fold excess of n-hexane, filtering, and washing with n-hexane to give greyish white crystals (0.33 g, 89%). M.p. 191-193° C. (melting and decomposition).

Anal. calcd. for C₁₆H₁₆F₂NO₃P: C, 56.64, H, 4.75, N, 4.13; found: C, 56.81, H, 4.79, N, 4.03.

¹H NMR (400 MHZ, DMSO-d₆): δ 8.02 (d, J=9.2 Hz, 2H), 7.63 (dt, J=11.3, 5.8 Hz), 7.31 (dd, J=18.1, 9.0 Hz, 2H), 4.39 (t, J=6.6 Hz, 2H), 1.88-1.75 (m, 2H), 1.60-1.40 (m, 4H) ppm.

¹³C NMR (101 MHZ, DMSO-d₆): δ 157.49, 155.17, 137.39, 122.05, 122.00, 121.95, 121.91, 114.15, 113.90, 110.77, 110.68, 106.44, 106.21, 42.38, 29.61, 29.46, 28.00, 26.64, 20.41, 20.37 ppm.

### Example 12: [4-(3,6-Dichloro-9H-carbazol-9-yl)butyl]phosphonic acid (V1364)

### 9-(4-Bromobutyl)-3,6-dichloro-9H-carbazole

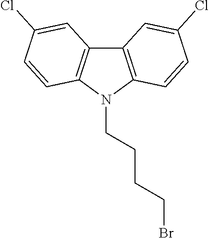 [SMILES: Clc1ccc2c(c1)c1cc(Cl)ccc1n2CCCCBr]

3,6-Dichloro-9H-carbazole (0.7 g, 2.96 mmol) was dissolved 10 ml of anhydrous DMF under argon atmosphere, followed by the addition of 1,4-dibromobutane (0.5 ml, 4.44 mmol). The mixture was cooled down in an ice bath to 0° C. Afterwards, NaH (60% dispersion in mineral oil) (0.18 g, 4.44 mmol) was added portionwise and 0° C. temperature was maintained until complete consumption of starting material (TLC, acetone:n-hexane, 1:24). Organic components were extracted with ethyl acetate, organic layer was dried over anhydrous Na₂SO₄, filtered and solvent evaporated under reduced pressure. Crude product was purified by column chromatography (acetone:n-hexane, 1:24). Product obtained as white crystals (0.77 g, 70% yield). M.p. 120-122° C. Anal. calcd. for C₁₆H₁₄BrCl₂N: C, 51.79, H, 3.80, N, 3.77; found: C, 51.99, H, 4.03, N, 3.87.

### Diethyl [4-(3,6-dichloro-9H-carbazol-9-yl)butyl]phosphonate

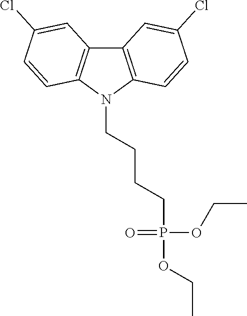 [SMILES: CCOP(=O)(CCCCn1c2ccc(Cl)cc2c2cc(Cl)ccc21)OCC]

9-(4-Bromobutyl)-3,6-dichloro-9H-carbazole (0.73 g, 1.96 mmol) was suspended in triethyl phosphite (6.7 ml, 39.3 mmol) and the reaction was refluxed overnight. After termination of reaction (TLC, eluent acetone:n-hexane, 7:18), solvent was removed under reduced pressure and the crude product was purified by column chromatography (eluent acetone:n-hexane, 7:18). Product obtained as yellowish resin (0.81 g, 96% yield). Anal. calcd. for C₂₀H₂₄C₁₂NO₃P: C, 56.09, H, 5.65, N, 3.27; found: C, 56.22, H, 5.43, N, 3.30.

### [4-(3,6-Dichloro-9H-carbazol-9-yl)butyl]phosphonic acid (V1364)

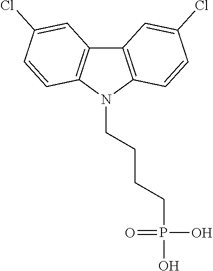 [SMILES: O=P(O)(O)CCCCn1c2ccc(Cl)cc2c2cc(Cl)ccc21]

Diethyl [4-(3,6-dichloro-9H-carbazol-9-yl)butyl]phosphonate (0.75 g, 1.75 mmol) was dissolved in anhydrous 1,4-dioxane (10 ml) under argon atmosphere. Afterwards, bromotrimethylsilane (2.3 ml, 17.5 mmol) was added dropwise and reaction was stirred overnight at 25° C. After consumption of phosphonate (TLC, eluent acetone:n-hexane, 7:18) methanol (0.4 ml, 10.87 mmol) was added and stirring continued for 2 hours. Afterwards, distilled water was added dropwise until precipitate was formed and stirring continued overnight. Product was filtered and purified by dissolving in minimum amount of THF, precipitating into 20-fold excess of n-hexane, filtering, and washing with n-hexane to give grey crystals (0.54 g, 82%). M.p. 215-217° C. (melting and decomposition).

Anal. calcd. for C₁₆H₁₆C₁₂NO₃P: C, 51.63, H, 4.33, N, 4.76; found: C, 51.88, H, 4.40, N, 4.85.

¹H NMR (400 MHZ, DMSO-d₆): δ 8.32 (s, 2H), 7.68 (d, J=8.8 Hz, 2H), 7.48 (d, J=8.7 Hz, 2H), 4.39 (t, J=6.9 Hz, 2H), 1.85-1.74 (m, 2H), 1.58-1.44 (m, 4H) ppm.

¹³C NMR (101 MHZ, DMSO-d₆): δ 138.97, 126.26, 123.51, 122.41, 120.46, 111.34, 42.37, 29.55, 29.39, 28.01, 26.63, 20.40, 20.36 ppm.

### Example 13: [4-(3,6-Dibromo-9H-carbazol-9-yl)butyl]phosphonic acid (V1517)

### 9-(4-Iodobutyl)-3,6-dibromo-9H-carbazole

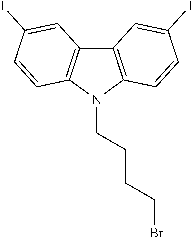 [SMILES: BrCCCCn1c2ccc(I)cc2c2cc(I)ccc21]

3,6-Diiodo-9H-carbazole (0.7 g, 1.67 mmol) was dissolved in 10 ml of anhydrous DMF under argon atmosphere, followed by the addition of 1,4-dibromobutane (0.3 ml, 2.51 mmol) and ground KOH (0.14 g, 2.51 mmol). Reaction mixture was stirred overnight at 25° C. After termination of reaction (TLC, acetone:n-hexane, 1:24), organic components were extracted with ethyl acetate, organic layer was dried over anhydrous Na₂SO₄, filtered and solvent evaporated under reduced pressure. Crude product was purified by column chromatography (acetone:n-hexane, 1:24). Product obtained as white solid (0.61 g, 66% yield). Anal. calcd. for C₁₆H₁₄BrI₂N: C, 34.69, H, 2.55, N, 2.53; found: C, 34.58, H, 2.62, N, 2.29.

### Diethyl [4-(3,6-diiodo-9H-carbazol-9-yl)butyl]phosphonate

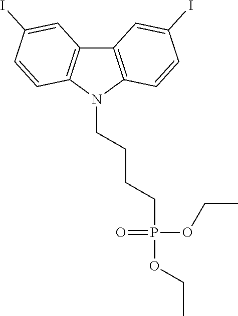 [SMILES: CCOP(=O)(CCCCn1c2ccc(I)cc2c2cc(I)ccc21)OCC]

9-(4-Iodobutyl)-3,6-dibromo-9H-carbazole (0.58 g, 1.05 mmol) was suspended in triethyl phosphite (3.6 ml, 20.9 mmol) and the reaction was refluxed overnight. After termination of reaction (TLC, eluent acetone:n-hexane, 7:18), solvent was removed under reduced pressure and the crude product was purified by column chromatography (eluent acetone:n-hexane, 7:18). Product obtained as yellowish resin (0.6 g, 94% yield). Anal. calcd. for C₂₀H₂₄₁₂NO₃P: C, 39.30, H, 3.96, N, 2.29; found: C, 39.50, H, 4.15, N, 2.33.

### [4-(3,6-Dibromo-9H-carbazol-9-yl)butyl]phosphonic acid (V1517)

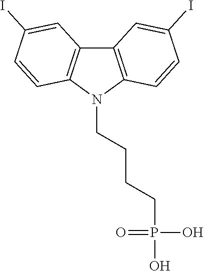 [SMILES: O=P(O)(O)CCCCn1c2ccc(I)cc2c2cc(I)ccc21]

Diethyl [4-(3,6-diiodo-9H-carbazol-9-yl)butyl]phosphonate (0.57 g, 0.93 mmol) was dissolved in anhydrous 1,4-dioxane (15 ml) under argon atmosphere. Afterwards, bromotrimethylsilane (1.2 ml, 9.32 mmol) was added dropwise and reaction was stirred overnight at 25° C. After consumption of phosphonate (TLC, eluent acetone:n-hexane, 7:18) methanol (0.4 ml, 9.32 mmol) was added and stirring continued for 2 hours. Afterwards, distilled water was added dropwise until precipitate was formed and stirring continued overnight. Product was filtered and purified by dissolving in minimum amount of THE, precipitating into 20-fold excess of n-hexane, filtering, and washing with n-hexane to give white crystals (0.41 g, 79%). M.p. 193.5-195° C. (melting and decomposition).

Anal. calcd. for C₁₆H₁₆₁₂NO₃P: C, 34.62, H, 2.91, N, 2.52; found: C, 34.47, H, 2.86, N, 2.51.

¹H NMR (400 MHZ, DMSO-d₆): δ 8.60 (s, 2H), 7.72 (d, J=8.5 Hz, 2H), 7.51 (d, J=8.6 Hz, 2H), 4.36 (t, J=6.5 Hz, 2H), 1.86-1.70 (m, 2H), 1.58-1.40 (m, 4H) ppm.

¹³C NMR (101 MHZ, DMSO-d₆): δ 139.14, 134.21, 129.29, 123.42, 112.11, 82.22, 42.17, 29.46, 29.30, 27.95, 26.60, 20.35, 20.31 ppm.

### Example 14: [6-(3,6-Dibromo-9H-carbazol-9-yl) hexyl]phosphonic acid (V1518)

### 9-(6-Iodohexyl)-3,6-dibromo-9H-carbazole

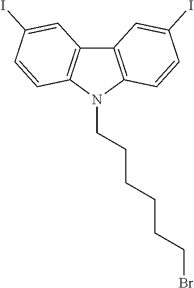 [SMILES: BrCCCCCCn1c2ccc(I)cc2c2cc(I)ccc21]

3,6-Diiodo-9H-carbazole (0.7 g, 1.67 mmol) was dissolved in 10 ml of anhydrous THF under argon atmosphere, followed by the addition of 1,6-dibromohexane (0.4 ml, 2.51 mmol) and ground KOH (0.14 g, 2.51 mmol). Reaction mixture was stirred overnight at 25° C. After termination of reaction (TLC, acetone:n-hexane, 1:24), organic components were extracted with ethyl acetate, organic layer was dried over anhydrous Na₂SO₄, filtered and solvent evaporated under reduced pressure. Crude product was purified by column chromatography (acetone:n-hexane, 1:24). Product obtained as white solid (0.61 g, 63% yield). Anal. calcd. for C₁₈H₁₈BrI₂N: C, 37.14, H, 3.12, N, 2.41; found: C, 37.40, H, 3.28, N, 2.48.

### Diethyl [6-(3,6-diiodo-9H-carbazol-9-yl)hexyl]phosphonate

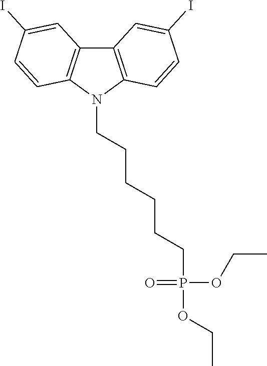 [SMILES: CCOP(=O)(CCCCCCn1c2ccc(I)cc2c2cc(I)ccc21)OCC]

9-(6-Iodohexyl)-3,6-dibromo-9H-carbazole (0.56 g, 0.96 mmol) was suspended in triethyl phosphite (3.3 ml, 19.2 mmol) and the reaction was refluxed overnight. After termination of reaction (TLC, eluent acetone:n-hexane, 7:18), solvent was removed under reduced pressure and the crude product was purified by column chromatography (eluent acetone:n-hexane, 7:18). Product obtained as yellowish resin (0.6 g, 98% yield).

Anal. calcd. for C₂₂H₂₈₁₂NO₃P: C, 41.34, H, 4.42, N, 2.19; found: C, 41.10, H, 4.53, N, 2.07.

### [6-(3,6-Dibromo-9H-carbazol-9-yl) hexyl]phosphonic acid (V1518)

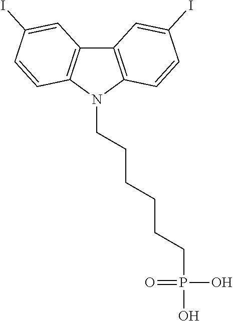 [SMILES: O=P(O)(O)CCCCCCn1c2ccc(I)cc2c2cc(I)ccc21]

Diethyl [6-(3,6-diiodo-9H-carbazol-9-yl)hexyl]phosphonate (0.58 g, 0.91 mmol) was dissolved in anhydrous 1,4-dioxane (15 ml) under argon atmosphere. Afterwards, bromotrimethylsilane (1.2 ml, 9.32 mmol) was added dropwise and reaction was stirred overnight at 25° C. After consumption of phosphonate (TLC, eluent acetone:n-hexane, 7:18) methanol (0.4 ml, 9.32 mmol) was added and stirring continued for 2 hours. Afterwards, distilled water was added dropwise until precipitate was formed and stirring continued overnight. Product was filtered and purified by dissolving in minimum amount of THE, precipitating into 20-fold excess of n-hexane, filtering, and washing with n-hexane to give white solid (0.36 g, 68%).

Anal. calcd. for C₁₈H₂O₁₂NO₃P: C, 37.07, H, 3.46, N, 2.40; found: C, 37.23, H, 3.52, N, 2.33. ¹H NMR (400 MHZ, DMSO-d₆): δ 8.60 (s, 2H), 7.72 (d, J=8.6 Hz, 2H), 7.48 (d, J=8.6 Hz, 2H), 4.33 (t, J=6.6 Hz, 2H), 1.72-1.63 (m, 2H), 1.50-1.18 (m, 8H) ppm.

¹³C NMR (101 MHZ, DMSO-d₆): δ 139.13, 134.21, 129.32, 123.41, 112.01, 82.20, 42.33, 29.71, 29.55, 28.19, 28.09, 26.74, 25.99, 22.65, 22.60 ppm.

### Example 15: [4-(3,6-Dibromo-9H-carbazol-9-yl)butyl]phosphonic acid (V1298)

### 9-(4-Bromobutyl)-3,6-dibromo-9H-carbazole

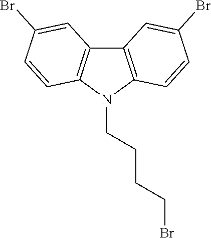 [SMILES: BrCCCCn1c2ccc(Br)cc2c2cc(Br)ccc21]

3,6-Dibromo-9H-carbazole (1 g, 3.07 mmol) was dissolved in 15 ml of anhydrous DMF under argon atmosphere, followed by the addition of 1,4-dibromobutane (0.55 ml, 4.61 mmol). The mixture was cooled down in an ice bath to 0° C. Afterwards, NaH (60% dispersion in mineral oil) (0.18 g, 4.61 mmol) was added portionwise and 0° C. temperature was maintained until complete consumption of starting material (TLC, acetone:n-hexane, 1:24). Organic components were extracted with ethyl acetate, organic layer was dried over anhydrous Na₂SO₄, filtered and solvent evaporated under reduced pressure. Crude product was purified by column chromatography (acetone:n-hexane, 1:24). Product obtained as white crystals (1.09 g, 77% yield). M.p. 116.5-118° C. Anal. calcd. for C₁₆H₁₄Br₃N: C, 41.78, H, 3.07, N, 3.04; found: C, 41.90, H, 3.17, N, 3.20.

### Diethyl [4-(3,6-dibromo-9H-carbazol-9-yl)butyl]phosphonate

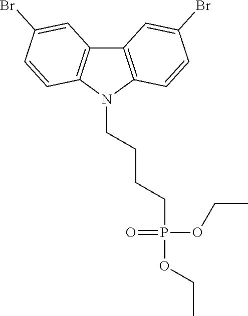 [SMILES: CCOP(=O)(CCCCn1c2ccc(Br)cc2c2cc(Br)ccc21)OCC]

9-(6-Bromohexyl)-3,6-dibromo-9H-carbazole (1.07 g, 2.06 mmol) was suspended in triethyl phosphite (7.1 ml, 41.37 mmol) and the reaction was refluxed overnight. After termination of reaction (TLC, eluent acetone:n-hexane, 7:18), solvent was removed under reduced pressure and the crude product was purified by column chromatography (eluent acetone:n-hexane, 7:18). Product obtained as yellowish resin (1.109 g, 92% yield). Anal. calcd. for C₂₀H₂₄Br₂NO₃P: C, 46.45, H, 4.68, N, 2.71; found: C, 46.60, H, 4.79, N, 2.55.

### [4-(3,6-Dibromo-9H-carbazol-9-yl)butyl]phosphonic acid (V1298)

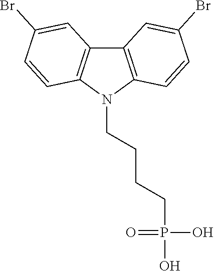 [SMILES: O=P(O)(O)CCCCn1c2ccc(Br)cc2c2cc(Br)ccc21]

Diethyl [4-(3,6-dibromo-9H-carbazol-9-yl)butyl]phosphonate (0.5 g, 0.96 mmol) was dissolved in anhydrous 1,4-dioxane (15 ml) under argon atmosphere. Afterwards, bromotrimethylsilane (1.3 ml, 9.66) was added dropwise and reaction was stirred overnight at 25° C. After consumption of phosphonate (TLC, eluent acetone:n-hexane, 7:18) methanol (0.4 ml, 9.66 mmol) was added and stirring continued for 2 hours. Afterwards, distilled water was added dropwise until precipitate was formed and stirring continued overnight. Product was filtered and purified by dissolving in minimum amount of THE, precipitating into 20-fold excess of n-hexane, filtering, and washing with n-hexane to give white crystals (0.29 g, 65%). M.p. 203-204.5° C. (melting and decomposition).

Anal. calcd. for C₁₆H₁₆Br₂NO₃P: C, 41.68, H, 3.50, N, 3.04; found: C, 41.49, H, 3.35, N, 3.11.

¹H NMR (400 MHZ, DMSO-d₆): δ 8.46 (s, 2H), 7.71-7.50 (m, 4H), 4.39 (t, J=6.9 Hz, 2H), 1.90-1.72 (m, 2H), 1.60-1.40 (m, 4H) ppm.

¹³C NMR (101 MHZ, DMSO-d₆): δ 139.05, 128.82, 123.43, 122.91, 111.76, 111.26, 42.29, 29.49, 29.33, 27.96, 26.61, 20.36, 20.32 ppm.

### Example 16: [4-(2,7-Dibromo-9H-carbazol-9-yl)butyl]phosphonic acid (V1299)

### 9-(4-Bromobutyl)-2,7-dibromo-9H-carbazole

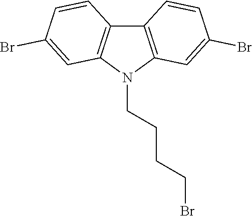 [SMILES: BrCCCCn1c2cc(Br)ccc2c2ccc(Br)cc21]

2,7-Dibromo-9H-carbazole (0.5 g, 1.53 mmol) was dissolved in 10 ml of anhydrous DMF under argon atmosphere, followed by the addition of 1,4-dibromobutane (0.28 ml, 2.30 mmol). The mixture was cooled down in an ice bath to 0° C. Afterwards, NaH (60% dispersion in mineral oil) (0.09 g, 2.30 mmol) was added portionwise and 0° C. temperature was maintained until complete consumption of starting material (TLC, acetone:n-hexane, 1:24). Organic components were extracted with ethyl acetate, organic layer was dried over anhydrous Na₂SO₄, filtered and solvent evaporated under reduced pressure. Crude product was purified by column chromatography (acetone:n-hexane, 1:24). Product obtained as white crystals (0.56 g, 80% yield). M.p. 109.5-110.5° C. Anal. calcd. for C₁₆H₁₄Br₃N: C, 41.78, H, 3.07, N 3.04; found: C, 42.01, H, 3.20, N, 3.17.

### Diethyl [4-(2,7-dibromo-9H-carbazol-9-yl)butyl]phosphonate

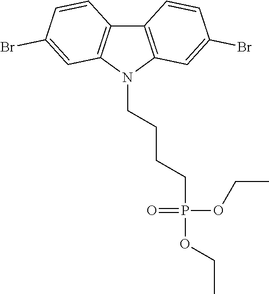 [SMILES: CCOP(=O)(CCCCn1c2cc(Br)ccc2c2ccc(Br)cc21)OCC]

1.13 mmol) was suspended in triethyl phosphite (3.9 ml, 22.60 mmol) and the reaction was refluxed overnight. After termination of reaction (TLC, eluent acetone:n-hexane, 7:18), solvent was removed under reduced pressure and the crude product was purified by column chromatography (eluent acetone:n-hexane, 7:18). Product obtained as barely yellow resin (0.52 g, 90%). Anal. calcd. for C₂₀H₂₄Br₂NO₃P: C, 46.45, H, 4.68, N, 2.71; found: C, 46.58, H, 4.50, N, 2.84.

### [4-(2,7-Dibromo-9H-carbazol-9-yl)butyl]phosphonic acid (V1299)

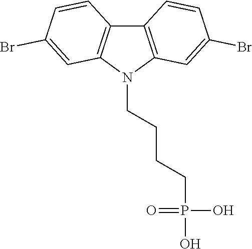 [SMILES: O=P(O)(O)CCCCn1c2cc(Br)ccc2c2ccc(Br)cc21]

Diethyl [4-(2,7-dibromo-9H-carbazol-9-yl)butyl]phosphonate (0.5 g, 0.96 mmol) was dissolved in anhydrous 1,4-dioxane (15 ml) under argon atmosphere. Afterwards, bromotrimethylsilane (1.3 ml, 9.66 mmol) was added dropwise and reaction was stirred overnight at 25° C. After consumption of phosphonate (TLC, eluent acetone:n-hexane, 7:18) methanol (0.4 ml, 9.66 mmol) was added and stirring continued for 2 hours. Afterwards, distilled water was added dropwise until precipitate was formed and stirring continued overnight. Product was filtered and purified by dissolving in minimum amount of THE, precipitating into 20-fold excess of n-hexane, filtering, and washing with n-hexane to give white crystals (0.254 g, 57% yield). M.p. 189.5-190.5° C. (melting and decomposition).

Anal. calcd. for C₁₆H₁₆Br₂NO₃P: C, 41.68, H, 3.50, N, 3.04; found: C, 41.82, H, 3.39, N, 2.98

¹H NMR (400 MHZ, DMSO-d₆): δ 8.11 (d, J=8.3 Hz, 2H), 7.94 (s, 2H), 7.35 (d, J=8.3 Hz, 2H), 4.39 (t, J=7.2 Hz, 2H), 1.87-1.70 (m, 2H), 1.63-1.46 (m, 4H) ppm.

¹³C NMR (101 MHz, DMSO-d₆): δ 141.09, 122.18, 122.14, 120.68, 119.22, 112.52, 42.26, 29.44, 29.28, 27.99, 26.63, 20.26, 20.21 ppm.

### Example 17: [2-(1,3,6,8-Tetrabromo-9H-carbazol-9-yl)ethyl]phosphonic acid (V1428)

### 1,3,6,8-Tetrabromo-9-(2-bromoethyl)-9H-carbazole 1101 1,3,6,8-Tetrabromo-9H-carbazole (0.6 g, 1.24 mmol) was

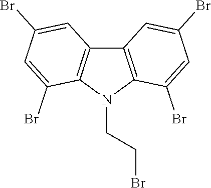 [SMILES: BrCCn1c2c(Br)cc(Br)cc2c2cc(Br)cc(Br)c21]

1,3,6,8-Tetrabromo-9H-carbazole (0.6 g, 1.24 mmol) was suspended in 1,2-dibromoethane (2.68 ml, 27.28 mmol), followed by addition of 50% KOH aqueous solution (0.7 ml, 6.2 mmol) and tetrabutylammonium bromide (0.06 g, 0.18 mmol). Reaction mixture was heated to 80° C. and stirred for 48 hours. After the first 24 hours additional 50% KOH solution (0.7 ml, 6.2 mmol) and tetrabutylammonium bromide (0.06 g, 0.18 mmol) were added. After termination of reaction (TLC, acetone:n-hexane, 1:24), organic components were extracted with ethyl acetate, organic layer dried over anhydrous Na₂SO₄, filtered and solvent removed under reduced pressure. Crude product was purified by column chromatography (acetone:n-hexane, 1:24). Product obtained as white crystals (0.60 g, 83% yield). M.p. 188.5-190° C. Anal. calcd. for C₁₄H₁₀Br₅N: C 28.51, H, 1.37, N, 2.38; found: C, 28.74, H, 1.52, N, 2.47.

### Diethyl [2-(1,3,6,8-tetrabromo-9H-carbazol-9-yl)ethyl]phosphonate

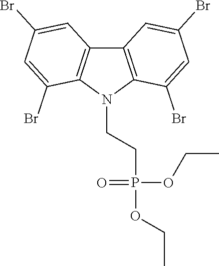 [SMILES: CCOP(=O)(CCn1c2c(Br)cc(Br)cc2c2cc(Br)cc(Br)c21)OCC]

9-(2-Bromoethyl)-1,3,6,8-tetrabromo-9H-carbazole (0.27 g, 0.45 mmol) was suspended in triethyl phosphite (1.6 ml, 9 mmol) and the reaction was refluxed overnight. After termination of reaction (TLC, eluent acetone:n-hexane, 7:18), solvent was removed under reduced pressure and the crude product was purified by column chromatography (eluent acetone:n-hexane, 7:18). Product obtained as white crystals (0.1 g, 36% yield). M.p. 211.5-213.5° C. Anal. calcd. for C₁₈H₁₈Br₄NO₃P: C 33.42, H, 2.80, N, 2.17; found: C, 33.28, H, 2.71, N, 2.25.

### [2-(1,3,6,8-Tetrabromo-9H-carbazol-9-yl)ethyl]phosphonic acid (V1428)

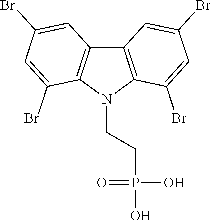 [SMILES: O=P(O)(O)CCn1c2c(Br)cc(Br)cc2c2cc(Br)cc(Br)c21]

Diethyl [2-(1,3,6,8-tetrabromo-9H-carbazol-9-yl)ethyl]phosphonate (0.09 g, 0.14 mmol) was dissolved in anhydrous 1,4-dioxane: DCM (1:1, 6 ml) under argon atmosphere. Afterwards, bromotrimethylsilane (0.2 ml, 1.39 mmol) was added dropwise and reaction was stirred overnight at 25° C. After consumption of phosphonate (TLC, eluent acetone:n-hexane, 6:19) methanol (0.05 ml, 1.39 mmol) was added and stirring continued for 2 hours. Afterwards, distilled water was added dropwise until precipitate was formed and stirring continued overnight. Product was filtered and purified by dissolving in minimum amount of THF, precipitating into 20-fold excess of n-hexane, filtering, and washing with n-hexane to give white crystals (0.07 g, 87% yield). M.p. 331-332° C. (melting and decomposition).

Anal. calcd. for C₁₄H₁₀Br₄NO₃P: C, 28.46, H, 1.71, N, 2.37; found: C, 28.50, H, 1.79, N, 2.56.

¹H NMR (400 MHZ, DMSO-d₆): δ 8.58 (s, 2H), 7.90 (s, 2H), 5.29-5.19 (m, 2H), 2.13-2.02 (m, 2H) ppm.

¹³C NMR (101 MHz, DMSO-d₆): δ 136.70, 134.30, 126.39, 123.14, 112.84, 103.89, 42.36, 30.79 (d, 1J (C,P)=128.4 Hz) ppm.

### Example 18: [2-(3,6-Dibromo-2,7-dimethoxy-9H-carbazol-9-yl)ethyl]phosphonic acid (V1452)

### 3,6-Dibromo-2,7-dimethoxy-9H-carbazole

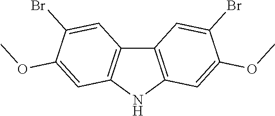

2,7-Dimethoxy-9H-carbazole (3 g, 13.2 mmol) was dissolved in 100 ml of DMF, followed by addition of N-chlorosuccinimide (4.81 g, 27.1 mmol). Reaction conducted for 1 hour at 25° C. After termination of reaction (TLC, eluent THF: n-hexane, 7:18), reaction mixture was poured into excess of distilled water. Precipitated crude product was filtered off, washed with distilled water, and purified by column chromatography (eluent THF: n-hexane, 7:18). Product obtained as white crystals (3.23 g, 64% yield). M.p. 211-212° C. (melting and decomposition). Anal. calcd. for C₁₄H₁₁Br₂NO₂: C, 43.67, H, 2.88, N, 3.64; found: C, 43.58, H, 2.81, N, 3.80.

### 9-(2-Bromoethyl)-3,6-dibromo-2,7-dimethoxy-9H-carbazole

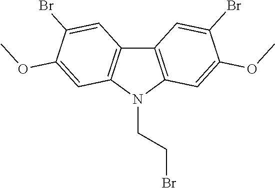

3,6-Dibromo-2,7-dimethoxy-9H-carbazole (1.1 g, 2.86 mmol) was suspended in 1,2-dibromoethane (6.1 ml, 71.4 mmol), followed by addition of 50% KOH aqueous solution (1.6 ml, 14.3 mmol) and tetrabutylammonium bromide (0.14 g, 0.43 mmol). Reaction mixture was heated to 80° C. and stirred for 72 hours. After the first 24 hours additional 50% KOH solution (1.6 ml, 14.3 mmol) and tetrabutylammonium bromide (0.14 g, 0.43 mmol) were added. After termination of reaction (TLC, acetone:n-hexane, 4:21), organic components were extracted with ethyl acetate, organic layer dried over anhydrous Na₂SO₄, filtered and solvent removed under reduced pressure. Crude product was purified by column chromatography (acetone:n-hexane, 4:21). Product obtained as white crystals (0.96 g, 69% yield). M.p. 206-208° C. (melting and decomposition). Anal. calcd. for C₁₆H₁₄Br₃NO₂: C, 39.06, H, 2.87, N, 2.85; found: C, 38.92, H, 2.77, N, 2.99.

### Diethyl [2-(3,6-dibromo-2,7-dimethoxy-9H-carbazol-9-yl)ethyl]phosphonate

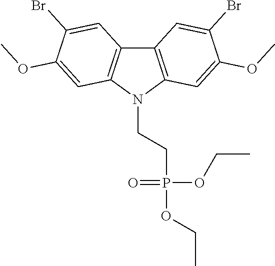

9-(2-Bromoethyl)-3,6-dibromo-2,7-dimethoxy-9H-carbazole (0.92 g, 1.87 mmol) was suspended in triethyl phosphite (6.4 ml, 37.4 mmol) and the reaction was refluxed overnight. After termination of reaction (TLC, acetone:n-hexane, 2:3), solvent was removed under reduced pressure and the crude product was purified by column chromatography (acetone:n-hexane, 2:3). Product obtained as white crystals (0.66 g, 65% yield). M.p. 207-208° C. Anal. calcd. for C₂₀H₂₄Br₂NO₅P: C, 43.74, H, 4.40, N, 2.55; found: C, 43.80, H, 4.23, N, 2.41.

### [2-(3,6-Dibromo-2,7-dimethoxy-9H-carbazol-9-yl)ethyl]phosphonic acid (V1452)

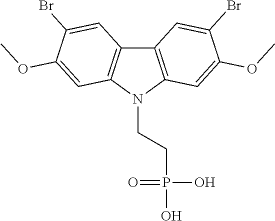

Diethyl [2-(3,6-dibromo-2,7-dimethoxy-9H-carbazol-9-yl)ethyl]phosphonate (0.63 g, 1.15 mmol) was dissolved in anhydrous 1,4-dioxane (15 ml) under argon atmosphere. Afterwards, bromotrimethylsilane (1.5 ml, 11.5 mmol) was added dropwise and reaction was stirred overnight at 25° C. After consumption of phosphonate (TLC, acetone:n-hexane, 2:3) methanol (0.5 ml, 11.5 mmol) was added and stirring continued for 2 hours. Afterwards, distilled water was added dropwise until precipitate was formed and stirring continued overnight. Product was filtered and purified by dissolving in minimum amount of THF, precipitating into 20-fold excess of n-hexane, filtering, and washing with n-hexane to give white crystals (0.33 g, 58% yield). M.p.−204° C. (decomposition).

Anal. calcd. for C₁₆H₁₆Br₂NO₅P: C, 38.97, H, 3.27, N, 2.84; found: C, 39.01, H, 3.20, N, 2.77

¹H NMR (400 MHZ, DMSO-d₆): δ 8.30 (s, 2H), 7.25 (s, 2H), 4.61-4.43 (m, 2H), 3.96 (s, 6H), 2.04 (dd, J=18.2, 9.0 Hz, 2H) ppm.

¹³C NMR (101 MHZ, DMSO-d₆): δ 153.52, 140.06, 123.85, 116.08, 102.52, 93.74, 56.45, 37.39, 32.75, 30.72, 27.67, 26.36 ppm.

### Example 19: [2-(3,6-Dichloro-2,7-dimethoxy-9H-carbazol-9-yl)ethyl]phosphonic acid (V1460)

### 3,6-Dichloro-2,7-dimethoxy-9H-carbazole

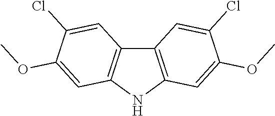

2,7-Dimethoxy-9H-carbazole (0.8 g, 3.52 mmol) was dissolved in 20 ml of DMF, followed by addition of (0.96 g, 7.21 mmol) N-chlorosuccinimide. Reaction conducted for 72 hours at 30° C. After termination of reaction (TLC, eluent THF: n-hexane, 7:18), reaction mixture was poured into excess of distilled water. Precipitated crude product was filtered off, washed with distilled water, and purified by column chromatography (eluent THF: n-hexane, 7:18). Product obtained as white crystals (0.76 g, 73% yield). M.p. 287-288° C. (melting and decomposition). Anal. calcd. for C₁₄H₁₁C₁₂NO₂: C, 56.78, H, 3.74, N, 4.73; found: C, 56.99, H, 3.92, N, 4.80.

### 9-(2-Bromoethyl)-3,6-dichloro-2,7-dimethoxy-9H-carbazole

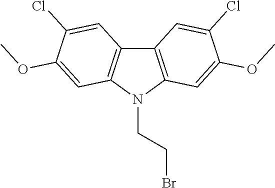

3,6-Dichloro-2,7-dimethoxy-9H-carbazole (1.15 g, 3.88 mmol) was suspended in 1,2-dibromoethane (8.4 ml, 97 mmol), followed by addition of 50% KOH aqueous solution (2.2 ml, 19.4 mmol) and tetrabutylammonium bromide (0.19 g, 0.58 mmol). Reaction mixture was heated to 80° C. and stirred for 72 hours. After the first 24 hours additional 50% KOH solution (2.2 ml, 19.4 mmol) and tetrabutylammonium bromide (0.19 g, 0.58 mmol) were added. After termination of reaction (TLC, THF: n-hexane, 7:18), organic components were extracted with ethyl acetate, organic layer dried over anhydrous Na₂SO₄, filtered and solvent removed under reduced pressure. Crude product was purified by column chromatography (THF: n-hexane, 7:18). Product obtained as white crystals (1.01 g, 65% yield). M.p. 232.5-234° C. (melting and decomposition). Anal. calcd. for C₁₆H₁₄BrCl₂NO₂: C, 47.67, H, 3.50, N, 3.47; found: C, 47.40, H, 3.39, N, 4.52.

### Diethyl [2-(3,6-dichloro-2,7-dimethoxy-9H-carbazol-9-yl)ethyl]phosphonate

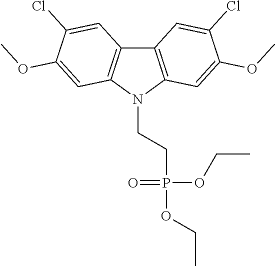

9-(2-Bromoethyl)-2,6-dichloro-2,7-dimethoxy-9H-carbazole (0.97 g, 2.41 mmol) was suspended in triethyl phosphite (8.3 ml, 48.1 mmol) and the reaction was refluxed overnight. After termination of reaction (TLC, acetone:n-hexane, 2:3), solvent was removed under reduced pressure and the crude product was purified by column chromatography (acetone:n-hexane, 2:3). Product obtained as white crystals (0.91 g, 83% yield). M.p. 189-190.5° C. Anal. calcd. for C₂₀H₂₄C₁₂NO₅P: C, 52.19, H, 5.26, N, 3.04; found: C, 52.01, H, 5.47, N, 3.00.

### [2-(3,6-Dichloro-2,7-dimethoxy-9H-carbazol-9-yl)ethyl]phosphonic acid (V1460)

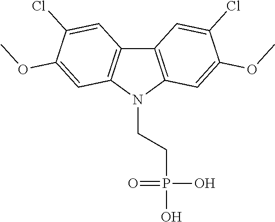

Diethyl [2-(3,6-dichloro-2,7-dimethoxy-9H-carbazol-9-yl)ethyl]phosphonate (0.88 g, 1.91 mmol) was dissolved in anhydrous 1,4-dioxane (20 ml) under argon atmosphere. Afterwards, bromotrimethylsilane (2.5 ml, 19.1 mmol) was added dropwise and reaction was stirred overnight at 25° C. After consumption of phosphonate (TLC, acetone:n-hexane, 2:3) methanol (0.8 ml, 19.1 mmol) was added and stirring continued for 2 hours. Afterwards, distilled water was added dropwise until precipitate was formed and stirring continued overnight. Product was filtered and purified by dissolving in minimum amount of THE, precipitating into 20-fold excess of n-hexane, filtering, and washing with n-hexane to give white crystals (0.59 g, 77% yield). M.p. 261.5-263.5° C. (melting and decomposition).

Anal. calcd. for C₁₆H₁₆Cl₂NO₅P: C, 47.55, H, 3.99, N, 3.47; found: C, 47.69, H, 3.87, N, 3.25.

¹H NMR (400 MHZ, DMSO-d₆): δ 8.15 (s, 2H), 7.27 (s, 2H), 4.53 (dd, J=15.5, 8.9 Hz, 2H), 3.96 (s, 6H), 2.14-1.97 (m, 2H) ppm.

¹³C NMR (101 MHz, DMSO-d₆): δ 152.86, 139.45, 120.84, 115.34, 113.62, 93.80, 56.32, 37.42, 27.71, 26.40 ppm.

### Example 20: (2-(4-phenyl-9H-carbazol-9-yl)ethyl)phosphonic acid (V1503)

### 9-(2-bromoethyl)-4-phenyl-9H-carbazole

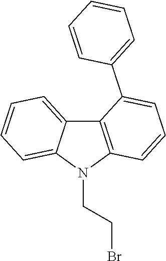 [SMILES: BrCCn1c2ccccc2c2c(-c3ccccc3)cccc21]

4-Phenyl-9H-carbazole (0.6 g, 0.0025 mol, 1 eq) was dissolved in 1,2-Dibromoethane (4.9 ml, 0.0567 mol 23 eq). After, 50% KOH solution (7 ml) and Tetrabutylammonium bromide (16 mg, 0.04 mmol, 0.02 eq) was added to the reaction mixture. After 72 hours at 50° C. reaction was complete (TLC in acetone: hexane v: v 1:4), the mixture was extracted with ethyl acetate, the organic layer was dried with anhydrous sodium sulfate, and the solvent was removed using a vacuum rotary evaporator. The product is purified by column chromatography (eluent, acetone:n-hexane 1:24) to yield 0.735 g, (85%) white powder. Anal. Calcd. for C₂₀H₁₆BrN, %: C, 68.58; H, 4.60; N, 4.00, found, %: C, 68.68; H, 4.74; N, 4.12.

### Diethyl (2-(4-phenyl-9H-carbazol-9-yl)ethyl)phosphonate

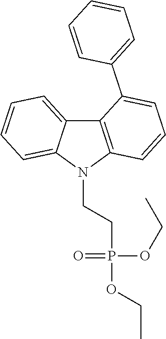 [SMILES: CCOP(=O)(CCn1c2ccccc2c2c(-c3ccccc3)cccc21)OCC]

9-(2-bromoethyl)-4-phenyl-9H-carbazole (0.7 g, 1.9 mmol, 1 eq) was dissolved in triethyl phosphite (5.15 ml, 16 eq) and heated at reflux for 20 h. When the reaction was finished (TLC acetone:n-hexane 7:18 v: v) the solvent was distilled off under reduced pressure. The crude product was purified by column chromatography (acetone:n-hexane, 1:4, v: v) to give 0.8 g (98%) of clear liquid. Anal. Calcd. for C₂₄H₂₆NO₃P, %: C, 70.75; H, 6.43; N, 3.44, found, %: C, 70.59; H, 6.61; N, 3.53.

### (2-(4-phenyl-9H-carbazol-9-yl)ethyl)phosphonic acid (V1503)

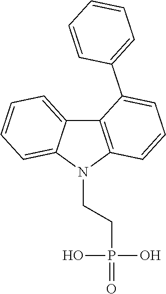 [SMILES: O=P(O)(O)CCn1c2ccccc2c2c(-c3ccccc3)cccc21]

diethyl (2-(4-phenyl-9H-carbazol-9-yl)ethyl)phosphonate (0.78 g, 1.91 mmol) was dissolved in anhydrous 1,4-dioxane (6.5 ml, 76.5 mmol) and bromotrimethylsilane (2.78 ml, 21 mmol) was added dropwise. Reaction was stirred for 22 h at 25° C. under argon atmosphere. Afterwards, methanol (5 ml) was added and stirring continued for 6h. Finally, distilled water was added dropwise (10 ml), until solution became opaque, and it was stirred overnight. Product was filtered off, washed with water, dissolved in tetrahydrofuran (1 ml) and precipitated into n-hexane (12 ml). The product was filtered off and washed with n-hexane, to give 0.54 g (80%) of white powder.

### Example 21: (2-(2,7-diphenyl-9H-carbazol-9-yl)ethyl)phosphonic acid (V1608)

### 9-(2-bromoethyl)-2,7-diphenyl-9H-carbazole

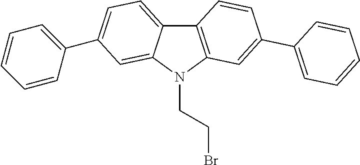 [SMILES: BrCCn1c2cc(-c3ccccc3)ccc2c2ccc(-c3ccccc3)cc21]

2,7-diphenyl-9H-carbazole (0.6 g, 1.9 mmol) was dissolved in 1,2-dibromoethane (4.8 ml, 56.4 mmol), and tetrabutylammonium bromide (0.012 g, 0.02 mmol) with 50% KOH aqueous solution (5 ml) were added subsequently. The reaction was stirred at 70° C. for 6 h (TLC, acetone:n-hexane, 4:21, v: v). After completion of the reaction, extraction was done with ethyl acetate. The organic layer was dried over anhydrous Na₂SO₄ and the solvent was distilled off under reduced pressure. The crude product was purified with column chromatography to yield 0.62 g (77%) of white powder. Anal. Calcd. for C₂₆H₂₀BrN, %: C, 73.25; H, 4.73; N, 3.29, found, %: C, 73.34; H, 4.81; N, 3.32

### diethyl (2-(2,7-diphenyl-9H-carbazol-9-yl)ethyl)phosphonate

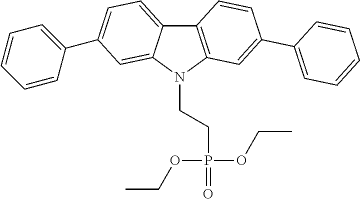 [SMILES: CCOP(=O)(CCn1c2cc(-c3ccccc3)ccc2c2ccc(-c3ccccc3)cc21)OCC]

9-(2-bromoethyl)-2,7-diphenyl-9H-carbazole (0.42 g, 0.9 mmol, 1 eq) was dissolved in triethyl phosphite (6 ml, 80 eq) and heated at reflux for 20 h. When reaction was finished (TLC acetone:n-hexane 7:18 v:v) the solvent was distilled off under reduced pressure. The crude product was purified by column chromatography (acetone:n-hexane, 1:4, v: v) to yield 0.40 g (83%) of clear liquid. Anal. Calcd. for C₃₀H₃₀NO₃P, %: C, 74.52; H, 6.25; N, 2.90, found C, 74.14; H, 6.45; N, 2.98

### (2-(2,7-diphenyl-9H-carbazol-9-yl)ethyl)phosphonic acid (V1608)

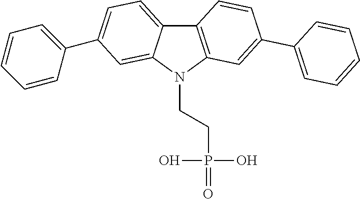 [SMILES: O=P(O)(O)CCn1c2cc(-c3ccccc3)ccc2c2ccc(-c3ccccc3)cc21]

Diethyl (2-(2,7-diphenyl-9H-carbazol-9-yl)ethyl)phosphonate (0.31 g, 0.64 mmol, 1 eq) was dissolved in anhydrous 1,4-dioxane (2.7 ml, 50 eq) and bromotrimethylsilane (0.93 ml, 7.06 mmol, 11 eq) was added dropwise. Reaction was stirred for 20 h at 25° C. under argon atmosphere. Afterwards, methanol (1 ml) was added and stirring continued for 3h. Finally, distilled water was added dropwise (10 ml), until solution became opaque, and it was left in a fridge overnight. The product was filtered off and washed with n-hexane, to yield 0.23 g (83%) of white powder. Anal Calcd. for: C₂₆H₂₂NO₃P, %: C, 73.06; H, 5.19; N, 3.28, found, %: C, 72.82; H, 5.34; N, 3.15.

### Example 22: (4-(9H-carbazol-9-yl)phenyl)phosphonic acid (V1365)

### Diisopropyl (4-(9H-carbazol-9-yl)phenyl)phosphonate

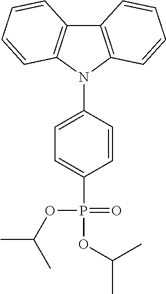 [SMILES: CC(C)OP(=O)(OC(C)C)c1ccc(-n2c3ccccc3c3ccccc32)cc1]

9-(4-Bromophenyl)carbazole (2 g, 6.21 mmol, 1 eq) dissolved in diizopropylphosphite (1.15 ml, 6.83 mmol, 1.1 eq) under Ar atmosphere. Following, Triethylamine (1.90 ml, 13.6 mmol, 2.2 eq) and Tetrakis(triphenylphosphine)palladium (0) (0.107 g, 0.09 mmol, 0.015 eq) were added in solution. Reaction was stirred for 16 hours 90° C. After the reaction was completed (TLC acetone:n-hexane 7:18 v:v), reaction mixture was filtered through celite. Crude solution was dried using vacuum evaporator and purified with column chromatography (eluent acetone:n-hexane 7:18 v:v) to exclude white crystals (1.89 g, 75% yield). Anal. Calcd. for C₂₄H₂₆NO₃P, %: C. 70.75, H. 6.43, N. 3.44, found, %: C, 70.82, H, 6.52, N, 3.48.

### (4-(9H-carbazol-9-yl)phenyl)phosphonic acid (V1365)

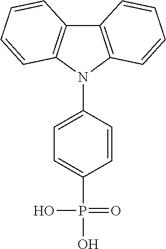 [SMILES: O=P(O)(O)c1ccc(-n2c3ccccc3c3ccccc32)cc1]

Diisopropyl (4-(9H-carbazol-9-yl)phenyl)phosphonate (1 g, 2.45 mmol, 1 eq) was dissolved in 1,4-Dioxane (8.4 ml 98.2 mmol, 40 eq) and bromotrimethylsilane (3.57 g, 27 mmol, 11 eq) was added dropwise. Reaction was left for 20 h and methanol (4 ml) was added afterwards. After 4 more hours few milliliters of H₂O were added dropwise. Reaction solution was distilled, filtered and washed with ethanol. White crystals were collected (0.53 g, 66% yield).

Anal. Calcd. for C₁₈H₁₄NO₃P, %: C, 66.87, H, 4.37, N, 4.33, found, %: C, 66.96, H, 4.43, N, 4.28.

¹H NMR (400 MHZ. (CD₃)₂SO) δ 8.26 (d. J=7.7 Hz, 2H), 7.98 (t. J=8.6 Hz, 2H), 7.76 (t. J=8.7 Hz, 2H), 7.50-7.39 (m, 4H), 7.26-7.36 (m, 2H)

¹³C NMR (101 MHZ, CD₃)₂SO) δ 139.75, 139.66, 132.98, 132.47, 126.41, 126.14, 122.98, 120.62, 120.41, 109.71

### Example 23: {4-[3,6-Di(thiophen-3-yl)-9H-carbazol-9-yl]butyl}phosphonic acid (V1443)

### 3,6-Di(thiophen-3-yl)-9H-carbazole

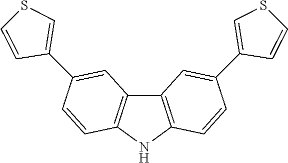 [SMILES: c1cc(-c2ccc3[nH]c4ccc(-c5ccsc5)cc4c3c2)cs1]

3,6-Dibromo-9H-carbazole (0.5 g, 1.53 mmol) was dissolved in anhydrous 1,4-dioxane (15 ml) under argon atmosphere, followed by addition of 3-thienylboronic acid (0.49 g, 3.84 mmol), Pd(PPh₃)₄ (0.17 g, 0.15 mmol) and K₂CO₃ 2M aqueous solution (2.3 ml, 4.61 mmol). Reaction conducted at 70° C. under inert argon atmosphere for 24 hours. After termination of reaction (TLC, acetone:n-hexane, 4:21), reaction mixture was cooled down and filtered through celite which was washed with THF. Organic solvent was evaporated, and the crude product was purified by column chromatography using acetone:n-136hexane (4:21) as an eluent resulting white crystals (0.351 g, 69%) as a product. M.p. 201-202° C. Anal. calcd. for C₂₀H₁₃NS₂: C, 72.48; H 3.95; N, 4.23; found: C, 72.29; H 4.02; N, 4.40.

### 9-(4-Bromobutyl)-3,6-di(thiophen-3-yl)-9H-carbazole

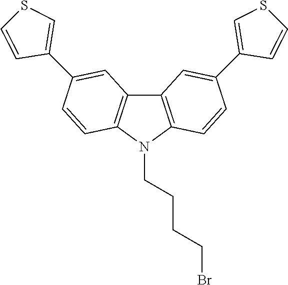 [SMILES: BrCCCCn1c2ccc(-c3ccsc3)cc2c2cc(-c3ccsc3)ccc21]

3,6-Di(thiophen-3-yl)-9H-carbazole (0.32 g, 0.96 mmol) was dissolved in 5 ml of anhydrous DMF under argon atmosphere, followed by the addition of 1,4-dibromobutane (0.17 ml, 1.44 mmol) and ground KOH (0.08 g, 1.44 mmol). Reaction mixture was stirred overnight at 25° C. After termination of reaction (TLC, acetone:n-hexane, 1:4), organic components were extracted with ethyl acetate, organic layer was dried over anhydrous Na₂SO₄, filtered and solvent evaporated under reduced pressure. Crude product was purified by column chromatography (acetone:n-hexane, 1:4). Product obtained as colorless resin (0.28 g, 62% yield). Anal. calcd. for C₂₄H₂₀BrNS₂: C, 61.80, H, 4.32, N, 3.00; found: C, 61.99, H, 4.25, N, 2.87.

### Diethyl {4-[3,6-di(thiophen-3-yl)-9H-carbazol-9-yl]butyl}phosphonate

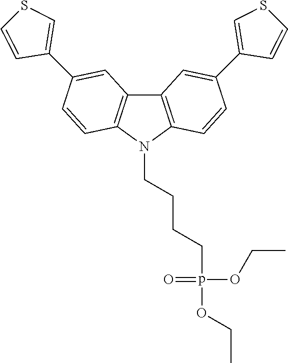

9-(4-Bromobutyl)-3,6-di(thiophen-3-yl)-9H-carbazole (0.25 g, 0.53 mmol) was suspended in triethyl phosphite (1.8 ml, 10.71 mmol) and the reaction was refluxed overnight. After termination of reaction (TLC, acetone:n-hexane, 1:1), solvent was removed under reduced pressure and the crude product was purified by column chromatography (acetone:n-hexane, 1:1). Product obtained as yellowish resin (0.26 g, 93%). Anal. calcd. for C₂₈H₃₀NO₃PS₂: C, 64.22, H, 5.77, N, 2.67; found: C, 64.10, H, 5.84, N, 2.60.

### {4-[3,6-Di(thiophen-3-yl)-9H-carbazol-9-yl]butyl}phosphonic acid (V1443)

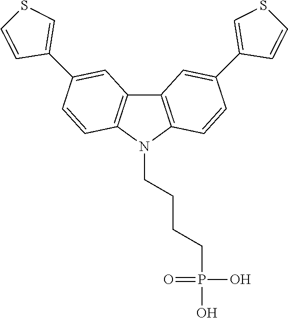 [SMILES: O=P(O)(O)CCCCn1c2ccc(-c3ccsc3)cc2c2cc(-c3ccsc3)ccc21]

Diethyl [4-(3,6-di(thiophen-3-yl)-9H-carbazole-9-yl)butyl]phosphonate (1 g, 2.12 mmol) was dissolved in anhydrous 1,4-dioxane (20 ml) under argon atmosphere. Afterwards, bromotrimethylsilane (2.75 ml, 21.2 mmol) was added dropwise and reaction was stirred overnight at 25° C. After consumption of phosphonate (TLC, acetone:n-hexane, 1:1) methanol (0.9 ml, 21.2 mmol) was added and stirring continued for 2 hours. Afterwards, distilled water was added dropwise until precipitate was formed and stirring continued overnight. Product was filtered and purified by dissolving in minimum amount of THE, precipitating into 20-fold excess of n-hexane, filtering, and washing with n-hexane to give dark grey crystals (0.81 g, 92% yield). M.p. 186.5-188° C.

Anal. calcd. for C₂₄H₂₂NO₃PS₂: C, 61.66, H, 4.74, N, 3.00; found: C, 61.71, H, 4.90, N, 3.12.

¹H NMR (400 MHZ, DMSO-d₆): δ 8.61 (s, 2H), 7.83 (d, J=7.2 Hz, 4H), 7.72-7.58 (m, 6H), 4.42 (t, J=6.5 Hz, 2H), 1.95-1.79 (m, 2H), 1.65-1.46 (m, 4H) ppm.

¹³C NMR (101 MHZ, DMSO-d₆): δ 142.48, 139.74, 126.80, 126.54, 126.42, 124.51, 122.70, 118.96, 118.07, 109.82, 42.25, 29.78, 29.63, 28.08, 26.72, 20.50, 20.46 ppm.

### Example 24: [2-(diphenylamino)ethyl]phosphonic acid (V1550)

### N-(2-bromoethyl)-N-phenylaniline

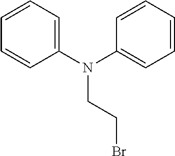 [SMILES: BrCCN(c1ccccc1)c1ccccc1]

Diphenylamino (2.5 g, 14.8 mmol) was suspended in 1,2-dibromoethane (32 ml, 369 mmol), followed by addition of 50% KOH aqueous solution (8.3 ml, 73.9 mmol) and tetrabutylammonium bromide (0.71 g, 2.21 mmol). Reaction mixture was heated to 80° C. and stirred for 240 hours. After the first 24 hours additional 50% KOH solution (8.3 ml, 73.9 mmol) and tetrabutylammonium bromide (0.71 g, 2.21 mmol) were added. After termination of reaction (TLC, acetone:n-hexane, 1:24), organic components were extracted with ethyl acetate, organic layer dried over anhydrous Na₂SO₄, filtered and solvent removed under reduced pressure. Crude product was purified by column chromatography (acetone:n-hexane, 1:24). Product obtained as colorless resin (0.69 g, 17% yield). Anal. calcd. for C₁₄H₁₄BrN: C, 60.89, H, 5.11, N, 5.07; found: C, 60.90, H, 5.01, N, 5.00.

### Diethyl [2-(diphenylamino)ethyl]phosphonate

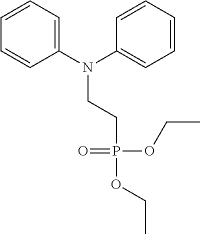 [SMILES: CCOP(=O)(CCN(c1ccccc1)c1ccccc1)OCC]

N-(2-bromoethyl)-N-phenylaniline (0.53 g, 1.92 mmol) was dissolved in triethyl phosphite (6.6 ml, 38.4 mmol) and the reaction was refluxed overnight. After termination of reaction (TLC, acetone:n-hexane, 7:18), solvent was removed under reduced pressure and the crude product was purified by column chromatography (acetone:n-hexane, 7:18). Product obtained as a slightly yellow resin (0.55 g, 86% yield). Anal. calcd. for C₁₈H₂₄NO₃P: C, 64.85, H, 7.26, N, 4.20; found: C, 65.02, H, 7.31, N, 4.09.

### [2-(diphenylamino)ethyl]phosphonic acid (V1550)

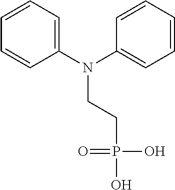 [SMILES: O=P(O)(O)CCN(c1ccccc1)c1ccccc1]

Diethyl [2-(diphenylamino)ethyl]phosphonate (0.5 g, 1.5 mmol) was dissolved in anhydrous 1,4-dioxane (10 ml) under argon atmosphere. Afterwards, bromotrimethylsilane (1.9 ml, 15 mmol) was added dropwise and reaction was stirred overnight at 25° C. After consumption of phosphonate (TLC, acetone:n-hexane, 7:18) methanol (0.6 ml, 15 mmol) was added and stirring continued for 2 hours. Afterwards, distilled water was added dropwise until precipitate was formed and stirring continued overnight. Product was filtered and purified by dissolving in minimum amount of THE, precipitating into 20-fold excess of n-hexane, filtering, and washing with n-hexane to give bluish grey crystals (0.31 g, 58% yield). M.p. 82.5-84° C.

Anal. calcd. for C₁₄H₁₆NO₃P: C, 60.65, H, 5.82, N, 5.05; found: C, 60.41, H, 5.68, N 4.99.

¹H NMR (400 MHZ, DMSO-d₆): δ 7.28 (t, J=7.5 Hz, 4H), 7.04-6.90 (m, 6H), 3.92-3.76 (m, 2H), 1.94-1.74 (m, 2H) ppm.

¹³C NMR (101 MHZ, DMSO-d₆): δ 146.89, 129.47, 121.39, 120.57, 46.52, 26.25, 24.97 ppm.

### Example 25: [4-(Diphenylamino)butyl]phosphonic acid (V1494)

### N-(4-bromobutyl)-N-phenylaniline

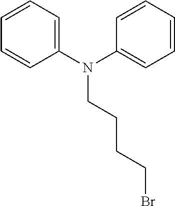 [SMILES: BrCCCCN(c1ccccc1)c1ccccc1]

Diphenylamine (2.5 g, 14.8 mmol) was dissolved in 25 ml of anhydrous DMF under argon atmosphere, followed by the addition of 1,4-dibromobutane (2.7 ml, 22.2 mmol). The mixture was cooled down in an ice bath to 0° C. Afterwards, NaH (60% dispersion in mineral oil) (0.89 g, 22.2 mmol) was added portionwise and reaction stirred for 1 hour at 25° C. After the termination of reaction (TLC, acetone:n-hexane, 1:24). Organic components were extracted with ethyl acetate, organic layer was dried over anhydrous Na₂SO₄, filtered and solvent evaporated under reduced pressure. Crude product was purified by column chromatography (acetone:n-hexane, 1:24). Product obtained as colorless resin (1.23 g, 27% yield). Anal. calcd. for C₁₆H₁₈BrN: C, 63.17, H, 5.96, N, 4.60; found: C, 63.40, H, 5.81, N, 4.37.

### Diethyl [4-(diphenylamino)butyl]phosphonate

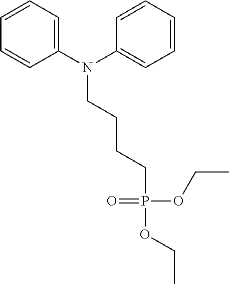 [SMILES: CCOP(=O)(CCCCN(c1ccccc1)c1ccccc1)OCC]

N-(4-bromobutyl)-N-phenylaniline (1.2 g, 3.94 mmol) was dissolved in triethyl phosphite (13.5 ml, 78.9 mmol) and the reaction was refluxed overnight. After termination of reaction (TLC, acetone:n-hexane, 7:18), solvent was removed under reduced pressure and the crude product was purified by column chromatography (acetone:n-hexane, 7:18). Product obtained as yellowish resin (1.03 g, 91% yield). Anal. calcd. for C₂₀H₂₈NO₃P: C, 66.47, H, 7.81, N, 3.88; found: C, 66.57, H, 7.81, N, 3.70.

### [4-(Diphenylamino)butyl]phosphonic acid (V1494)

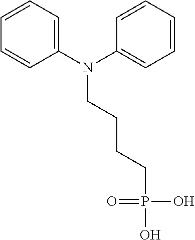 [SMILES: O=P(O)(O)CCCCN(c1ccccc1)c1ccccc1]

Diethyl [4-(diphenylamino)butyl]phosphonate (1 g, 2.77 mmol) was dissolved in anhydrous 1,4-dioxane (15 ml) under argon atmosphere. Afterwards, bromotrimethylsilane (3.6 ml, 27.7 mmol) was added dropwise and reaction was stirred overnight at 25° C. After consumption of phosphonate (TLC, acetone:n-hexane, 7:18) methanol (1.1 ml, 27.7 mmol) was added and stirring continued for 2 hours. Afterwards, distilled water was added dropwise until precipitate was formed and stirring continued overnight. Product was filtered and purified by dissolving in minimum amount of THE, precipitating into 20-fold excess of n-hexane, filtering, and washing with n-hexane to give grey crystals (0.64 g, 76% yield). M.p. 145-147° C. (melting and decomposition).

Anal. calcd. for C₁₆H₂₀NO₃P: C, 62.94, H, 6.60, N, 4.59; found: C, 63.21, H, 6.84, N 4.80.

¹H NMR (400 MHZ, DMSO-d₆): δ 7.25 (t, J=7.7 Hz, 4H), 7.01-6.86 (m, 6H), 3.71-3.62 (m, 2H), 1.68-1.58 (m, 2H), 1.57-1.44 (m, 4H) ppm.

¹³C NMR (101 MHZ, DMSO-d₆): δ 147.57, 129.31, 120.98, 120.52, 51.23, 28.05, 27.90, 20.39, 20.35 ppm.

### Example 26:9-(4-Phosphonobutyl)-9H-carbazole-3,6-bis(aminium) dibromide (V1482) and 9-(4-Phosphonobutyl)-9H-carbazole-3,6-bis(aminium) dichloride (V1548)

### Di-tert-butyl (9H-carbazole-3,6-diyl) dicarbamate

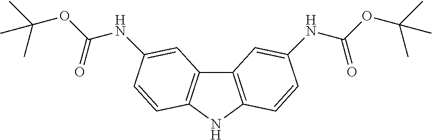 [SMILES: CC(C)(C)OC(=O)Nc1ccc2[nH]c3ccc(NC(=O)OC(C)(C)C)cc3c2c1]

9H-carbazole-3,6-diamine (4 g, 20.3 mmol) was dissolved in MeOH (60 ml) and TEA (8.5 ml, 60.9 mmol). Afterwards, di-tert-butyl dicarbonate (9.3 ml, 40.6 mmol) was slowly added and reaction stirred for 3 h at 25° C. After termination of reaction (TLC, acetone:n-hexane, 1:4), solvents were removed under reduced pressure and organic components were extracted with ethyl acetate. Organic layer was dried over anhydrous Na₂SO₄, filtered and solvent evaporated under reduced pressure. Crude product was purified by column chromatography, using acetone:n-hexane (1:4) as an eluent, resulting yellow crystals (7.48 g, 93% yield) as a product. M.p. 239-241° C. (melting and decomposition). Anal. calcd. for C₂₂H₂₇N₃O₄: C, 66.48, H, 6.85, N 10.57; found: C, 66.57, H, 6.99, N, 10.51.

### Di-tert-butyl [9-(4-bromobutyl)-9H-carbazole-3,6-diyl]dicarbamate

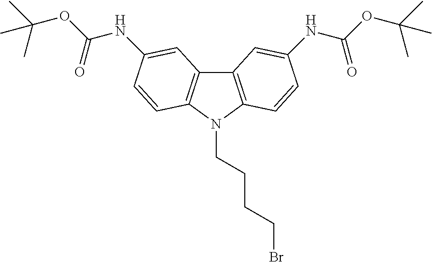 [SMILES: CC(C)(C)OC(=O)Nc1ccc2c(c1)c1cc(NC(=O)OC(C)(C)C)ccc1n2CCCCBr]

Di-tert-butyl (9H-carbazole-3,6-diyl) dicarbamate (5 g, 12.6 mmol) was dissolved in 40 ml of anhydrous DMF under argon atmosphere, followed by the addition of 1,4-dibromobutane (3 ml, 25.1 mmol) and ground KOH (1.27 g, 25.1 mmol). Reaction mixture was stirred for 1 hour at 25° C. After termination of reaction (TLC, acetone:n-hexane, 6:19), organic components were extracted with ethyl acetate, organic layer was dried over anhydrous Na₂SO₄, filtered and solvent evaporated under reduced pressure. Crude product was purified by column chromatography (acetone:n-hexane, 6:19). Product obtained as white crystals (2.68 g, 41% yield). M.p. 86-87.5° C. Anal. calcd. for C₂₆H₃₄BrN₃O₄: C, 58.65, H, 6.44, N, 7.89; found: C, 58.50, H, 6.49, N, 7.99.

### Di-tert-butyl {9-[4-(diethoxyphosphoryl)butyl]-9H-carbazole-3,6-diyl}dicarbamate

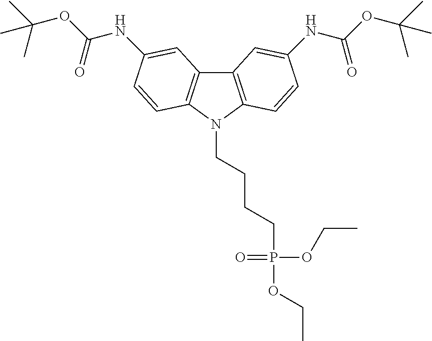 [SMILES: CCOP(=O)(CCCCn1c2ccc(NC(=O)OC(C)(C)C)cc2c2cc(NC(=O)OC(C)(C)C)ccc21)OCC]

Di-tert-butyl [9-(4-bromobutyl)-9H-carbazole-3,6-diyl]dicarbamate (2.45 g, 4.68 mmol) was dissolved in triethyl phosphite (16.1 ml, 93.6 mmol) and the reaction was refluxed for 4 hours. After termination of reaction (TLC, acetone:n-hexane, 2:3), solvent was removed under reduced pressure and the crude product was purified by column chromatography (acetone:n-hexane, 2:3). Product obtained as white crystals (2.37 g, 87% yield). M.p. 206.5-207.5° C. Anal. calcd. for C₃₀H₄₄N₃O₇P: C, 61.11, H, 7.52, N, 7.13; found: C, 61.28, H, 7.66, N, 7.01.

### 9-(4-Phosphonobutyl)-9H-carbazole-3,6-bis(aminium) dichloride (V1548)

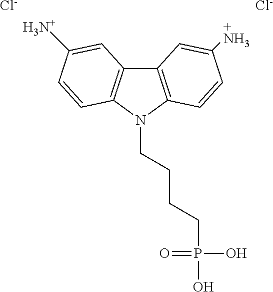 [SMILES: [Cl-] ; [Cl-] ; [NH3+]c1ccc2c(c1)c1cc([NH3+])ccc1n2CCCCP(=O)(O)O]

Di-tert-butyl {9-[4-(diethoxyphosphoryl)butyl]-9H-carbazole-3,6-diyl}dicarbamate (92) (0.8 g, 1.36 mmol) was suspended in 37% hydrochloric acid (5.3 ml, 54.2 mmol) and refluxed overnight. After the termination of the reaction (TLC, acetone:n-hexane, 2:3), solvent was evaporated, and product was purified by dissolving in minimum amount of MeOH, precipitating into 20-fold excess of diethyl ether, filtering and washing with diethyl ether to give brown crystals (0.42 g, 77% yield). M.p. 325-327° C.

Anal. calcd. for C₁₆H₂₂C₁₂N₃O₃P: C, 47.31, H, 5.46, N, 10.34; found: C, 47.20, H, 5.33, N, 10.36.

¹H NMR (400 MHZ, DMSO-d₆): δ 9.55 (s, 6H), 8.13 (s, 2H), 7.74 (d, J=8.6 Hz, 2H), 7.48 (d, J=8.6 Hz, 2H), 4.46-4.30 (m, 2H), 1.89-1.72 (m, 2H), 1.61-1.40 (m, 4H) ppm.

¹³C NMR (101 MHZ, DMSO-d₆): δ 139.33, 124.31, 121.44, 121.31, 114.51, 110.77, 42.37, 29.55, 29.40, 27.92, 26.57, 20.39, 20.35 ppm.

### 9-(4-Phosphonobutyl)-9H-carbazole-3,6-bis(aminium) dibromide (V1482)

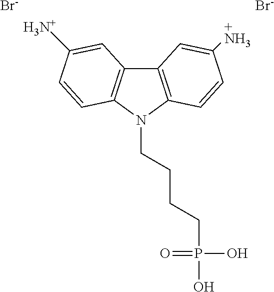 [SMILES: [Br-] ; [Br-] ; [NH3+]c1ccc2c(c1)c1cc([NH3+])ccc1n2CCCCP(=O)(O)O]

Di-tert-butyl {9-[4 (diethoxyphosphoryl)butyl]-9H-carbazole-3,6-diyl}dicarbamate (92) (0.7 g, 1.19 mmol) was dissolved in anhydrous 1,4-dioxane (30 ml) under argon atmosphere. Afterwards, bromotrimethylsilane (1.5 ml, 11.9 mmol) was added dropwise and reaction was stirred overnight at 25° C. After consumption of phosphonate (TLC, acetone:n-hexane, 2:3) methanol (1.1 ml, 27.7 mmol) was added and stirring continued for 2 hours. Afterwards, distilled water was added dropwise until precipitate was formed and stirring continued overnight. Solvent was evaporated under reduced pressure. Product was purified by dissolving in minimum amount of MeOH, precipitating into 20-fold excess of diethyl ether, filtering and washing with diethyl ether to give brown crystals (0.28 g, 48% yield). M.p. 340-342° C.

Anal. calcd. for C₁₆H₂₂Br₂N₃O₃P: C, 38.81, H, 4.48, N, 8.49; found: C, 38.68, H, 4.37, N, 8.40.

¹H NMR (400 MHZ, DMSO-d₆): δ 10.11 (s, 6H), 8.21 (s, 2H), 7.83 (d, J=8.7 Hz, 2H), 7.52 (d, J=8.6 Hz, 2H), 4.47 (t, J=5.9 Hz, 2H), 1.93-1.74 (m, 2H), 1.64-1.38 (m, 4H) ppm.

¹³C NMR (101 MHZ, DMSO-d₆): δ 139.74, 123.26, 121.58, 121.44, 115.13, 111.03, 42.46, 29.55, 29.39, 27.94, 26.58, 20.38, 20.34 ppm.

### Example 27:2,2′-[9-(4-Phosphonobutyl)-9H-carbazole-3,6-diyl]bis(ethan-1-aminium) dichloride (V1570) and 2,2′-[9-(4-Phosphonobutyl)-9H-carbazole-3,6-diyl]bis(ethan-1-aminium) dibromide

### Di-tert-butyl [(9H-carbazole-3,6-diyl)bis(ethane-2,1-diyl)]dicarbamate

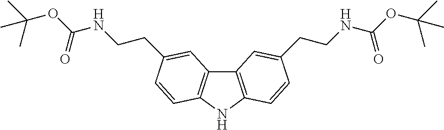 [SMILES: CC(C)(C)OC(=O)NCCc1ccc2[nH]c3ccc(CCNC(=O)OC(C)(C)C)cc3c2c1]

9H-Carbazole-3,6-diethanamine dihydrochloride (0.9 g, 2.76 mmol) was dissolved in MeOH (20 ml) and TEA (1.2 ml, 8.28 mmol). Afterwards, di-tert-butyl dicarbonate (1.4 ml, 6.07 mmol) was slowly added and reaction stirred for 3 hours at 25° C. After termination of reaction (TLC, acetone:n-hexane, 8:17), solvents were removed under reduced pressure and organic components were extracted with ethyl acetate. Organic layer was dried over anhydrous Na₂SO₄, filtered and solvent evaporated under reduced pressure. Crude product was purified by column chromatography, using acetone:n-hexane (8:17) as an eluent, resulting light yellow crystals (0.86 g, 69% yield) as a product. M.p. 134-136° C. Anal. calcd. for C₂₆H₃₅N₃O₄: C, 68.85, H, 7.78, N, 9.26; found: C, 68.98, H, 7.78, N, 9.21.

### Di-tert-butyl {[9-(4-bromobutyl)-9H-carbazole-3,6-diyl]bis(ethane-2,1-diyl)}dicarbamate

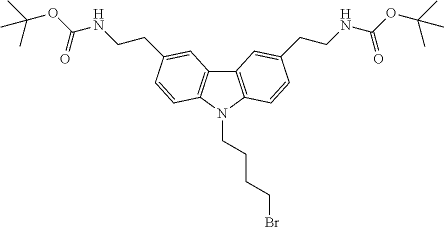 [SMILES: CC(C)(C)OC(=O)NCCc1ccc2c(c1)c1cc(CCNC(=O)OC(C)(C)C)ccc1n2CCCCBr]

Di-tert-butyl [(9H-carbazole-3,6-diyl)bis(ethane-2,1-diyl)]dicarbamate (0.8 g, 1.76 mmol) was dissolved in 10 ml of anhydrous DMF under argon atmosphere, followed by the addition of 1,4-dibromobutane (0.3 ml, 2.65 mmol) and ground KOH (0.15 g, 2.65 mmol). Reaction mixture was stirred for 1 hour at 25° C. After termination of reaction (TLC, acetone:n-hexane, 1:4), organic components were extracted with ethyl acetate, organic layer was dried over anhydrous Na₂SO₄, filtered and solvent evaporated under reduced pressure. Crude product was purified by column chromatography (acetone:n-hexane, 1:4). Product obtained as colorless resin (0.87 g, 84% yield). Anal. calcd. for C₃₀H₄₂BrN₃O₄: C, 61.22, H 7.19, N, 7.14; found: C, 61.27, H, 7.10, N, 7.03.

### Di-tert-butyl ({9-[4-(diethoxyphosphoryl)butyl]-9H-carbazole-3,6-diyl}bis(ethane-2,1-diyl))dicarbamate

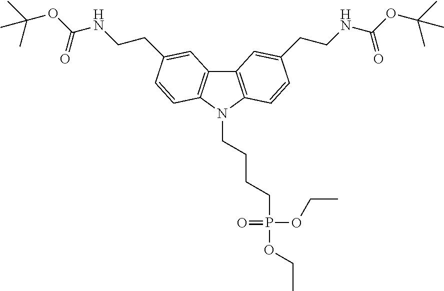 [SMILES: CCOP(=O)(CCCCn1c2ccc(CCNC(=O)OC(C)(C)C)cc2c2cc(CCNC(=O)OC(C)(C)C)ccc21)OCC]

Di-tert-butyl {[9-(4-bromobutyl)-9H-carbazole-3,6-diyl]bis(ethane-2,1-diyl)}dicarbamate (0.84 g, 1.43 mmol) was dissolved in triethyl phosphite (4.9 ml, 28.5 mmol) and the reaction was refluxed for 3 hours. After termination of reaction (TLC, acetone:n-hexane, 2:3), solvent was removed under reduced pressure and the crude product was purified by column chromatography (acetone:n-hexane, 2:3). Product obtained as colorless resin (0.89 g, 97% yield). Anal. calcd. for C₃₄H₅₂N₃O₇P: C, 63.24, H 8.12, N, 6.51; found: C, 63.30, H, 8.27, N, 6.58.

### 2,2′-[9-(4-Phosphonobutyl)-9H-carbazole-3,6-diyl]bis(ethan-1-aminium) dichloride (V1570)

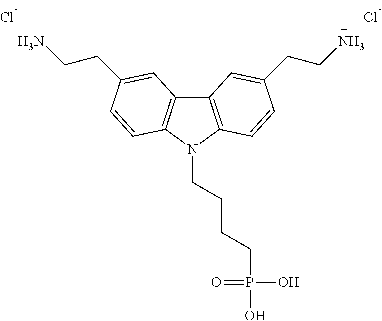 [SMILES: Cl ; Cl ; NCCc1ccc2c(c1)c1cc(CC[NH3+])ccc1n2CCCCP(=O)(O)O]

Di-tert-butyl ({9-[4-(diethoxyphosphoryl)butyl]-9H-carbazole-3,6-diyl}bis(ethane-2,1-diyl)) dicarbamate (0.4 g, 0.62 mmol) was suspended in 37% hydrochloric acid (2.4 ml, 24.8 mmol) and refluxed overnight. After the termination of the reaction (TLC, acetone:n-hexane, 1:1), solvent was evaporated, and product was purified by dissolving in minimum amount of MeOH, precipitating into 20-fold excess of diethyl ether, filtering and washing with diethyl ether to give brown crystals (0.25 g, 87% yield). M.p. 227-229° C. (melting and decomposition).

Anal. calcd. for C₂₀H₃₀C₁₂N₃O₃P: C, 51.96, H, 6.54, N, 9.09; found: C, 52.21, H, 6.30, N, 9.09.

¹H NMR (400 MHZ, DMSO-d₆): δ 8.26 (s, 6H), 8.02 (s, 2H), 7.56 (d, J=8.3 Hz, 2H), 7.33 (d, J=8.3 Hz, 2H), 4.41-4.28 (m, 2H), 3.16-2.99 (m, 8H), 1.89-1.74 (m, 2H), 1.62-1.42 (m, 4H) ppm.

¹³C NMR (101 MHZ, DMSO-d₆): δ 139.32, 127.50, 126.58, 122.05, 120.15, 109.53, 42.16, 40.56, 33.04, 29.74, 29.59, 28.07, 26.71, 20.44, 20.39 ppm.

### 2,2′-[9-(4-Phosphonobutyl)-9H-carbazole-3,6-diyl]bis(ethan-1-aminium) dibromide

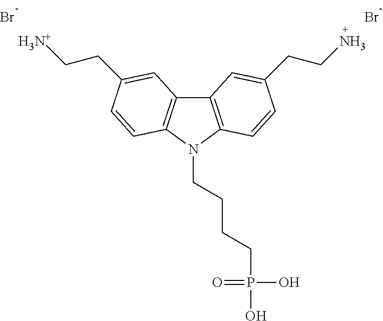 [SMILES: Br ; Br ; NCCc1ccc2c(c1)c1cc(CC[NH3+])ccc1n2CCCCP(=O)(O)O]

Di-tert-butyl ({9-[4-(diethoxyphosphoryl)butyl]-9H-carbazole-3,6-diyl}bis(ethane-2,1-diyl)) dicarbamate (0.45 g, 0.69 mmol) was dissolved in anhydrous 1,4-dioxane (15 ml) under argon atmosphere. Afterwards, bromotrimethylsilane (1 ml, 6.96 mmol) was added dropwise and reaction was stirred overnight at 25° C. After consumption of phosphonate (TLC, acetone:n-hexane, 1:1) methanol (0.3 ml, 6.96 mmol) was added and stirring continued for 2 hours. Afterwards, distilled water was added dropwise until precipitate was formed and stirring continued overnight. Solvent was evaporated under reduced pressure. Product was purified by dissolving in minimum amount of MeOH, precipitating into 20-fold excess of diethyl ether, filtering and washing with diethyl ether to give brown crystals (0.27 g, 70% yield). M.p. 280.5-282° C. (melting and decomposition). Anal. calcd. for C₂₀H₃₀Br₂N₃O₃P: C, 43.58, H, 5.49, N, 7.62; found: C, 43.29, H, 5.42, N, 7.55.

### Example 28: (4-(diphenylamino)phenyl)phosphonic acid (V1678)

### Diisopropyl (4-(diphenylamino)phenyl)phosphonate

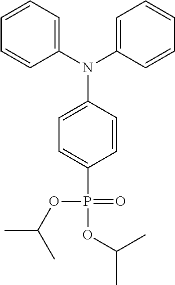 [SMILES: CC(C)OP(=O)(OC(C)C)c1ccc(N(c2ccccc2)c2ccccc2)cc1]

4-Bromotriphenylamine (2 g, 6.17 mmol, 1 eq) dissolved in Diizopropylphosphite (1.14 ml, 6.79 mmol, 1.1 eq) under Ar atmosphere. Following, Triethylamine (1.89 ml, 13.5 mmol, 2.2 eq) and Tetrakis(triphenylphosphine)palladium (0) (0.17 g, 0.15 mmol, 0.03 eq) were added in solution. Reaction was stirred for 4 hours 90° C. After reaction was completed (TLC acetone:n-hexane 7:18 v:v), reaction mixture was filtered through celite. Crude solution was dried using vacuum evaporator and purified with column chromatography (eliuent acetone:n-hexane 7:18 v:v) to exclude clear liquid (1.82 g, 72% yield). Anal. calcd. for C₂₄H₂₈NO₃P, %: C, 70.40; H, 6.89; N, 3.42

### (4-(diphenylamino)phenyl)phosphonic acid (V1678)

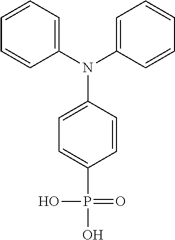 [SMILES: O=P(O)(O)c1ccc(N(c2ccccc2)c2ccccc2)cc1]

Diisopropyl (4-(diphenylamino)phenyl)phosphonate (1 g, 2.44 mmol, 1 eq) was dissolved in 1,4-Dioxane (8.33 ml 97.69 mmol, 40 eq) and Bromotrimethylsilane (3.55 g, 26.86 mmol, 11 eq) was added dropwise. Reaction was left for 20 h and methanol (4 ml, 98.88 mmol, 40 eq.) was added. After 4 more hours few milliliters of H₂O was added dropwise. Reaction solution was distilled, filtered and washed with ethanol. Brownish crystals were collected (0.58 g, 73% yield)

Anal Calcd for C₁₈H₁₆NO₃P, %: C, 66.46; H, 4.96; N, 4.31

¹H NMR (400 MHZ, DMSO) δ 7.53 (dd, J=12.4, 8.2 Hz, 2H), 7.34 (t, J=7.6 Hz, 4H), 7.11 (t, J=7.4 Hz, 2H), 7.06 (d, J=7.9 Hz, 4H), 6.94 (dd, J=8.5, 2.9 Hz, 2H).

¹³C NMR (101 MHz, DMSO) δ 149.64, 146.58, 131.96, 129.77, 127.14, 124.04, 120.68, 120.53.

### Example 29: (4-(di-p-tolylamino)phenyl)phosphonic acid (V1679)

Diisopropyl (4-(di-p-tolylamino)phenyl)phosphonate

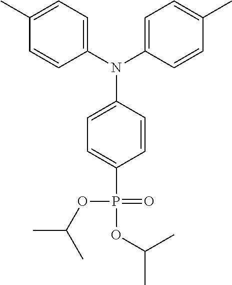

4-Bromo-4′4″-dimethyltriphenylamine (2 g, 5.70 mmol, 1 eq) dissolved in diizopropylphosphite (1.05 ml, 6.27 mmol, 1.1 eq) under Ar atmosphere. Following, Triethylamine (1.74 ml, 12.5 mmol, 2.2 eq) and Tetrakis(triphenylphosphine)palladium (0) (0.16 g, 0.14 mmol, 0.03 eq) was added in solution. Reaction was stirred for 4 hours 90° C. After the reaction was completed (TLC acetone:n-hexane 7:18 v:v), reaction mixture was filtered through celite. Crude solution was dried using vacuum evaporator and purified with column chromatography (eliuent acetone:n-hexane 7:18 v:v) to exclude white crystals (1.36 g, 58% yield). Anal. Calcd. for C₂₆H₃₂NO₃P, %: C, 71.38; H, 7.37; N, 3.20.

(4-(di-p-tolylamino)phenyl)phosphonic acid (V1679) 102781 Diisopropyl (4-(di-p-tolylamino)phenyl)phosphonate (0.98

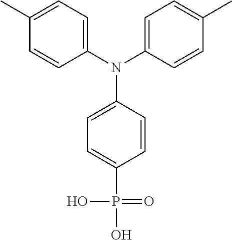

g, 2.39 mmol, 1 eq) was dissolved in 1,4-Dioxane (8.17 ml, 95.73 mmol, 40 eq) and Bromotrimethylsilane (3.47 g, 26.33 mmol, 11 eq) was added dropwise. Reaction was left for 20 h and methanol (4 ml, 98.88 mmol, 41 eq.). After 4 more hours few milliliters of H₂O was added dropwise. Reaction solution was distilled, filtered and washed with ethanol. Brownish crystals were collected (0.52 g, 67% yield)

Anal. Calcd. for C₂₀H₂₀NO₃P, %: C, 67.98; H, 5.71; N, 3.96

¹H NMR (400 MHZ, DMSO) δ 7.48 (d, J=12.5, 8.2 Hz, 2H), 7.14 (d, J=8.0 Hz, 4H), 7.02-6.88 (m, 4H), 6.88-6.76 (m, 2H), 2.26 (d, J=6.8 Hz, 6H).

¹³C NMR (101 MHz, DMSO) δ 150.01, 144.04, 133.40, 131.96, 130.35, 125.68, 125.34, 119.08, 20.48.

### Example 30 (4-(bis(4-methoxyphenyl)amino)phenyl)phosphonic acid (V1680)

### Diisopropyl (4-(bis(4-methoxyphenyl)amino)phenyl)phosphonate

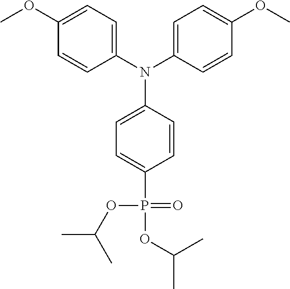

4.61 mmol, 1 eq) dissolved in diizopropylphosphite (0.85 ml, 5.08 mmol, 1.1 eq) under Ar atmosphere. Following, Triethylamine (1.03 ml, 10.15 mmol, 2.2 eq) and Tetrakis(triphenylphosphine)palladium (0) (0.13 g, 0.12 mmol, 0.025 eq) was added in solution. Reaction was stirred for 4 hours 90° C. After reaction was completed (TLC acetone:n-hexane 7:18 v:v), reaction mixture was filtered through celite. Crude solution was dried using vacuum evaporator and purified with column chromatography (eluent acetone:n-hexane 7:18 v:v) to exclude white crystals (1.36 g, 63%). Anal. Calcd. for C₂₆H₃₂NO₅P, %: C, 66.51; H, 6.87; N, 2.98.

(4-(bis(4-methoxyphenyl)amino)phenyl)phosphonic acid (V1680)

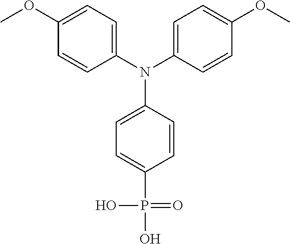

methoxyphenyl)amino)phenyl)phosphonate (0.45 g, 0.96 mmol, 1 eq) was dissolved in 1,4-Dioxane (3.29 ml, 38.59 mmol, 40 eq) and Bromotrimethylsilane (1.40 ml, 10.61 mmol, 11 eq) was added dropwise. Reaction was left for 20 h and methanol (3 ml, 74.16 mmol, 76 eq.). After 4 more hours few milliliters of H₂O were added dropwise. Reaction solution was distilled, filtered and washed with ethanol to give brownish crystals (0.28 g 89% yield)

Anal. Calcd. for C₂₀H₂₀NO₅P, %: C, 62.34; H, 5.23; N, 3.63.

¹H NMR (400 MHZ, DMSO) δ 7.43 (dd, J=12.5, 8.3 Hz, 2H), 7.14-7.03 (m, 4H), 6.98-6.85 (m, 4H), 6.75-6.67 (m, 2H), 3.74 (s, 6H).

¹³C NMR (101 MHz, DMSO) δ 156.37, 150.64, 139.25, 131.78, 127.57, 124.23, 116.83, 115.13, 55.28.

### Example 31: (E)-3-(4-(bis(2,2-diphenylvinyl)amino)phenyl)-2-cyanoacrylic acid (V1626) and (E)-3-(4-(bis(2,2-bis(4-methoxyphenyl)vinyl)amino)phenyl)-2-cyanoacrylic acid (V1627)

### (E)-3-(4-aminophenyl)-2-cyanoacrylic acid

To a solution of 4-amino benzaldehyde (1.2 g, 9.91 mmol) and

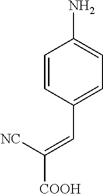 [SMILES: N#C/C(=C\c1ccc(N)cc1)C(=O)O]

cyano acetic acid (0.93 g, 10.90 mmol) in ethanol (30 ml), piperidine (1.96 ml, 19.82 mmol) was added with stirring and stirring was continued at room temperature for 20 h (TLC, methanol: DCM, 2:23). The reaction mixture was concentrated under vacuum and the residue was purified by column chromatography using methanol: TEA: DCM (v: v: v; 1:1:23) eluent to yield the title compound as a red solid (1.70 g, 91%). C₁₀H₈N₂O₂ [M⁺] exact mass=188.06, MS (ESI)=186.88.

(E)-3-(4-(bis(2,2-diphenylvinyl)amino)phenyl)-2-cyanoacrylic acid (V1626)

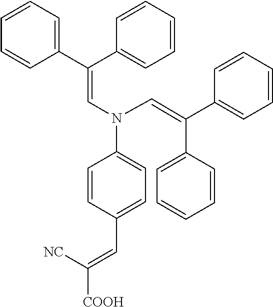 [SMILES: N#C/C(=C\c1ccc(N(C=C(c2ccccc2)c2ccccc2)C=C(c2ccccc2)c2ccccc2)cc1)C(=O)O]

1.59 mmol) was dissolved in toluene (9.5 mL+volume of the Dean-Stark trap), (+/−) camphor-10-sulphonic acid (0.37 g, 1.59 mmol) was added and the mixture was heated at reflux for 20 minutes. Afterwards, diphenylacetaldehyde (0.59 ml, 3.35 mmol) was added, and reflux continued using a Dean-Stark trap. After termination of the reaction (3 h, TLC, methanol: TEA: DCM, 1:1:23) the reaction mixture was extracted with ethyl acetate. The organic layer was dried over anhydrous Na₂SO₄, filtered and solvent evaporated. The crude product was purified by column chromatography using methanol: TEA: DCM (v: v: v; 0.5:1:23.5) eluent. The intermediate product was extracted with ethyl acetate. The organic layer was dried over anhydrous Na₂SO₄, filtered and solvent evaporated. The obtained product was precipitated from acetone into 20-fold excess of n-hexane. The precipitate was filtered off and washed with n-hexane to collect V1626 as a red solid (0.20 g, 23%).

¹H NMR (400 MHZ, DMSO-d₆) δ: 8.23 (s, 1H); 8.05 (d, J=8.5 Hz, 2H); 7.39 (q, J=8.7, 7.1 Hz, 5H); 7.24-7.06 (m, 9H); 7.01 (d, J=7.2 Hz, 4H); 6.38 (d, J=7.5 Hz, 4H); 5.96 (s, 2H) ppm.

¹³C NMR (101 MHz, DMSO) δ: 164.03; 153.47; 149.08; 140.22; 139.07; 133.78; 132.99; 128.97; 128.81; 127.81; 127.67; 127.48; 127.39; 127.30; 124.45; 116.93; 116.29; 98.81 ppm.

Anal. calcd for C₃₈H₂₈N₂O₂: C, 83.80; H 5.18; N, 5.14; found: C, 83.37; H 5.32; N 5.27.

C₃₈H₂₈N₂O₂ [M⁺] exact mass=544.22, MS (ESI)=544.28

### (E)-3-(4-(bis(2,2-bis(4-methoxyphenyl)vinyl)amino)phenyl)-2-cyanoacrylic acid (V1627)

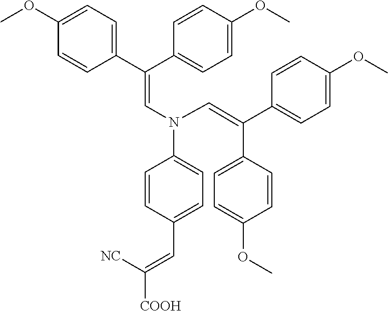

(E)-3-(4-aminophenyl)-2-cyanoacrylic acid (0.30 g, 1.59 mmol) was dissolved in toluene (9.5 mL+volume of the Dean-Stark trap), (+/−) camphor-10-sulphonic acid (0.37 g, 1.59 mmol) was added and the mixture was heated at reflux for 20 minutes. Afterwards, 2,2-bis(4-methoxyphenyl) acetaldehyde (0.86 g, 3.35 mmol) was added, and reflux continued using a Dean-Stark trap. After termination of the reaction (3 h, TLC, methanol: TEA: DCM, 1:1:23) the reaction mixture was extracted with ethyl acetate. The organic layer was dried over anhydrous Na₂SO₄, filtered and solvent evaporated. The crude product was purified by column chromatography using methanol: TEA: DCM (v: v: v; 0.5:1:23.5) eluent. The intermediate product was extracted with ethyl acetate. The organic layer was dried over anhydrous Na₂SO₄, filtered and solvent evaporated. The obtained product was precipitated from toluene into 20-fold excess of n-hexane. The precipitate was filtered off and washed with n-hexane to collect V1627 as a dark red solid (0.21 g, 20%).

¹H NMR (400 MHZ, DMSO-d₆) δ: 8.20 (s, 1H); 8.03 (d, J=8.5 Hz, 2H); 7.11 (d, J=8.5 Hz, 2H); 6.93 (d, J=8.4 Hz, 4H); 6.88 (d, J=8.4 Hz, 4H); 6.66 (d, J=8.3 Hz, 4H); 6.37 (d, J=8.3 Hz, 4H); 5.81 (s, 2H); 3.82 (s, 6H); 3.69 (s, 6H) ppm.

¹³C NMR (101 MHz; DMSO) δ: 164.15; 159.07; 158.82; 153.44; 149.55; 133.07; 132.98; 132.90; 131.40; 130.09; 128.63; 125.18; 123.86; 117.07; 115.76; 114.17; 113.17; 98.11; 55.34; 55.09 ppm.

Anal. calcd for C₄₂H₃₆N₂O₆: C, 75.89; H 5.46; N, 4.21; found: C, 75.44; H 5.48; N 4.16. C₄₂H₃₆N₂O₆ [M⁺] exact mass=664.26, MS (ESI)=664.27.

### Example 32: [4-(3,6-dimethyl-9H-carbazol-9-yl)butyl]phosphonic acid (Me-4PACz)

### (3,6-Dimethyl-9H-carbazole) (1a)

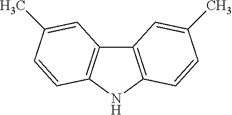

1,3-bis-(diphenylphosphino)dichloronickel (II) (Ni(dppp)₂Cl₂) (2.5 g, 4.62 mmol) were dissolved in 700 ml of absolute diethyl ether under argon atmosphere. After 15 min, 40.9 mL of a 3 M CH₃MgBr solution in diethyl ether (123.08 mmol) was added over a period of 60 min to the purple red suspension, yielding a brown and clear solution. Afterwards reaction mixture was refluxed for 5 h, cooled to room temperature, and quenched with 100 mL of saturated aqueous NH₄Cl solution. Organic phase was separated and extracted three times with 200 mL of saturated aqueous Na₂CO₃ solution, three times with 200 mL of water, and finally three times with 200 mL of saturated aqueous NaCl solution. The organic layer was dried over anhydrous Na₂SO₄ and the solvent was distilled off under reduced pressure. The crude product was purified by column chromatography (acetone n-hexane 1:24 v/v) to give 3.5 g (58%) of white crystalline powder.

### 9-(4-bromobutyl)-3,6-dimethyl-9H-carbazole (2b)

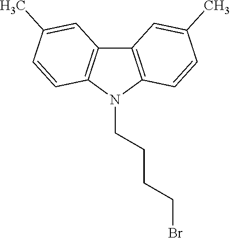

1a (0.6 g, 3.07 mmol) was dissolved in 1,4-dibromobutane (9.1 ml, 76.75 mmol), tetrabuthylammonium bromide (0.148 g, 0.46 mmol) and 50% KOH aqueous solution (0.86 ml, 15.35 mmol) were added subsequently. Reaction was stirred at 60° C. overnight (TLC, acetone:n-hexane, 1:24, v: v). After completion of the reaction, extraction was done with dichloromethane. The organic layer was dried over anhydrous Na₂SO₄ and the solvent was distilled off under reduced pressure. The crude product was purified by column chromatography (acetone nhexane 1:124 v/v) to give 0.91 g (90%) of white crystalline solid. Anal. calcd for C₁₈H₂₀BrN, %: C, 65.46, H, 6.10, N, 4.24, found, %: C 65.31, H, 6.34, N, 4.39.

### Diethyl [4-(3,6-dimethyl-9H-carbazol-9-yl)butyl]phosphonate (3b)

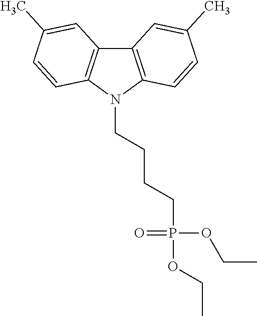 [SMILES: CCOP(=O)(CCCCn1c2ccc(C)cc2c2cc(C)ccc21)OCC]

2b (0.8 g, 2.42 mmol) was dissolved in triethyl phosphite (9 ml, 52.49 mmol) and the reaction mixture was heated at reflux overnight. After reaction completion (TLC, acetone:n-hexane, 6:19, v: v) the solvent was distilled off under reduced pressure. The crude product was purified by column chromatography (acetone/n-hexane 1:4 v/v) to give 0.89 g (95%) of yellowish resin. Anal. calcd for C₂₂H₃₀NO₃P, %: C, 68.20, H, 7.80, N, 3.62, found, %: C 68.03, H, 7.98, N, 3.79.

### [4-(3,6-dimethyl-9H-carbazol-9-yl)butyl]phosphonic acid (Me-4PACz)

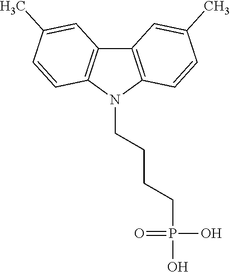

3b (0.6 g, 1.55 mmol) was dissolved in anhydrous 1,4-dioxane (20 ml) under argon atmosphere and bromotrimethylsilane (2.12 ml, 15.59 mmol) was added dropwise. Reaction was stirred for 22 h at 25° C. under argon atmosphere. Afterwards, methanol (3 ml) was added and stirring continued for 3 h. Finally, distilled water was added dropwise (15 ml), until solution became opaque, and it was stirred overnight. Product was filtered off, washed with water, dissolved in tetrahydrofuran (1 ml) and precipitated into n-hexane (15 ml). The product was filtered off and washed with n-hexane, to give 0.460 g (91%) of white powder.

¹H NMR (400 MHZ, (CD₃)₂SO): 8 7.88 (s, 2H), 7.45 (d, J=8.3 Hz, 2H), 7.23 (d, J=8.3 Hz, 2H), 4.34-4.27 (m, 2H), 2.47 (s, 6H), 1.85-1.76 (m, 2H), 1.58-1.45 (m, 4H).

¹³C NMR (100 MHZ, (CD₃)₂SO): δ 138.6, 127.0, 126.8, 122.0, 112.0, 109.0, 42.0, 29.71, 29.56, 28.1, 26.8, 21.1, 20.49, 20.45.

Anal. calcd for C₁₈H₂₂NO₃P, %: C, 65.25, H, 6.69, N, 4.23, found, %: C, 65.38, H, 6.51, N, 4.29.

### Example 33: Perovskite single-junction preparation

The perovskite solar cell has an inverted (p-i-n) planar structure and is deposited on ITO-covered glass (Automated Research GmbH, both 7 Ohm/sq and 15 Ohm/sq sheet conductivities were used in this study), which was cleaned with Mucasol (2% in DI-water, substrates were brushed), DI-water, acetone and isopropanol, each for 15 minutes in an ultrasonic bath. Afterwards the surface was “activated” for 10-15 minutes in an UV—O3 cleaner (FHR UVOH 150 Lab), which is a crucial step before SAM functionalization (for the tandem cells as well). The single-junction cell configuration is ITO/HTL/Perovskite/(LiF)/C₆₀/SnO₂/Ag, where the HTL is PTAA, MeO-2PACz, 2PACz or Me-4PACz. All the spin-coating layer deposition steps were conducted in a nitrogen atmosphere. The hole transport material PTAA (2 mg ml-1 in toluene) was deposited using spin-coating (5000 rpm for 30 s, 5 s acceleration), followed by heating for 10 min at 100° C. The rotation was reduced for the SAM solutions to 3000 rpm (used concentration of the SAM solutions=1 mmol/l, or ˜0.3 mg/ml). The perovskite was prepared following the typical triple cation process. In short, 1.5 M nominal PbI₂ and

PbBr₂ in DMF: DMSO=4:1 volume were first prepared as stock solutions (shaken overnight at 60° C.) and then added to FAI and MABr with 9% PbX₂ excess, respectively (X=I or Br) (typical amounts were 0.3 g FAI and 0.06 g of MABr). The so obtained FAPbI₃ and MAPbBr₃ were then mixed in 77:23 volume ratio to obtain the “double cation” perovskite. Finally, 5 vol-% of 1.5 M nominal CsI in DMSO was added to the perovskite precursor (stock solution prepared one day before, typically ˜50 mg powder). 100 μl of perovskite solution was then spread on the substrate and spun using one step spincoating process (3500 for 35 s, 5 s acceleration). 10-13 s before the end of the program, 300 μl of Anisole as the anti-solvent was dripped on the film. The films were then annealed at 100° C. for 15-30 min. Afterwards, 20 nm of C₆₀ was thermally evaporated at a rate of 0.15 Å s⁻¹ onto the perovskite film. Optionally, as indicated, a 1 nm-thick LiF interlayer was deposited between C₆₀ and perovskite, evaporated at a rate of 0.05 Å s⁻¹, within the same vacuum run as the C₆₀ layer. 20 nm of SnO₂ were then deposited by thermal ALD in an Arradiance GEMStar reactor. Tetrakis(dimethylamino)tin(IV) (TDMASn) was used as the Sn precursor and was held at 60° C. in a stainless-steel container. Water was used as oxidant, and was delivered from a stainless-steel container without active heating, whereas the precursor delivery manifold was heated to 115° C. For the deposition at 80° C., the TDMASn/purge1/H₂O/purge2 times were 1s/10s/0.2s/15s with corresponding nitrogen flows of 30 sccm/90 sccm/90 sccm/90 sccm. With this, 140 cycles lead to 20 nm tin oxide. The method was based on Kohnen et al. We noticed a beneficial effect when letting the TDMASn bottle cool down to room temperature when not in use. Finally, 100 nm Ag were deposited by thermal evaporation at a rate of 1 Å s⁻¹.

### Example 34: Silicon Solar Cell Preparation

The silicon heterojunction (SHJ)-bottom cell was fabricated from a 260 μm thick, ˜3 Ω cm⁻¹ polished FZ <100> n-type crystalline silicon (c-Si) wafer in a rear junction configuration. The front surface of the wafer was left polished by capping with a PECVD deposited SiO₂ prior to wet texturing to obtain random pyramids with <111> facets. After removal of the capping in HF another final RCA clean and HF dip (1% dilution in water) were done and an approx. 5 nm thick, intrinsic (i) amorphous silicon (a-Si: H) layer stack was grown on both sides of the c-Si wafer in order to passivate the c-Si surface. On the textured rear-side, an approx. −5-nm thick, p-doped a-Si: H layer stack was deposited to form the hole contact (junction). On the polished front-side, a 95-nm thick (20-nm thick for single-junction reference cells), n-doped nanocrystalline silicon oxide layer (nc-SiOx:H) with a refractive index, n, of 2.7 at 633 nm was used as the electron contact of the SHJ bottom cell and the optical intermediate layer between the top and the bottom cells. The a- and nc-Si layers were deposited with an Applied

Materials (AKT1600) plasma enhanced chemical vapor deposition (PECVD) cluster tool. In order to contact the bottom cell a ZnO: Al/Ag layer stack was deposited on the textured rear-side and a 20 nm (70-nm thick for single-junction references) thick ITO layer was deposited on the polished front-side on top of the nc-SiOx:H interlayer. Both depositions were DC-sputtered in an in-line sputter tool from Leybold Optics using Ar/O₂ gas mixtures. For the ITO a tube target with 95/5 doping ratio and for the AZO a tube target with 1% Al₂O₃ in ZnO was used. Both contact-layer stacks of the silicon were deposited using aligned shadow masks with an opening of 1.13×1.13 cm² (2×2 cm² for single-junction reference). For single-junction reference cells with an aperture area of 2×2 cm², an Ag grid was screenprinted on top of the front ITO.

### Example 35: Preparation of Tandem Solar Cells

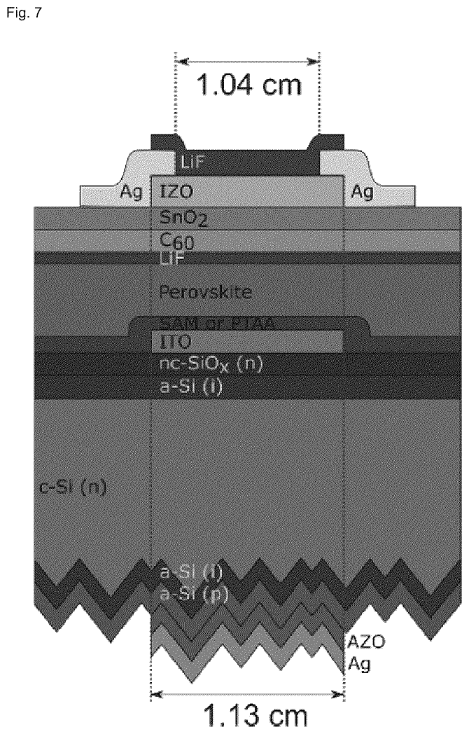

The bottom cells were blown clean with N₂ and UV-03-treated for 15 minutes. The same HTL, perovskite, (LiF), C₆₀ and SnO₂ deposition as described above was conducted on the silicon bottom cells. Subsequently, 100 nm IZO (Roth&Rau MicroSys 200 PVD, ceramic target purchased from FHR Anlagenbau GmbH) are deposited by sputtering. The 2-inch ceramic target consisted of 90% wt. In₂O₃ and 10% wt. ZnO. At a RF-power of 70 W the cells oscillated under the target to have a uniform deposition. 0.2% vol O₂ was added to the chamber. The previously optimized layer (26) has a mobility, carrier density and resistivity of 43.5 cm² V⁻¹ s⁻¹, 3.4·10²⁰ cm³ and 4.2·10⁻⁴ Ω cm, respectively. A 100 nm silver frame was thermally evaporated through a shadow mask to collect the charge carriers without a need of grid fingers. Lastly, 100 nm LiF is evaporated as an antireflective coating by thermal evaporation. The active area is defined by the metal frame and is slightly larger than 1 cm². A schematic of a monolithic tandem solar cell is shown in FIG. 7.

### Luminescence Spectroscopy Techniques

### Time-Dependent Steady-State Photoluminescence

Time-dependent steady state absolute photoluminescence measurements were performed on a homebuilt setup using an integrating sphere, where the samples were placed at the edge of the sphere. The PL was collected with a fiber connected to a CCD-array spectrometer (Ocean Optics). The samples were excited with a continuous-wave laser at 532 nm emission wavelength, a photon flux of ˜1.2E16 photons/s and a spot size on the sample of 0.12 cm² (around 1-sun-equivalent excitation fluence, calibrated with a certified silicon reference cell). The 30-suns case was realized by a focusing lens to reduce the spot size to 0.4 mm². The spot size was measured by fitting a Gaussian curve to the beam profile extracted from CCD imaging the laser spot. The 1-sun 0.4 mm² case was realized by a focusing lens and appropriate ND filters. Non-absorbed laser light and emitted photoluminescence fluxes were simultaneously detected by the spectrometer, of which the spectral sensitivity was calibrated using a NIST-traceable halogen lamp. The spectral time evolutions of the perovskite films were recorded with an integration time of 300 ms and delay of 2-3 s between each recording. Measurements were carried out in air; the samples were measured promptly after they were taken out from the N₂-filled glovebox.

### Absolute PL and Pseudo-J-Vs

Excitation for the PL imaging measurements was performed with a 520 nm CW laser (Insaneware) through an optical fibre into an integrating sphere. The intensity of the laser was adjusted to a 1 sun equivalent intensity by illuminating a 1 cm²-sized perovskite solar cell under short-circuit and matching the current density to the J_{SC} under the sun simulator (e.g. ˜ 22.0 mA cm⁻² at 100 mW cm⁻², or 1.375×1021 photons m⁻² s⁻¹). A second optical fiber was used from the output of the integrating sphere to an Andor SR393i-B spectrometer equipped with a silicon CCD camera (DU420A-BR-DD, iDus). The system was calibrated by using a halogen lamp with known spectral irradiance, which was shone into to integrating sphere. A spectral correction factor was established to match the spectral output of the detector to the calibrated spectral irradiance of the lamp. The spectral photon density was obtained from the corrected detector signal (spectral irradiance) by division through the photon energy (hf), and the photon numbers of the excitation and emission were obtained from numerical integration using Matlab. In a last step, three fluorescent test samples with high specified PLQY supplied from Hamamatsu Photonics where measured where the specified value could be accurately reproduced within a small relative error of less than 5%. The samples were illuminated in the integrating sphere using the same 520 nm CW laser (Insaneware) as described above. A continuously variable neutral density filter wheel (ThorLabs) was used to attenuate the laser power to measure at different intensities which was monitored using an additional Si photodetector. The samples were illuminated at a given intensity for a variable illumination time using an electrical shutter. After an illumination time of 1 second, the PL spectra were recorded by averaging 30 spectra taken using a detector exposure time of 30 μs. The electrical shutter was then closed, and the filter wheel was moved to the next position and the steps were repeated. A custom-built Labview code was written to automate the measurement, and a Matlab code to automate the data evaluation.

### Pseudo-J-Vs

The pseudo-J-Vs were deduced from the intensity-dependent QFLS or V_{OC} measurements as recently demonstrated in Stolterfoht et al_1. This was done by calculating the dark-current density from the generated current density at a given light intensity in equivalent suns. E.g. 1 sun corresponds to 22.0 mA cm⁻², 1% of a sun to 0.220 mA cm⁻². The obtained dark current was then plotted against the measured QFLS or V_{OC} at the given light intensity to create a transport/series resistance-free dark J-V-curve. This curve was then shifted to the J_{SC} in the J-V-measurement to create the pseudo-J-V curve allowing to read of the pseudo-(or implied) FF and V_{OC} of the measured partial cell stack (e.g. the neat film, or perovskite/transport layer junction) or the complete cell. We note that the implied FF is only impacted by the non-radiative (and radiative) recombination processes in the studied sample but not by charge transport or resistive losses that are induced by the active layer or the transport layers, and resistances (e.g. the ITO sheet resistance).

### Intensity-Dependent V_{OC} Measurements

Steady-state intensity dependent V_{OC} measurements were obtained with a 520 nm continuous wave laser (Insaneware) providing a power of 1 W. A continuously variable neutral density filterwheel (ThorLabs) was used to attenuate the laser power (up to OD 6). The light intensity was thereby simultaneously measured with a silicon photodetector and a Keithley 485 to improve the accuracy of the measurement. The measurement was performed by measuring the V_{OC} after a 1 second illumination at a given light intensity and then the J_{SC} after 1 second illumination before the filterwheel rotated to the next position. A custom-built LabView code was written to automate the measurement.

Transient photoluminescence

TrPL measurements were carried out in a home-built setup using 660 nm excitation laser light from a supercontinuum light source (SuperK) with a 25-35 μm spot size. The samples were excited from the glass side to avoid increased reflection stray light, however, no significant difference in decay times was observed between excitation from both sides. We chose the longer wavelength excitation to avoid effects of charge diffusion from a high to low carrier density region. The excitation pulse had a repetition rate of 150 kHz and the PL emission was collected panchromatically through a photomultiplier and timecorrelated single photon counting technique. The fluence was controlled with a tuneable neutral density filter and monitored with a power meter.

### Absolute Photo and Electroluminescence Imaging of Tandems

Absolute PL imaging measurements were performed with two 450 nm LEDs for the perovskite subcell and with an 850 nm LED for the excitation of the silicon subcell. The excitation intensities for both measurements were set to 1.4×1021 photons m⁻² s⁻¹. The photoluminescence image detection was performed with a charge-coupled device (CCD) camera (Allied Vision) for the perovskite subcell and with an InGaAs based camera for the Si subcell. Both cameras were coupled with a liquid crystal tunable filter unit. The systems were calibrated to absolute photon numbers. Quantitative electroluminescence imaging was performed by sweeping a voltage between 1.4 and 2.0 V with a 2 mV voltage step and 0.5 s dwell time. The dark current J_{dark} was recorded for the sweeps. To avoid large data collection a luminescence image at every step for every subcell was recorded at the maximum energy of the luminescence. The intensity of the images was scaled to absolute photon numbers with a full hyperspectral image collected at a given injection. This results in a data set containing the electroluminescence yield of each subcell (j) Y^{j}_{EL} (J_{dark}) as a function of the injected current J_{dark}. The radiative current of every subcell J^{j}_{rad} is calculated by multiplying the Y^{j}_{EL} (J_{dark}) by the elementary charge. Finally, the voltage of the subcells V_{OC} is calculated with:

$${V}^{j} = kT ln ( \frac{{J}_{ra d}^{j} + {J}_{0 , ra d}^{j}}{{J}_{0 , ra d}^{j}} ) .$$

Here, J^{j}_{0,rad} is calculated from the EQE of the individual subcells following the reciprocity theorem (71):

$${J}_{0 , ra d}^{j} = q \int {EQE}^{j} ( E ) {ϕ}_{bb} ( E ) dE .$$

### Terahertz-Probe (OPTP) Spectroscopy

Optical-Pump Terahertz-Probe (OPTP) spectroscopy can measure the transient photo-excited sheet conductivity 40S and sum mobility μΣ=μe+μh of the electron mobility μe and the hole mobility μh. The terahertz pulses are generated by optical rectification of 800 nm pulses in a ZnTe crystal. These terahertz pulses are guided through the perovskite sample and the transmitted terahertz field T is measured by electro-optical sampling in a second ZnTe crystal. Additionally, the perovskite samples can be photoexcited by pump pulses with a wavelength of 400 nm and a pulse length of ˜150 fs. These charge carriers

alter the transmission of the terahertz probe pulse by ΔT, which is also detected. The derived pumpinduced change in THz transmission ΔT/T is analyzed by the thin-film approximation in equation (S5) for the photo-excited sheet conductivity ΔσS, which is the integral of the induced photoconductivity Δσ over the sample thickness d. The parameters are the speed of light c, the permittivity of the vacuum ε₀, and the terahertz refractive index of the substrates n_{sub}, which is 1.95 for the used quartz glass substrate.

$${Δσ}_{s} = {\int }_{x = 0}^{d} Δσ dx = - {ε}_{0} c ( 1 + {n}_{sub} ) \frac{\frac{Δ T}{T}}{1 + \frac{Δ T}{T}} \qquad ( 1 )$$

The transient of the photo-excited sheet conductivity is measured by scanning the delay of the pump pulse by an optical delay line. In this case, the terahertz pulse is sampled at its maximum. Additionally, the full terahertz pulse was scanned by a second delay line at a pump delay time of 10 ps. After both ΔT and T are Fourier-transformed, the photo-excited sheet conductivity spectrum is derived by Equation (1). The sum mobility spectrum is obtained by Equation (2) from the photo-excited sheet conductivity, the flux of the pump beam of 7×1011 photons/pulse/cm², and the reflectance of the pump beam at 400 nm of 25%. The quantum yield of exciton dissociation in such mixed halide perovskites is approximately 1 at room temperature.

$$Σμ = {μ}_{e} ( f , t ) + {μ}_{h} ( f , t ) = \frac{{Δσ}_{s}}{q {φ}_{pump} ( 1 - R )} \qquad ( 2 )$$

### Single Junction Solar Cell Characterization (Current-Voltage Curves, EQE)

The J-V curves of single-junction cells were recorded in nitrogen atmosphere with a solar simulator (Oriel LCS-100) and Keithley 2400 source-measure unit, controlled by a custom LabView program. The intensity was calibrated to AM1.5G 1-sun-equivalent with a filtered KG3 Silicon reference solar cell, calibrated by Fraunhofer ISE (spectral mismatch is around 0.997, within the measurement error, thus no correction was applied). J-V scans were as performed in a 2-point-probe configuration. The typical step size was 20 mV, with an integration time of 20 ms and settling time of 20 ms (250 mV/s). The cells did not experience any preconditioning. Shunted or partially shunted devices (mostly due to scratches and not perfectly clean substrates) were not considered in the analysis. EQE spectra were recorded with an Oriel Instruments QEPVSI-b system with a Newport 300 W xenon arc lamp, controlled by TracQ-Basic software. The system is calibrated using a Si reference cell with known spectral response before every measurement. The electrical response of the device under test is measured with a Stanford Research SR830 Lock-In amplifier (time constant of 0.3 s) and evaluated in TracQ. The typical short-circuit current mismatch between integrated external quantum efficiency (EQE) times AM1.5G irradiance and values from J-V scans is around 1% if the area of the cell precisely known (considering shadowing through the mask during metal evaporation).

### Tandem Solar Cell Characterization (Current-Voltage Curves, EQE)

The tandem solar cells were measured in air under AM1.5G (1 sun) equivalent illumination with a Wavelabs Sinus-70 LED class AAA sun simulator. The cells did not experience any preconditioning. For calibration we used a slightly modified calibration route compared to Meusel et al. We adjusted the spectrum such that for both subcells it led to the photogenerated current densities obtained by EQE measurements. Thus, for a perovskite-limited cell, we first increased the intensity of the blue light to get a silicon-limited cell. Subsequently, the NIR region was adjusted until the J_{SC} of the silicon-limited tandem solar cell was equal to the J_{ph,Si} (calculated from EQE and AM1.5G spectrum). Finally, the intensity of the blue light was decreased until the tandem solar cell was perovskite-limited again and the J_{SC} was equal to the J_{ph,Pero}. For a silicon-limited cell it is done vice versa. The backside of the cell was contacted with a metal vacuum chuck at 25° C., whereas the front side was contacted with two Au probes. A black laser-cut aperture mask covered the substrate outside of the active area. The J-V measurements and MPP tracks were recorded using a home-built LabView software. The EQE spectra were recorded with a home-built setup using chopped (79 Hz) monochromatic light from a Xe and He lamp, respectively. To measure the EQE of the perovskite subcell, the silicon subcell was saturated using an LED with 850 nm peak emission. To maintain short-circuit conditions, a bias voltage of 0.6 V was applied. The silicon subcell was measured by saturating the perovskite subcell with blue light from a LED (455 nm) and applying a bias voltage of 1 V.

The boxes in the PV parameter boxplots indicate the 25/75 percentiles and the whiskers mark the 10/90 percentiles. The line in the plots mark the respective average value.

### Helium Ultra-Violet Photoelectron Spectroscopy

Helium ultra-violet photoelectron spectroscopy (He—UPS) with an excitation energy of 21.2 eV was applied to investigate the secondary electron cut off (SECO) and the valence band onset. Four different layer stacks were investigated: i) ITO-covered glass substrate, two different SAMs ii) Me-4PACz and iii) 2PACz on an ITO-covered substrate and iv) ITO/PTAA/Perovskite (1.68 eV band gap). All samples were transferred from the glovebox to the vacuum system in a portable chamber in nitrogen atmosphere. The measurements were conducted using a step width of 0.05 eV and a dwell time of 3 seconds. Between the sample, contacted via the ITO, and the electron analyzer a bias voltage of 7 V was applied. Both, the SECO and the valence band onset (EF-EV), were determined by the intersection of the linear fit of the data with the linear background. Considering the excitation energy of He I, (21.2 eV-SECO) leads directly to the work function (EVak-EF) of the material.

### X-Ray Diffraction

Grazing-incidence wide-angle X-ray scattering (GIWAXS) data were acquired at the four crystal monochromator beamline of the Physikalisch-Technische Bundesanstalt at the synchrotron radiation facility BESSY II. Under high vacuum, X-rays with 8 keV photon energy (λ=1.5498 Å) were incident on 1 cm2 samples prepared with stack silicon/ITO/HTL/perovskite/C₆₀ to mimic growth conditions in devices, and with C₆₀ to prevent any material changes under vacuum. Grazing incidence angles from 1.5° to 6.5° were used to probe different depths in the film and at high angles the broadening due to the beam footprint on the sample is reduced. Scattering was detected with a vacuum-compatible version of the PILATUS3 X 100K hybrid photon-counting detector (DECTRIS). This detector was rotated around the sample center in 4.5° steps through 16 positions at a sample-to-detector distance of 206 mm with 30 s acquisition at each detector angle. The photon flux was approximately 1.82×108 s⁻¹ with 80 μm beam height. Data was reduced and corrected using PyFAI. Further 1D X-ray diffraction measurements were acquired using a PANalytical X'Pert Pro MPD (multipurpose diffractometer) in grazing incidence geometry (GI-XRD). Diffraction patterns were collected with a step size of 0.02 degree, for 6 seconds at each step and at a grazing angle of 1°, with the measurement conducted in air.

### Long Term Stability Measurement

Monolithic tandem solar cells were tracked over 300 h at the maximum power point (MPP) with a self-constructed ageing setup in collaboration with the University of Ljubljana (with them providing the LED-array and measurement components). To guarantee homogenous illumination the LED-array consists of 193 LEDs, 144 of which are blue LEDs and 49 are near-infrared LEDs with a wavelength of 470 nm and 940 nm, respectively. With an independent tunability of both intensities via two potentiometers, the photocurrent of the top and bottom cell can be adjusted to increase or decrease the current mismatch as intended. The bottom cell is electrically connected to a copper block on the backside, whereas the top cell is connected with 2 pogo-pins. Under ambient conditions (relative humidity of 30-40%, measured with a calibrated humidity tracker) the measurement took place in a closed housing at a stable 25° C., while the cells were kept in place with a diaphragm pump. While monitoring the current and voltage of each cell at MPP (using voltage perturbation) the intensity of a blue and infrared reference diode was logged to account for any drops/fluctuation of illumination.

### CITED REFERENCES

Meusel et al.: M. Meusel, R. Adelhelm, F. Dimroth, A. W. Bett, W. Warta, Spectral mismatch correction and spectrometric characterization of monolithic III-V multi-junction solar cells. Prog. Photovolt. Res. Appl. 10, 243-255 (2002).
Stolterfoht et al._1: M. Stolterfoht, M. Grischek, P. Caprioglio, C. M. Wolff, E. Gutierrez-Partida, F. Peña-Camargo, D. Rothhardt, S. Zhang, M. Raoufi, J. Wolansky, M. Abdi-Jalebi, S. D. Stranks, S. Albrecht, T. Kirchartz, D. Neher, How To Quantify the Efficiency Potential of Neat Perovskite Films: Perovskite Semiconductors with an Implied Efficiency Exceeding 28. Adv. Mater. 32, 2000080 (2020).
Sahli et al.: F. Sahli et al., Nat. Mater. 17, 820-826 (2018).
Chen et. al.: B. Chen et al., Joule 4, 850-864 (2020).
Köhnen et al.: E. Köhnen, M. Jošt, A. B. Morales-Vilches, P. Tockhorn, A. Al-Ashouri, B. Macco, L. Kegelmann, L. Korte, B. Rech, R. Schlatmann, B. Stannowski, S. Albrecht, Highly efficient monolithic perovskite silicon tandem solar cells: Analyzing the influence of current mismatch on device performance. Sustain. Energy Fuels 3, 1995-2005 (2019).
Yang et al.: W. S. Yang et al., Science 2017, 356, 1376-1379.
Zhao et al.: J. Zhao et al., Energy Environ. Sci. 2016, 9, 3650-3656.
Stolterfoht et al._2.: M. Stolterfoht et al. Energy Environ. Sci. 2017, 10, 1530-1539.
Heo et al.: J. H. Heo et al., Energy Environ. Sci. 2015, 8, 1602-1608.
Bryant et al.: D. Bryant et al., J. Phys. Chem. Lett. 2015, 6, 3190-3194.
Calado et al.: P. Calado, Nat. Commun. 2016, 7, 13831.

Bush et al.: K. A. Bush et al., 23.6%-efficient monolithic perovskite/silicon tandem solar cells with improved stability, nature energy Vol. 2, 2017, 17009_1-7.
Hou et al. 1: Y. Hou et al., Adv. Mater. Interfaces 2017, 4, 1700007.
Hou et al. 2: Y. Hou et al., Science 2017, 358, 1192-1197
Topolovsek et al.: P. Topolovsek et.al. J. Mater. Chem. A 2017, 5, 11882-11893.
   All scientific publications and patent documents cited in the present specification are incorporated by reference herein.

We claim:

1. A compound according to formula (I) 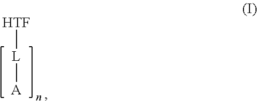
wherein
HTF is a hole transporting fragment selected from the group consisting of formulae 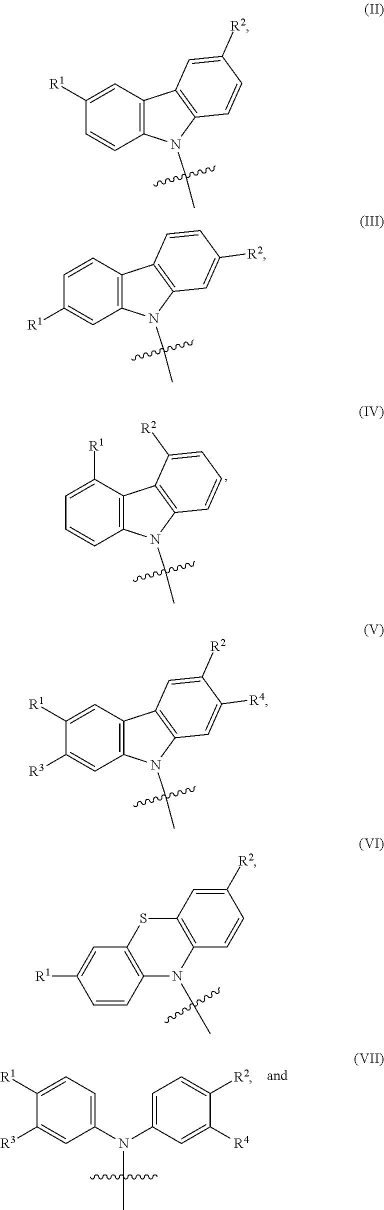 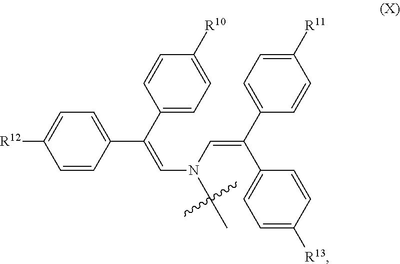
wherein
L is a linking fragment, selected from the group consisting of C₂ to C₁₆ alkyl and phenyl,
A is an anchor group, selected from the group consisting of H₂PO₃ and COOH,
R¹ to R⁴ are each independently selected from the group consisting of:
—H, -methyl, -tert-butyl, —OCH₃,
—CN, —F, —Cl, —Br, —I,
phenyl, thiophene, 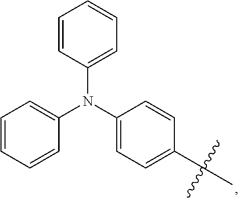 [SMILES: *c1ccc(N(c2ccccc2)c2ccccc2)cc1]
—NH₃⁺Br⁻, —NH₃⁺Cl⁻, —(CH₂)₂—NH₃⁺Br⁻, and —(CH₂)₂—NH₃⁺Cl⁻,
R¹⁰ to R¹³ are selected from the group consisting of —H, and —OCH₃, and
n is 1 or 2.

2. The compound according to claim 1, comprising the formula (I) 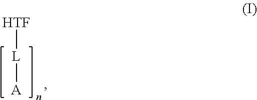
wherein
HTF is a hole transporting fragment selected from the group consisting of formulae 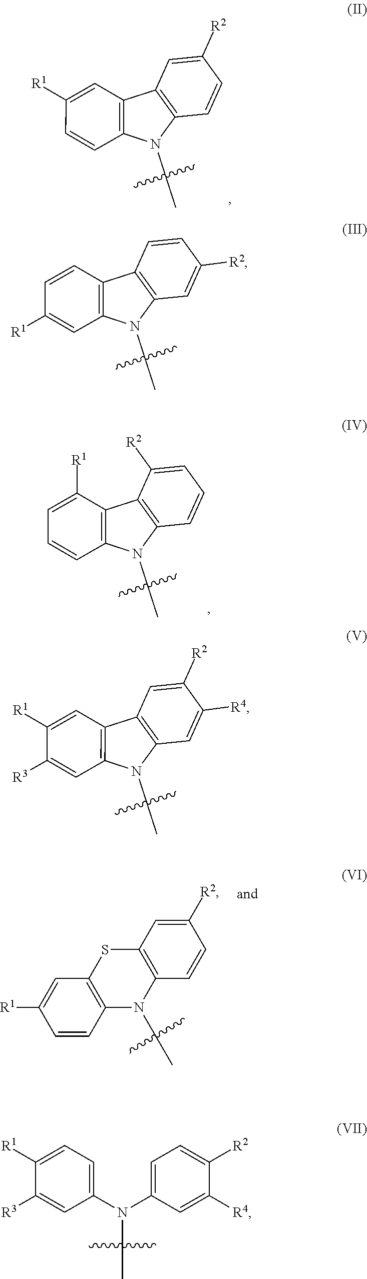
wherein
L is a linking fragment, selected from the group consisting of C₂ to C₁₆ alkyl and phenyl,
A is an anchor group, selected from the group consisting of H₂PO₃ and COOH,
R¹ to R⁴ are each independently selected from the group consisting of:
—H, -methyl, -tert-butyl, —OCH₃,
—CN, —F, —Cl, —Br, —I,
phenyl, thiophene, 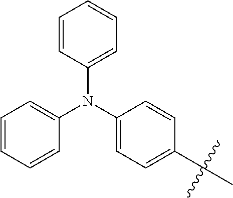 [SMILES: *c1ccc(N(c2ccccc2)c2ccccc2)cc1]
—NH₃⁺Br⁻, —NH₃⁺Cl⁻, —(CH₂)₂—NH₃⁺Br⁻, and —(CH₂)₂—NH₃⁺Cl⁻, and
n is 1 or 2.

3. The compound according to claim 1, wherein R¹ to R⁴ are each independently selected from the group consisting of:
—H, -methyl, -tert-butyl, —OCH₃
—CN, —F, —Cl, —Br, —I,
phenyl, thiophene,
—(CH₂)₂—NH₃⁺Br⁻, and —(CH₂)₂—NH₃⁺Cl⁻,

4. The compound according to claim 1, wherein HTF is selected from the group consisting of formulae 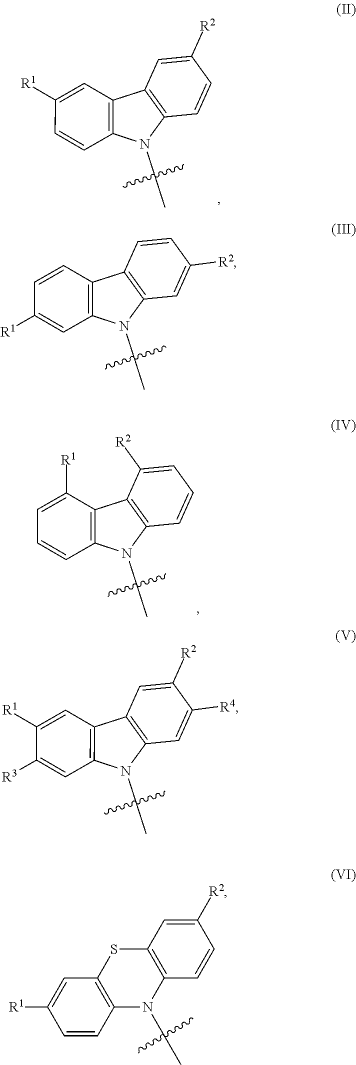
wherein
R¹ to R⁴ are each independently selected from the group consisting of:
—H, -methyl, -tert-butyl, —OCH₃,
—CN, —F, —Cl, —Br, —I,
phenyl, thiophene,
—(CH₂)₂—NH₃⁺Br⁻, and —(CH₂)₂—NH₃⁺Cl⁻.

5. The compound according to claim 1, wherein L is selected from the group consisting of C₂ to C₆ alkyl and phenyl.

6. The compound according to claim 1, wherein L is selected from the group consisting of C₂ to C₆ alkyl.

7. The compound according to claim 1, wherein L is a C₄ alkyl.

8. The compound according to claim 1, wherein A is H₂PO₃.

9. The compound according to claim 1, wherein the HTF is selected from the group consisting of any formulae: 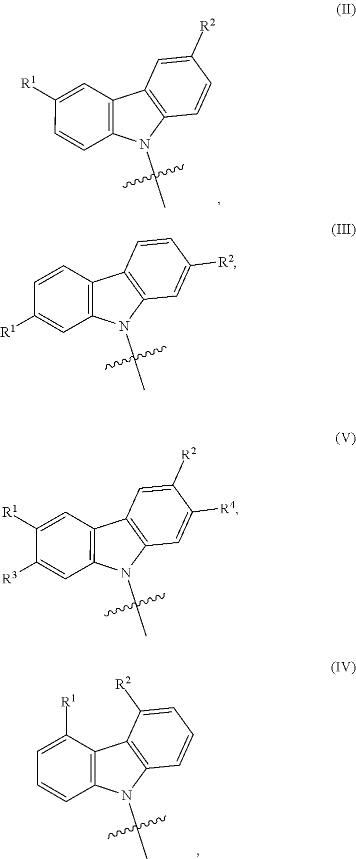
and wherein R¹ to R⁴ are each independently selected from the group consisting of:
—H, -methyl, -tert-butyl, —OCH₃,
—CN, —F, —Cl, —Br, —I,
phenyl, and thiophene.

10. The compound according to claim 1, wherein the HTF is selected from the group consisting of any formulae: 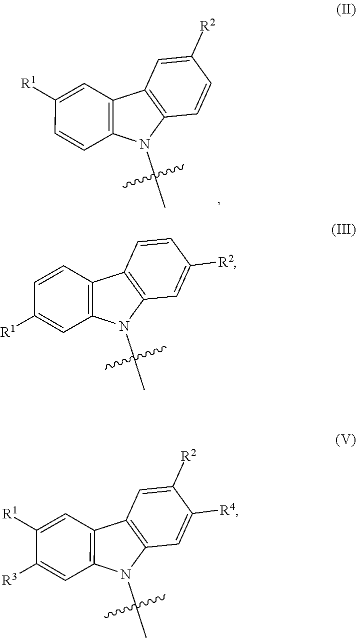
and wherein R¹ to R⁴ are each independently selected from the group consisting of:
—H, -methyl, -tert-butyl, —OCH₃,
—CN, —F, —Cl, —Br, —I,
phenyl, and thiophene.

11. The compound according to claim 1, selected from the group consisting of: 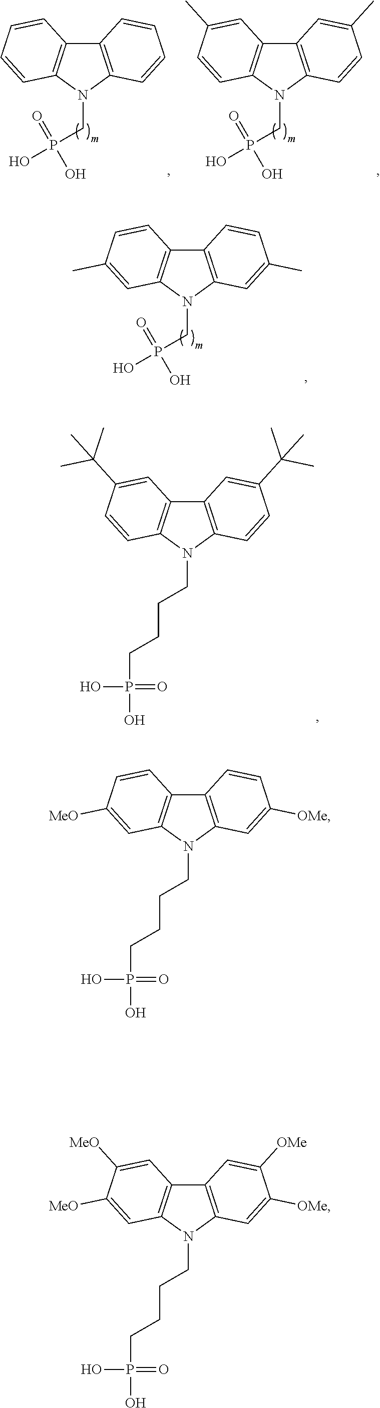 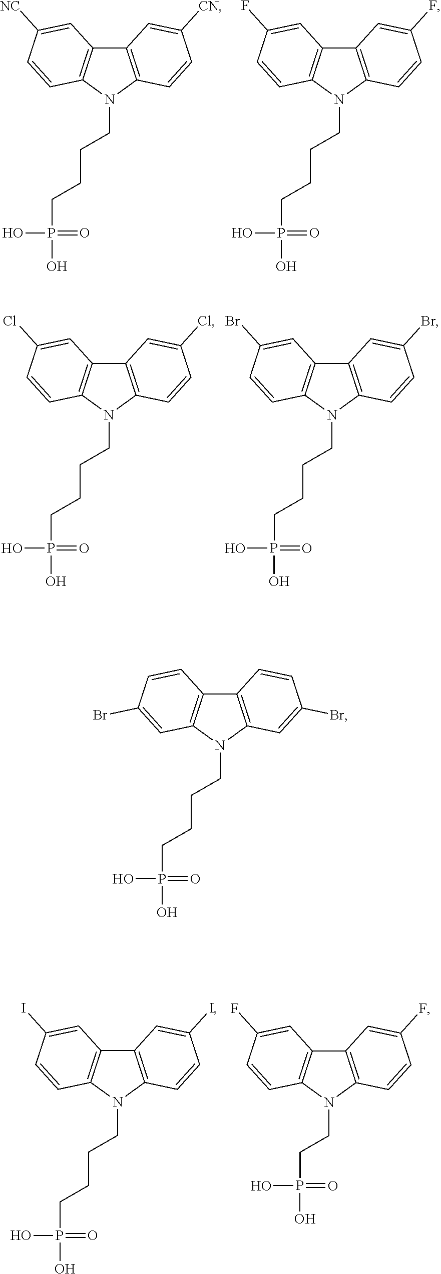 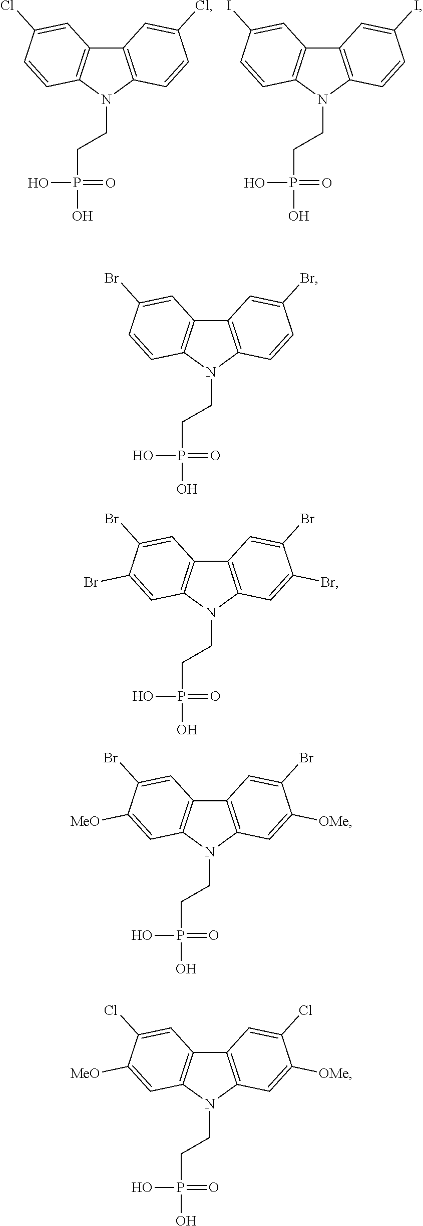 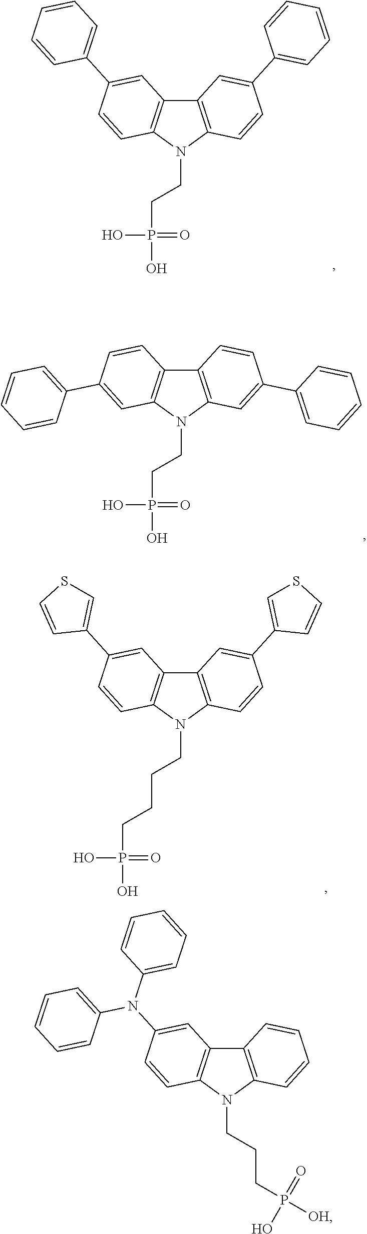 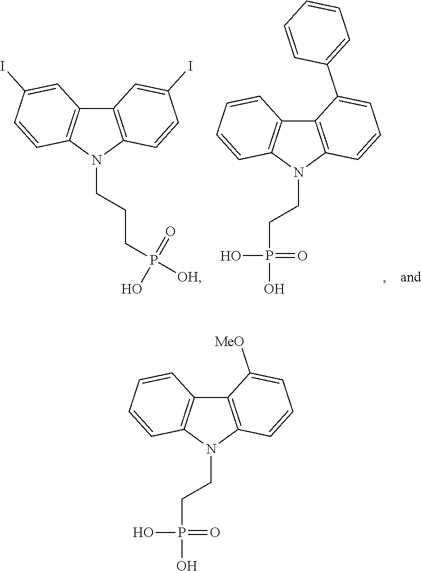
wherein m is an integer in the range of 2 to 6.

12. The compound according to claim 1, selected from the group consisting of: 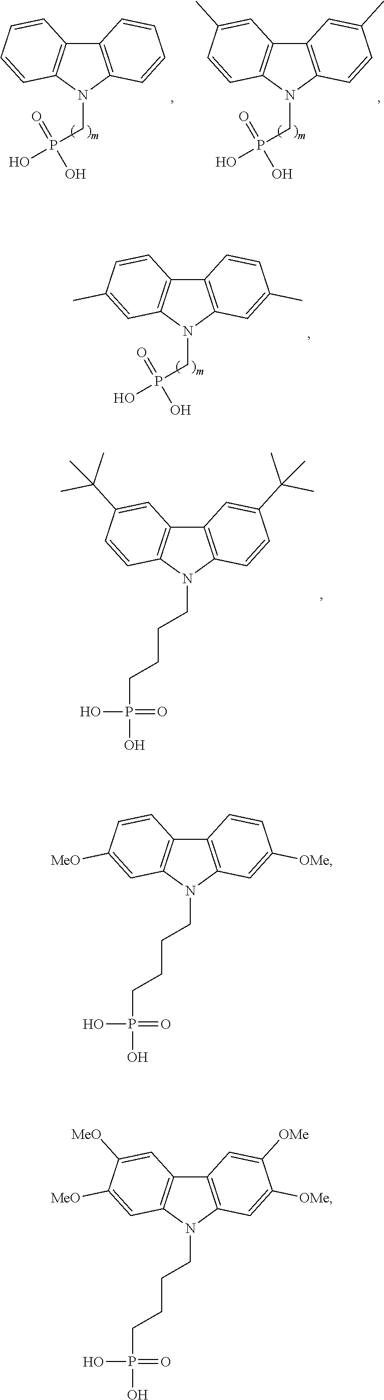 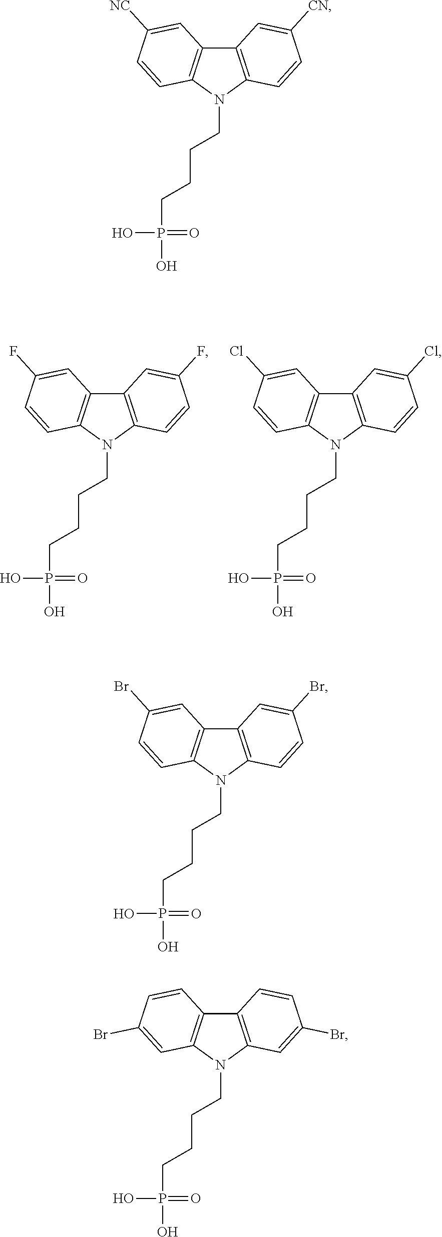 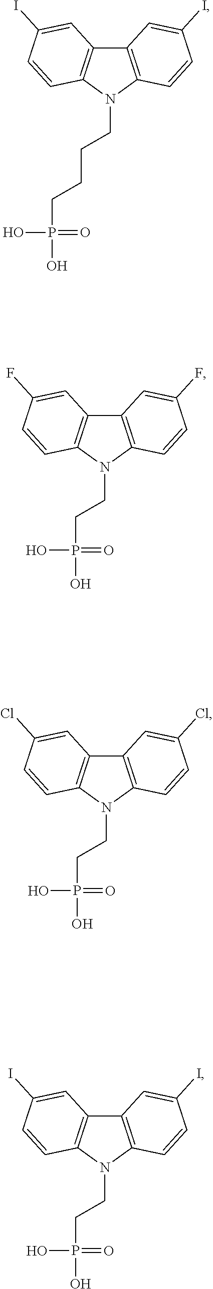 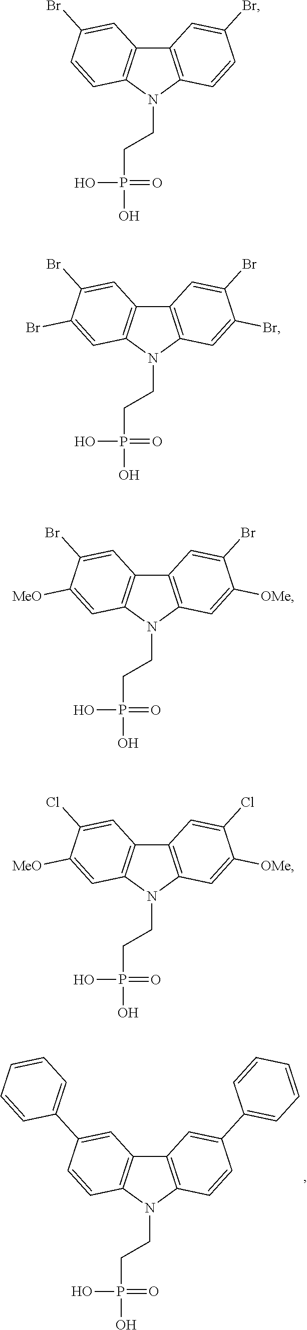 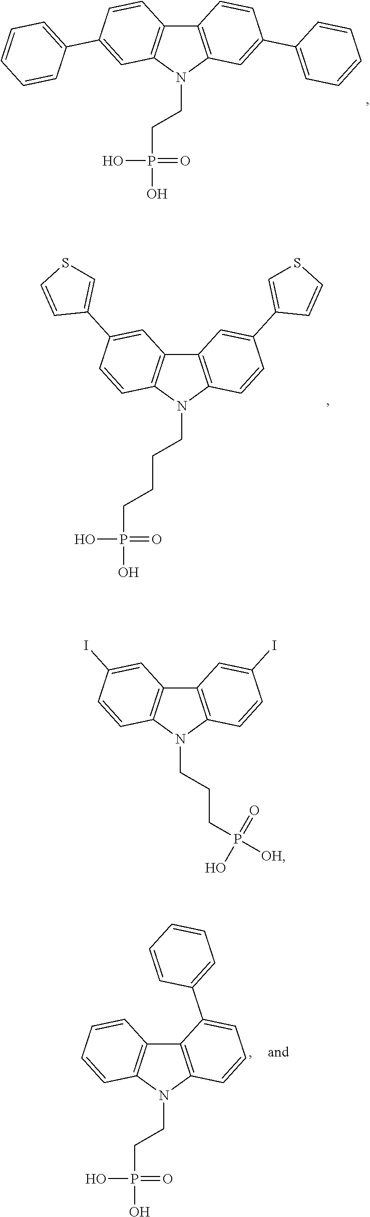 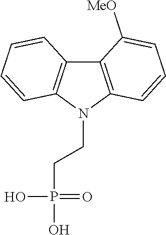
wherein m is an integer in the range of to 6.

13. The compound according to claim 1, selected from the group consisting of: 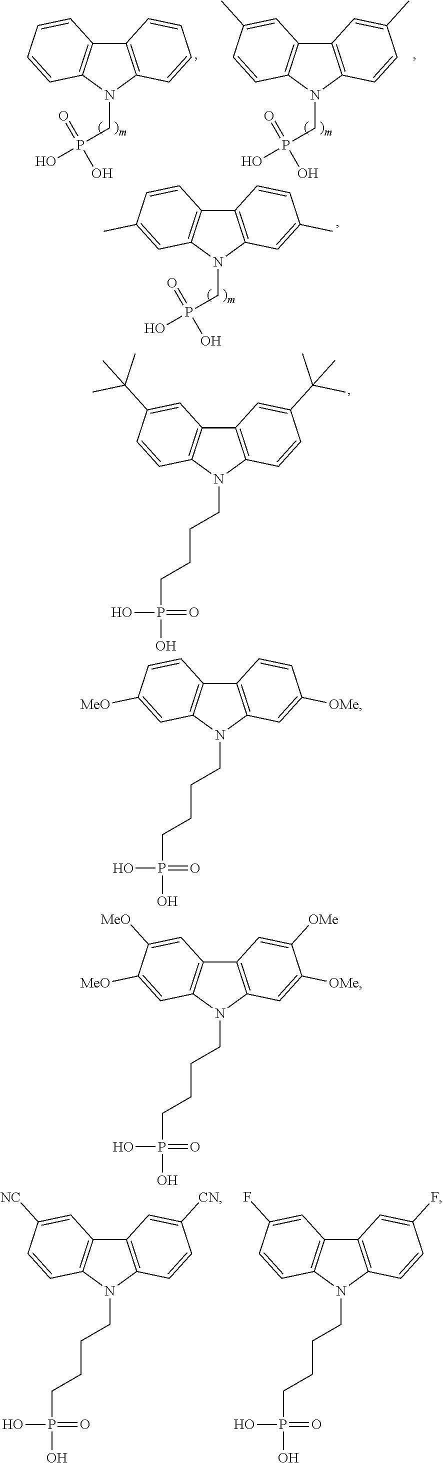 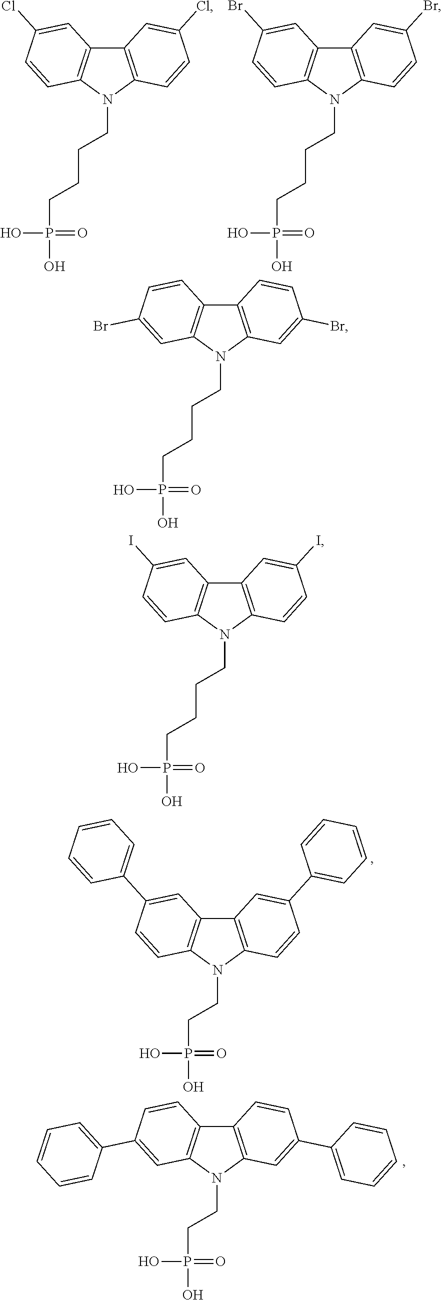 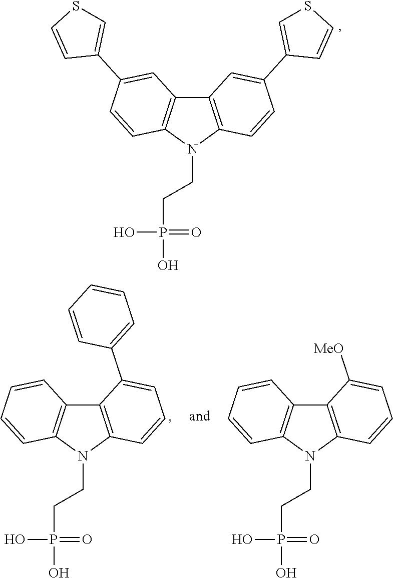
wherein m is an integer in the range of 4 to 6.

14. The compound according to claim 1, selected from the group consisting of: 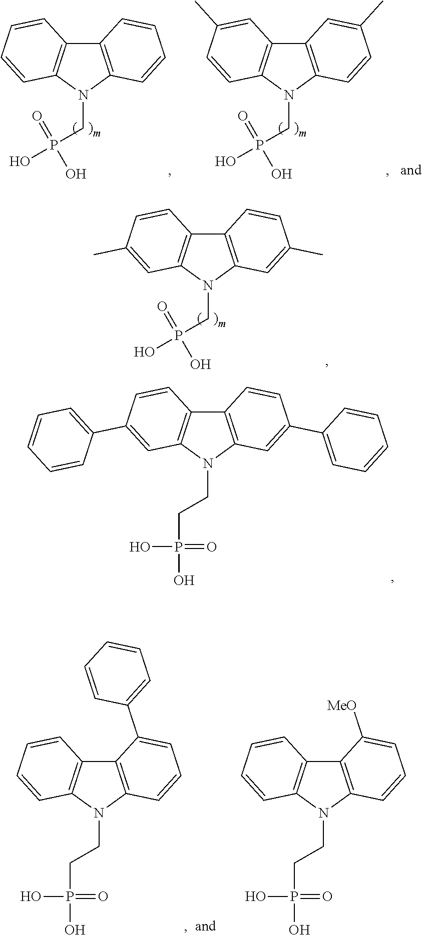
wherein m is an integer in the range of 4 to 6.

15. The compound according to claim 1, selected from the group consisting of: 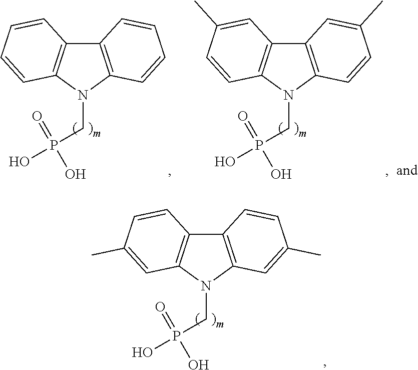
wherein m is an integer in the range of 4 to 6.

16. The compound according to claim 1, wherein the compound is 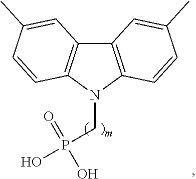
wherein m is 4.

17. A composition comprising a compound according to claim 1 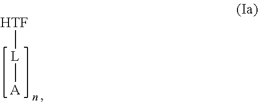
[x],
and a filler molecule FM_{[y]}, consisting of an anchor group selected from the group consisting of phosphonic acid, phosphoric acid, sulphonic acid, sulphuric acid, carboxylic acid and siloxane, a C₁ to C₁₈ alkyl, and a functional group selected from the group consisting of: methyl, halogen, amino, ammonium and sulphuric functional groups; wherein y equals (1−x), and wherein x is in the range of 0.02 to 1.
